(19) United States
(12) Patent Application Publication
(10) Pub. No.: US 2005/0140527 A1
(43) Pub. Date: Jun. 30, 2005

(54) Information recording processor, information playback processor, method therefor, and information recording medium and computer program used therewith

(76) Inventors: Tsutomu Ichinose, Tochigi (JP); Yoichiro Sako, Tokyo (JP)

Correspondence Address: William E. Vaughan;Bell, Boyd & Lloyd LLC, P.O. Box 1135, Chicago, IL, 60690, US

(21) Appl. No.: 10/979,638

(22) Filed: Nov. 1, 2004

(30) Foreign Application Priority Data
Dec. 4, 2003 (JP) P2003-406197
Jan. 30, 2004 (JP) P2004-022637

(51) Int. Cl. H03M 5/00; H04N 7/167

(52) U.S. Cl. 341/58; 380/203

(57) ABSTRACT

Information recording processor, information playback processor, method therefor, and information recording medium and component program used therewith are provided. In information recording and playback processors, when specific user control data includes additional data, bits in the specific user control data are set to be coincident with DC control bits in a DC-control-bit storage frame for specific user control data. When the user control data includes no additional data, the bits in the specific user control data are set to have values not coincident with the DC control bits in the Frame. Exclusive disjunction or exclusive non-disjunction of data in the specific user control data and the additional data is executed and calculated values are set as the values of the DC control bits in the Frame. The additional data is set based on correspondence between bit values of specific user control data in data to be recorded on a recording medium, and DC control bits set in the data. By executing selective processing, the DC control bits for additional data component bits are set.

### CROSS REFERENCES TO RELATED APPLICATIONS

This application claims priority to Japanese Patent Application No. P2003-406197 filed on Dec. 4, 2003 and Japanese Patent Application No. P2004-022637 filed on Jan. 30, 2004, the disclosures of which are incorporated by reference herein.

### BACKGROUND OF THE INVENTION

The present invention relates to information recording processors, information playback processors, methods therefor, and information recording media and computer programs used therewith. In particular, the present invention relates to an information recording processor, an information playback processor, and a method therefor in which, in a configuration capable of recording additional data, such as key information for use in decrypting content, content-playback control information, and copy-control information, on an information recording medium containing content, such as image data and music data, and reading the additional data, by setting additional data based on correspondence between the bit value of specific user control data (UCD) included in recorded data and DC control bits set in the recorded data, embedding of additional data that is difficult to analyze is realized. In addition, the present invention relates to a recording medium and computer program used with the information recording processor, the information playback processor, and the method therefor.

When data, such as music data and image data, is recorded in digital form on a recording medium, recording processing is performed in accordance with a predetermined recording format. For example, error-detecting/correcting codes are added to original data to be recorded, and the data is recorded in a form in which it is coded to have a format adapted for specific data recording/playback processing.

Regarding an information recording medium enabling high-density information recording, recently, an information recording medium based on a system using a blue laser to perform information recording and playback has been developed. In information recording using the blue laser, processing that converts two-bit data into three-bit data is basically performed.

Types of content to be recorded on the above information recording medium include, for example, movie data and music data. In general, rights of distribution, and the like, of many types of content, such as music data and image data, are owned by content creators or sellers. Therefore, in a common form for distributing the types of content, certain limitations in the use of the content are set, that is, by allowing only registered users to use the content, unauthorized reproduction, and the like, are prevented.

On a mass-storage recording medium, such as a recording medium using a blue-laser recording system capable of mass-storage recording, for example, a data capacity corresponding to one to several movies can be recorded. Since content can be easily recorded as described above in the form of digital information, many problems such as the spreading of unauthorized copies occur, so that reduction in profit of the copyright holder and distributor of the content becomes a large problem. In view of the present situation, it is an important issue to achieve protection of profits of the copyright holder and distributor by preventing unauthorized reproduction.

A system for preventing such unauthorized use of content has been proposed. In this system, content to be recorded on an information recording medium is recorded in encrypted form, and, simultaneously, encryption-key information for use as an encryption key for the encrypted content, information forming partial data of the encryption-key information, encryption-key generating information, such as data (e.g., a seed) required for generating an encryption key, or control information of various types, such as content-playback control information and copy-control information, is recorded as secret information on the information recording medium. In addition, a playback-processing program executed in a playback apparatus of a user reads the secret information, such as a key corresponding to the content to be played back, decrypts the content in accordance with the read secret information, and allows use of the content in accordance with playback-control information.

Regarding an example of the related art which discloses processing using embedding of secret information, Japanese Unexamined Patent Application Publication No. 2003-45128, in general, discloses a technology in which special data is embedded by using margin bits of eight-to-fourteen modulated data. Japanese Unexamined Patent Application Publication No. 2002-367282, in general, discloses a technology in which, in a system using transformation tables for modulating processing, data concerning one transformation table, which is used in modulation, is extracted and additional data is acquired based on the extracted data.

However, if the user or an authorized user of content acquires information representing the position of such an encryption key or control information on the information recording medium, that person can leak or alter the additional data. For example, a problem occurs, that is, information or copy-control information may be altered, or key information may leak out. Leaking of the encryption key or alteration of the control information will break a content-utilization form based on the valid right to use content, so that it is difficult to sufficiently protect the copyright of the content and the right to use the content.

### SUMMARY OF THE INVENTION

The present invention in an embodiment provides an information recording processor, an information playback processor, and a method therefor in which, in a configuration capable of recording additional data, such as key information for use in decrypting content, content-playback control information, and copy-control information, on an information recording medium containing content, such as image data and music data, and reading the additional data, by setting additional data based on correspondence between bit values of specific user control data included in recorded data and DC control bits set in the recorded data, embedding of additional data that is difficult to analyze is realized, and to provide a recording medium and computer program used with the information recording processor, the information playback processor, and the method therefor.

According to an embodiment, an information recording processor is provided which includes a DC-control-bit selecting unit for executing DC-control-bit selecting processing in which the values of DC control bits set in a recording frame are set to be coincident or to be not coincident with user control data in response to the values of additional data component bits to be recorded on an information recording medium, and a modulated data generating unit for generating a modulated recording frame used as recording-unit data by executing processing for modulating data to be recorded and DC-control-bit setting processing, the modulated data generating unit selectively executing the DC-control-bit setting processing based on control of a digital sum variation and the DC-control-bit setting processing based on information input from the DC-control-bit selecting unit.

According to an embodiment, an information playback processor for executing processing for playing back information recorded on an information recording medium is provided. The information playback processor includes a data demodulating unit for executing demodulating processing on data read from the information recording medium, and an additional data decoding unit for executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information on the basis of the result of the determination of correspondence.

According to an embodiment, an information recording medium including additional data recorded thereon is provided. The additional data is analyzable based on correspondence between bit values of specific user control data included in recorded data, and DC control bits set in the recorded data.

According to an embodiment, an information recording method is provided which includes a DC-control-bit selecting step of executing DC-control-bit selecting processing in which the values of DC control bits set in a recording frame are set to be coincident or to be not coincident with user control data in response to the values of additional data component bits to be recorded on an information recording medium, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information selected in the DC-control-bit selecting step are selectively executed.

According to an embodiment, an information playback method for executing processing for playing back information recorded on an information recording medium is provided. The information playback method includes a data demodulating step of executing demodulating processing on data read from the information recording medium, and an additional data decoding step of executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information on the basis of the result of the determination of correspondence.

According to an embodiment, a computer program for executing processing for recording information is provided. The computer program includes a DC-control-bit selecting step of executing DC-control-bit selecting processing in which the values of DC control bits set in a recording frame are set to be coincident with user control data in response to the values of additional data component bits to be recorded on an information recording medium, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on selecting information in the DC-control-bit selecting step are selectively executed.

According to an embodiment, a computer program for executing processing for playing back information recorded on an information recording medium is provided. The computer program includes a data demodulating step of executing demodulating processing on data read from the information recording medium, and an additional data decoding step of executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information on the basis of the result of the determination of correspondence.

According to an embodiment, an information recording processor is provided which includes a DC-control-bit selecting unit for executing DC-control-bit selecting processing in which, when specific user control data selected from user control data to be recorded on an information recording medium is user control data including additional data, the values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data, and a modulated data generating unit for generating a modulated recording frame used as recording-unit data by executing processing for modulating data to be recorded and DC-control-bit setting processing, the modulated data generating unit selectively executing the DC-control-bit setting processing based on control of a digital sum variation and the DC-control-bit setting processing based on information input from the DC-control-bit selecting unit.

According to an embodiment, an information recording processor is provided which includes a DC-control-bit calculating unit for executing arithmetic processing using data included in specific user control data set in user control data to be recorded on an information recording medium, and additional data, and setting values obtained in the arithmetic processing as the values of DC control bits set in a DC-control-bit storage frame for specific user control data, and a modulated data generating unit for generating a modulated recording frame used as recording-unit data by executing processing for modulating data to be recorded and DC-control-bit setting processing, the modulated data generating unit selectively executing the DC-control-bit setting processing based on control of a digital sum variation and the DC-control-bit setting processing based on information input from the DC-control-bit selecting unit.

According to an embodiment, an information playback processor for executing processing for playing back information recorded on an information recording medium is provided. The information playback processor includes a data demodulating unit which executes demodulating processing on data read from the information recording medium, and an additional data decoding unit which executes determination of correspondence between DC control bits acquired from a DC-control-bit storage frame for specific user control data, and specific user control data, and determines, based on the result of the determination of correspondence, whether or not the user control data includes additional data, and which executes acquisition of the additional data on the basis of the result of the determination.

According to an embodiment, an information playback processor for executing processing for playing back information recorded on an information recording medium is provided. The information playback processor includes a data demodulating unit which executes demodulating processing on data read from the information recording medium, and an additional data decoding unit which executes arithmetic processing of DC control bits acquired from a DC-control-bit storage frame for specific user control data and specific user control data, and acquisition of additional data on the basis of the result of the arithmetic processing.

According to an embodiment, an information recording medium is provided which has a data recording configuration in which information indicating whether additional data is included in specific user control data selected from user control data included in recorded data is analyzable based on the values of DC control bits set in a DC-control-bit storage frame for specific user control data.

According to an embodiment, an information recording medium is provided which has a configuration in which bit information is recorded as the values of DC control bits set in a DC-control-bit storage frame for specific user control data, the bit information being calculated as the result of arithmetic processing using information of bits in specific user control data selected from user control data included in recorded data and information of additional data component bits.

According to an embodiment, an information recording method is provided which includes a DC-control-bit selecting step of executing DC-control-bit selecting processing in which, when specific user control data selected from user control data to be recorded on an information recording medium is user control data including additional data, the values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from the DC-control-bit selecting unit are selectively executed.

According to an embodiment, an information recording method is provided which includes a DC-control-bit calculating step for executing arithmetic processing using data included in specific user control data set user control data to be recorded on an information recording medium, and additional data, and setting calculated values as the values of DC control bits set in a DC-control-bit storage frame for specific user control data, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from the DC-control-bit selecting unit are selectively executed.

According to an embodiment, an information playback method for executing processing for playing back information recorded on an information recording medium is provided. The information playback method includes a data demodulating step of executing demodulating processing on data read from the information recording medium, and an additional data decoding step in which determination of correspondence between DC control bits acquired from a DC-control-bit storage frame for specific user control data, and specific user control data is executed, and based on the result of the determination of correspondence, determination of whether or not the user control data includes additional data is performed, and in which acquisition of the additional data is executed based on the result of the determination.

According to an embodiment, an information playback method for executing processing for playing back information recorded on an information recording medium is provided. The information playback method includes a data demodulating step of demodulating processing on data read from the information recording medium, and an additional data decoding step of executing arithmetic processing of DC control bits acquired from a DC-control-bit storage frame for specific user control data and specific user control data, and acquisition of additional data on the basis of the result of the arithmetic processing.

According to an embodiment, a computer program for executing information recording processing is provided. The computer program includes a DC-control-bit selecting step for executing DC-control-bit selecting processing in which, when specific user control data selected from user control data to be recorded on an information recording medium is user control data including additional data, the values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from the DC-control-bit selecting unit are selectively executed.

According to an embodiment, a computer program for executing information recording processing is provided. The computer program includes a DC-control-bit calculating step for executing arithmetic processing using data included in specific user control data set user control data to be recorded on an information recording medium, and additional data, and setting calculated values as the values of DC control bits set in a DC-control-bit storage frame for specific user control data, and a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from the DC-control-bit selecting unit are selectively executed.

According to an embodiment, a computer program for executing processing for playing back information recorded on an information recording medium is provided. The computer program includes a data demodulating step of executing demodulating processing on data read from the information recording medium, and an additional data decoding step in which determination of correspondence between DC control bits acquired from a DC-control-bit storage frame for specific user control data, and specific user control data is executed, and based on the result of the determination of correspondence, determination of whether or not the user control data includes additional data is performed, and in which acquisition of the additional data is executed based on the result of the determination.

According to an embodiment, a computer program for executing processing for playing back information recorded on an information recording medium is provided. The computer program includes a data demodulating step of demodulating processing on data read from the information recording medium, and an additional data decoding step of executing arithmetic processing of DC control bits acquired from a DC-control-bit storage frame for specific user control data and specific user control-data, and acquisition of additional data on the basis of the result of the arithmetic processing.

As described above, an embodiment, additional data is set based on correspondence between bit values of specific user control data included in recording data to be recorded on an information recording medium and DC control bits set in the recording data. Thus, embedding of additional data that is difficult to analyze is realized.

In an embodiment, by executing selective processing in which the values of DC control bits set in a recording frame are set to be coincident with user control data in response to the values of additional data component bits to be recorded on the information recording medium, DC-control-bit selecting processing is performed. In addition, in information playback, by executing determination of correspondence between DC control bits for determining a response to additional data, the DC control bits being acquired from a DC-control-bit storage frame for determining a response to additional data, and user control data for determining a response to additional data, reading of the additional data can be performed.

As described above, additional data is set based on correspondence between bit values of specific user control data included in recorded data for an information recording medium and DC control bits set in the recorded data. Thus, embedding of additional data having high difficulty in analysis is realized.

According to an embodiment, when specific user control data is user control data including additional data, recording is performed so that specific-user-control-data storage bits are coincident with DC control bits set in a DC-control-bit storage frame for specific user control data. When the specific user control data is user control data which does not include additional data, recording is performed so that the specific-user-control-data storage bits are not coincident with the DC control bits set in a DC-control-bit storage frame for specific user control data. In playback processing, the bit values in the specific user control data are compared with the DC control bits set in the DC-control-bit storage frame for specific user control data. When both are coincident, specific-user-control-data storage data can be acquired as additional data.

According to an embodiment, calculation using specific-user-control-data storage data set in user control data to be recorded on an information recording medium and additional data, for example, XOR or XNOR, is executed, and calculated values are set as the values of DC control bits set in a DC-control-bit storage frame for specific user control data. In playback processing, by executing calculation using specific-user-control-data storage data, and DC control bits set in the specific user control data for specific user control data, additional data can be acquired.

In an embodiment, an information recording processor and information playback processor is provided in which content, whose copyright must be protected, is recorded on a recording medium, and in which additional data, such as key information for use in decrypting the content, key-generating information, content-playback control information, or copy-control information, must be embedded in a hardly analyzable form. In another embodiment, an information recording medium used therewith is provided.

Additional features and advantages of the present invention are described in, and will be apparent from, the following Detailed Description of the Invention and the figures.

### BRIEF DESCRIPTION OF THE FIGURES

FIG. 1 is a block diagram showing an information recording processor according to an embodiment.

FIG. 2 is a first illustration of processing in the modulated data generating unit in the information recording processor shown in FIG. 1.

FIG. 3 is a second illustration of processing in the modulated data generating unit in the information recording processor shown in FIG. 1.

FIG. 4 is an illustration of data in a transformation table for use in modulating processing in the information recording processor shown in FIG. 1.

FIGS. 5A and 5B are illustrations of processing executed in the recording-signal processing circuit in the information recording processor shown in FIG. 1.

FIG. 6 is an illustration of detailed configurations of a BIS block and a BIS cluster.

FIG. 7 is an illustration of the arrangement of user control data in a BIS block.

FIG. 8 is an illustration of the arrangement of user control data in a BIS cluster.

FIG. 9 is an illustration of processing for generating an ECC cluster based on the LDC cluster and a BIS cluster.

FIG. 10 is an illustration of the configurations of a DC-control-bit storage frame for determining a response to additional data and a DC-control-bit storage frame for specific user control data.

FIGS. 11A and 11B are illustrations of DC control bits in a DC-control-bit storage frame for determining a response to additional data which are set based on the values of additional data component bits.

FIG. 12 is an illustration of correspondence between DC control bits and user control data bits for determining a response to additional data, and additional data component bits.

FIG. 13 is an illustration of the configuration of a DC-control-bit storage frame for determining a response to additional data which is recorded on an information recording medium, and the configuration of a DC-control-bit storage frame for determining a response to additional data.

FIG. 14 is a flowchart illustrating an additional data recording process executed in the information recording processor according to an embodiment.

FIG. 15 is a block diagram showing an information playback processor according to an embodiment.

FIGS. 16A and 16b are block diagrams illustrating an example of processing in which additional data is applied in the information playback processor according to an embodiment.

FIG. 17 is a block diagram illustrating an example of processing in which additional data is applied in the information playback processor according to an embodiment.

FIG. 18 is a flowchart illustrating an additional data recording process executed in the information playback processor according to an embodiment.

FIG. 19 is a block diagram showing an information recording processor according to an embodiment.

FIG. 20 is a first illustration of processing in the modulated data generating unit in the information recording processor shown in FIG. 19.

FIG. 21 is a second illustration of processing in the modulated data generating unit in the information recording processor shown in FIG. 19.

FIG. 22 is an illustration of data in a transformation table for use in modulating processing in the information recording processor shown in FIG. 19.

FIGS. 23A and 23B are illustrations of processing executed in the recording-signal processing circuit in the information recording processor shown in FIG. 19.

FIG. 24 is an illustration of detailed configurations of a BIS block and a BIS cluster.

FIG. 25 is an illustration of the arrangement of user control data in a BIS block.

FIG. 26 is an illustration of the arrangement of user control data in a BIS cluster.

FIG. 27 is an illustration of processing for generating an ECC cluster based on the LDC cluster and a BIS cluster.

FIG. 28 is an illustration of the configurations of a DC-control-bit storage frame for specific user control data and specific user control data, and correspondence therebetween.

FIGS. 29A and 29B are illustrations of setting of DC control bits in a DC-control-bit storage frame for specific user control data.

FIG. 30 is an illustration of correspondence between specific user control data and additional data on the basis of coincidence and non-coincidence between DC control bits for specific user control data and specific user control data bits.

FIG. 31 is an illustration of a technique for setting different specific user control data items in clusters.

FIG. 32 is an illustration of the configurations of a DC-control-bit storage frame for specific user control data which is recorded on an information recording medium and specific user control data.

FIG. 33 is a flowchart illustrating an additional data recording process executed in the information recording processor according to an embodiment.

FIG. 34 is a block diagram showing an information playback processor according to an embodiment.

FIGS. 35A and 35B are illustrations of an example of processing in which additional data is applied in the information playback processor according to an embodiment.

FIG. 36 is a block diagram illustrating an example of processing in which additional data is applied in the information playback processor according to an embodiment.

FIG. 37 is a flowchart illustrating an additional data recording process executed in the information playback processor according to an embodiment.

FIG. 38 is a block diagram showing an information recording processor according to an embodiment.

FIG. 39 is an illustration of processing for recording additional data in an embodiment.

FIG. 40 is a flowchart illustrating an additional data recording process executed in the information recording processor according to an embodiment.

FIG. 41 is a block diagram showing an information playback processor according to an embodiment.

FIG. 42 is a flowchart illustrating the additional data recording process executed in the information playback processor according to an embodiment.

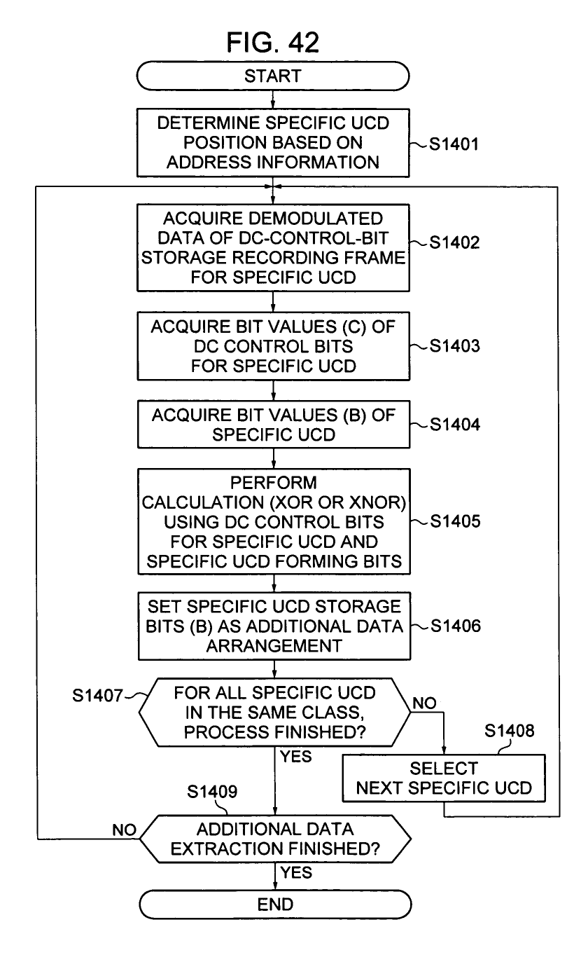

### DETAILED DESCRIPTION OF THE INVENTION

The present invention relates to information recording processors, information playback processors, methods therefor, and information recording media and computer programs used therewith. In particular, the present invention relates to an information recording processor, an information playback processor, and a method therefor in which, in a configuration capable of recording additional data, such as key information for use in decrypting content, content-playback control information, and copy-control information, on an information recording medium containing content, such as image data and music data, and reading the additional data, by setting additional data based on correspondence between the bit value of specific user control data (UCD) included in recorded data and DC control bits set in the recorded data, embedding of additional data that is difficult to analyze is realized. In addition, the present invention relates to a recording medium and computer program used with the information recording processor, the information playback processor, and the method therefor.

An information recording processor, information playback processor, and method therefor according to various embodiments and an information recording medium and computer used therewith are described below, in greater detail with reference to the accompanying drawings.

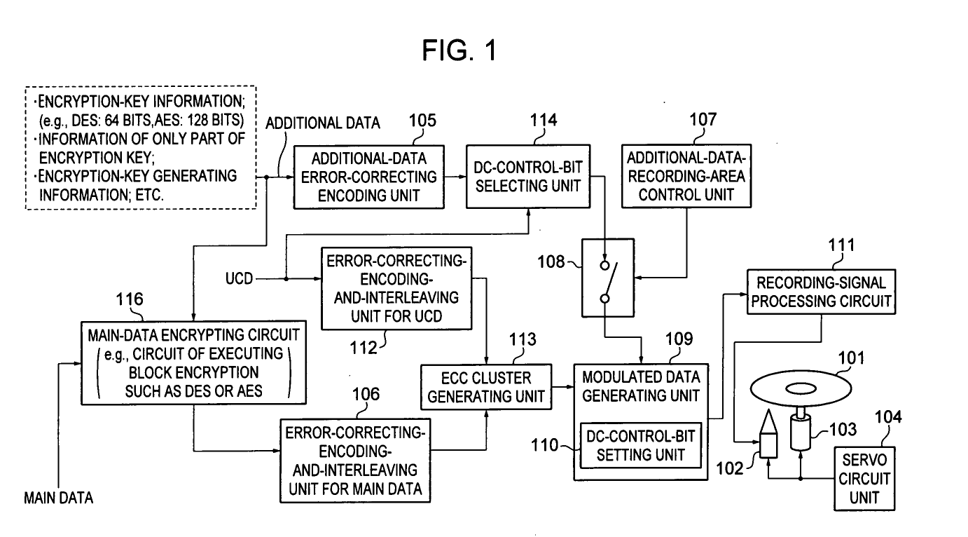

In an embodiment, the configuration and processing of the information recording processor are described with reference to FIG. 1.

The information recording processor described below includes a mastering apparatus that is an apparatus for producing a so-called “master disk”, and includes an apparatus having an information recording medium drive, which is usable by a general user, such as a DVD (digital versatile disk) recording/playback apparatus or a personal computer. In other words, the meaning of the information recording processor includes an information processing apparatus capable of recording data not only to a master disk, but also to various information recording media of recordable and rewritable types.

As shown in FIG. 1, the information recording processor includes an information recording medium 101 on which data can be recorded, a pickup 102 for outputting a data recording signal to the information recording medium 101, a spindle motor 103 for driving the information recording medium 101, a servo circuit 104 for controlling the pickup 102 and the spindle motor 103, an additional-data error-correcting encoding unit 105, an error-correcting-encoding-and-interleaving unit 106 for main data, an additional-data recording-area control unit 107, a switch 108, a modulated data generating unit 109, a DC-control-bit setting unit 110, a recording-signal processing circuit 111, an error-correcting-encoding-and-interleaving unit 112 for user control data, an ECC cluster generating unit 113, a DC-control-bit selecting unit 114, and a main-data encrypting circuit 116.

Recording data to be recorded on the information recording medium 101 includes main data formed by substantial data of data (such as content) to be played back, user control data (UCD) including various types of control data such as playback-control information, and additional data such as key information for use in decrypting content, content-playback control information, and copy-control information. The additional data is set as acquirable data based on correspondence between bit values of specific user control data and DC control bits set in the recording data.

The DC-control-bit selecting unit 114 executes selecting the values of DC control bits which are set in a DC-control-bit storage recording frame for determining a response to additional data. Specifically, the DC-control-bit selecting unit 114 performs DC-bit selecting processing in which, in response to the additional data component bit “0” or “1”, DC control bits to be set in a DC-control-bit storage recording frame for determining a response to additional data are set as bit values equal to the bit value (eight bits) of specific user control data, or as bit values being not equal to the bit value of the user control data. Details of the DC-bit selecting processing are described later.

Content data to be recorded on the information recording medium 101 is, for example, encrypted content data. The main data is encrypted by using an encryption key in the main-data encrypting circuit 116. The main-data encrypting circuit 116 generates encryption main data by receiving, for example, a 64-bit DES (data encryption standard) encryption key, 128-bit AES (advanced encryption standard) encryption key, information of a component of the encryption key, or a seed which is encryption-key generating information, and executing block-encryption processing, such as DES algorithm or AES algorithm, on the main data, such as content data, by using an encryption key generated based on the input information.

The encrypted main data is input to the error-correcting-encoding-and-interleaving unit 106. The error-correcting-encoding-and-interleaving unit 106 generates error-correcting codes and performs coding of the input data, and also performs interleaving processing. Details of these processes are described below.

The error-correcting-encoding-and-interleaving unit 112 generates error-correcting codes and performs coding of also on the user control data including the various types of control data, such as playback-control information, and performs interleaving processing.

The ECC cluster generating unit 113 generates ECC clusters based on the interleaving-processed main data and user control data, and the modulated data generating unit 109 receives the ECC clusters and executes modulating on the received ECC clusters. The modulated data generating unit 109 executes modulation based on the RLL (run length limited) (1, 7) modulation system in which modulation of two-bit data into three-bit data is basically performed.

In the modulation based on the (1, 7) RLL modulation system, data transformation is performed to produce modulated data in accordance with run-length limitation of (1, 7) RLL in which the number of consecutive 0's is a minimum of one and a maximum of seven. In this transformation processing, a transformation table is used. A specific example of using the transformation table is described later.

Based on modulated data based on the (1, 7) RLL system, a recording unit in which a synchronizing signal is set, which is called a “recording frame”, is generated and is recorded on the information recording medium 101 through the recording-signal processing circuit 111.

The modulating processing is performed after the DC-control-bit setting unit 110 selects “0” or “1” as each DC control bit for insertion so that the absolute value of a digital sum variation (DSV) decreases at regular intervals of the input main data.

The digital sum variation is a DC balance index of an NRZI (nonreturn to zero change on one) transformation signal generated as a recording signal for the information recording medium 101. Specifically, by totaling bits of a recording bit series (NRZI transformation signal), with each bit “0” as “−1”, and each bit “1” as “+1”, the total is obtained and is used as a digital sum variation. After the DC control bit “0” or “1” is selectively inserted so that the divergence of the digital sum variation from “0” is minimum, the modulating processing is performed. Details of the NRZI transformation processing are described later.

In an embodiment, in this DC control bit setting, for a selected specific recording frame, that is, a DC-control-bit storage recording frame for determining a response to additional data, bit values selected by the DC-control-bit selecting unit 114 is set as DC control bits without using DC-control-bit setting in accordance with the above rule. In other words, DC-bit setting is performed in which, in response to the additional data component bit “0” or “1”, DC control bits are set to have a bit string coincident with the bit values (eight bits) of specific user control data, or to have a bit string not coincident with the bit values. Information of the DC control bits is output from the DC-control-bit selecting unit 114 to the modulated data generating unit 109 through a switch 108 controlled by the additional-data recording-area control unit 107. Details of the DC-control-bit setting based additional data are described later.

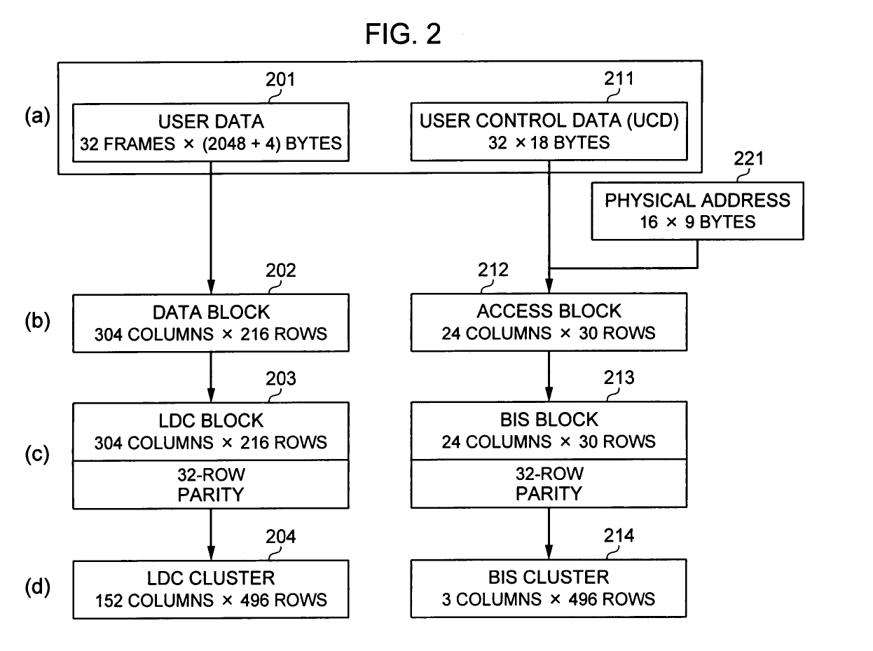

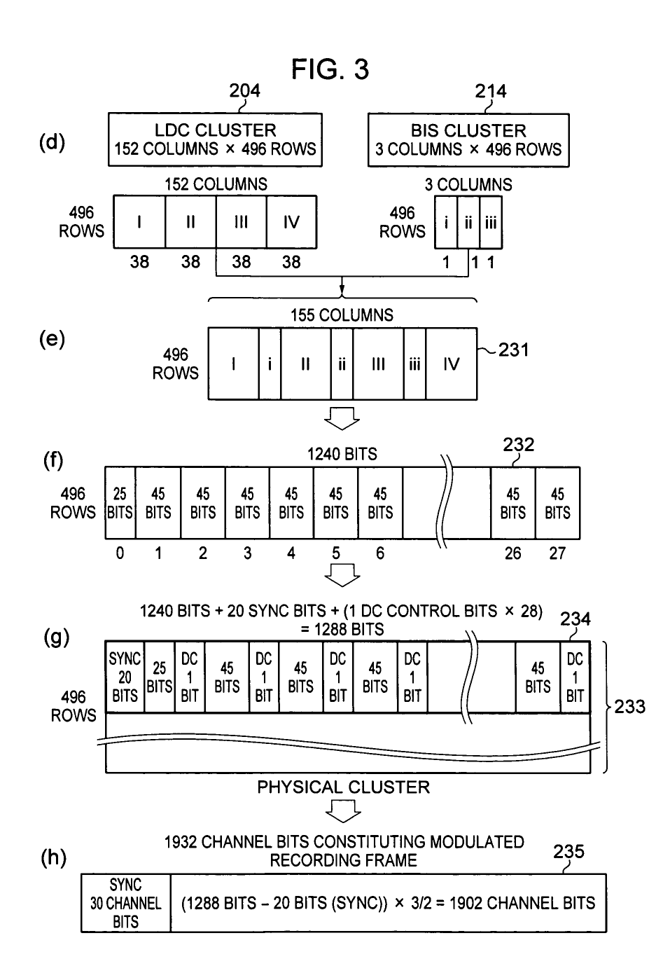

Details of ECC-cluster setting processing and modulated-data generating processing, which are based on main data and user control data, are described below, with reference to FIGS. 2 and 3.

The ECC-cluster setting processing and the modulated-data generating processing are executed by the error-correcting-encoding-and-interleaving unit 106, the error-correcting-encoding-and-interleaving unit 112, the ECC cluster generating unit 113, and the modulated data generating unit 109, which are shown in FIG. 1.

As shown in portion (a) of FIG. 2, the recording data is constituted by user data 201 as main data, and user control data 211. The user data 201 corresponds to the main data including the substantial data of data to be played back, such as content. The user control data 211 includes various types of control data such as playback-control information.

The user data 201 is set in 32-frame units, each consisting of 2048-byte data and 4-byte parity. The user control data 211 is formed by 32 units of 18-byte data.

Based on the user data 201, which has 32 frames by (2048+4) bytes, a data block 202 is formed. The data block 202 has an arrangement of 304 columns by 216 rows. One column by one row stores one-byte data (eight bits).

For the data block 202, an LDC block 203 is generated as a data block with parity of 32 rows added in each column. Interleaving processing on the LDC block 203 generates an LDC cluster 204 of 152 columns by 496 rows.

In addition, the user control data 211 is combined with physical address data 221 having 16 by 9 bytes to generate an access block 212 of 24 columns by 30 rows. After that, a BIS block 213 is generated as a data block in which parity of 32 rows is added in each column in the access block 212. Interleaving of the BIS block 213 generates a BIS cluster 214 of 3 columns by 496 rows.

Portion (d) of FIG. 3 shows data identical to that shown in portion (d) of FIG. 2, that is, the LDC cluster 204 of 152 columns by 496 rows which is generated based on the user data 201, and the BIS cluster 214 of 3 columns by 496 rows.

As shown in portion (d) of FIG. 3, the LDC cluster 204 of 152 columns by 496 rows is divided into four parts I to IV in 38-column units. The BIS cluster 214 of 3 columns by 496 rows is divided into three parts i to iii in column units. By combining the parts I to IV and the parts i to iii, the ECC cluster 231, shown in portion (e) of FIG. 3, of 155 columns by 496 rows is generated.

As shown in portion (f) of FIG. 3, the ECC cluster 231 is set as a cluster 232 partitioned into 28 parts 0 to 27. Only part 0 has 25 bits, and the other parts 1 to 27 each have 45 bits. The numbers of bits, shown in portion (f) of FIG. 3, are values per row.

As shown in portion (g) of FIG. 3, a 20-bit synchronizing (Sync) part is set. In addition, in the parts 0 to 27 shown in portion (f) of FIG. 3, a one-bit DC-control-bit part is set between two parts.

This sets a physical cluster 233 of [1240 bits+20 bits (Sync)+(1 DC-control bit×28)=1288 bits]×496 rows. Each row of the physical cluster 233 is used as a recording frame 234 which is a modulated-data generating unit.

The DC control bits are a DC balance index of an NRZI transformation signal generated as a recording signal for the information recording medium 101. Specifically, by totaling bits of a recording bit series (NRZI transformation signal), with each bit “0” as “−1”, and each bit “1” as “+1”, the total is obtained and is used as a digital sum variation. After the DC control bit “0” or “1” is selectively inserted so that the divergence of the digital sum variation from “0” is minimum, the modulating processing is performed.

As described above, in the present invention, in this DC control bit setting, for a selected specific recording frame, that is, a DC-control-bit storage recording frame determining a response to additional data, bit values selected by the DC-control-bit selecting unit 114 are set as DC control bits without using DC-control-bit setting in accordance with the above rule. In other words, DC-bit setting is performed in which, in response to the additional data component bit “0” or “1”, DC control bits are set to have a bit string coincident with the bit values (eight bits) of specific user control data, or to have a bit string not coincident with the bit values. Details of this processing are described below.

Modulating processing on a frame in which the DC control bits, that is, the recording frame 234 shown in portion (g) of FIG. 3 which is formed by 1288-bit data, is performed. In the modulating processing, 2-bit data is transformed into 3-bit data. This data transformation executes (1, 7) RLL data transformation that produces modulated data in accordance with run-length limitation in which the number of consecutive 0's is a minimum of one and a maximum of seven, whereby the modulated recording frame 235 is generated.

The modulated recording frame 235, shown in portion (h) of FIG. 3, has a total of 1932 channel bits consisting of 30 (synchronizing) channel bits (modulated data bits) and 1902 channel bits consisting of (1288−20) synchronizing bits×⅔.

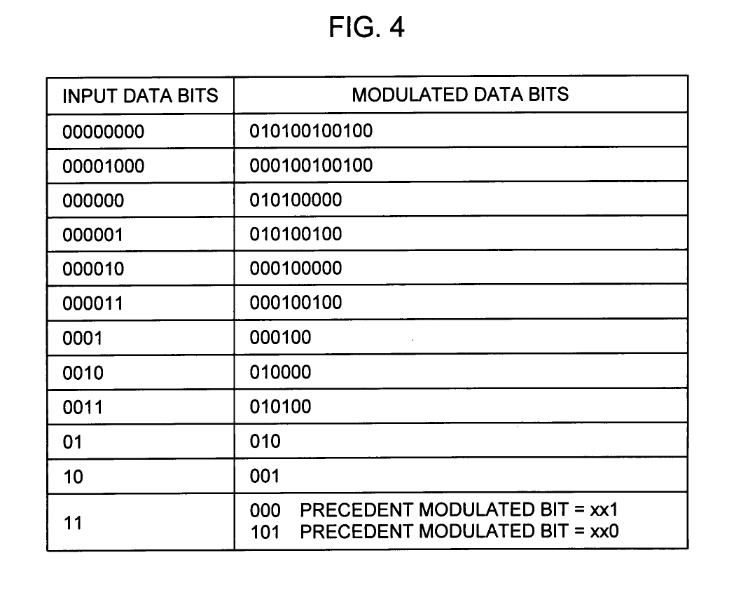

In the data modulating processing for transformation from 2-bit data to 3-bit data in accordance with the (1, 7) RLL run-length rule, a transformation table is used. A specific example of the transformation table is shown in FIG. 4.

As shown in FIG. 4, the transformation table indicates correspondence between strings of modulated data bits and corresponding strings of input bits. For example, when input data is “00000000”, a corresponding string of modulated data bits is “010100100100”. When input data is “11”, if precedent modulated data bits are “xx1”, corresponding modulated data bits are “000”, and if precedent modulated data bits are “xx0”, corresponding modulated data bits are “101”.

By using this transformation table to execute transformation from 2-bit data into 3-bit data, modulated data bits is generated in accordance with the (1, 7) RLL run-length rule.

Referring back to FIG. 1, the configuration and processing of the information recording processor is continuously performed as described below.

In the modulated data generating unit 109 shown in FIG. 1, the modulated data generating processing, described with reference to FIGS. 2 to 4, is executed, and the recording-signal processing circuit 111 generates a recording signal based on the generated modulated data.

The recording-signal processing circuit 111 generates a NRZI signal in which the polarity of each pulse is inverted in response to the value “0” or “1” of the modulated data generated in the modulated data generating unit 109. The recording-signal processing circuit 111 records the NRZI signal as a recording signal on the information recording medium 101.

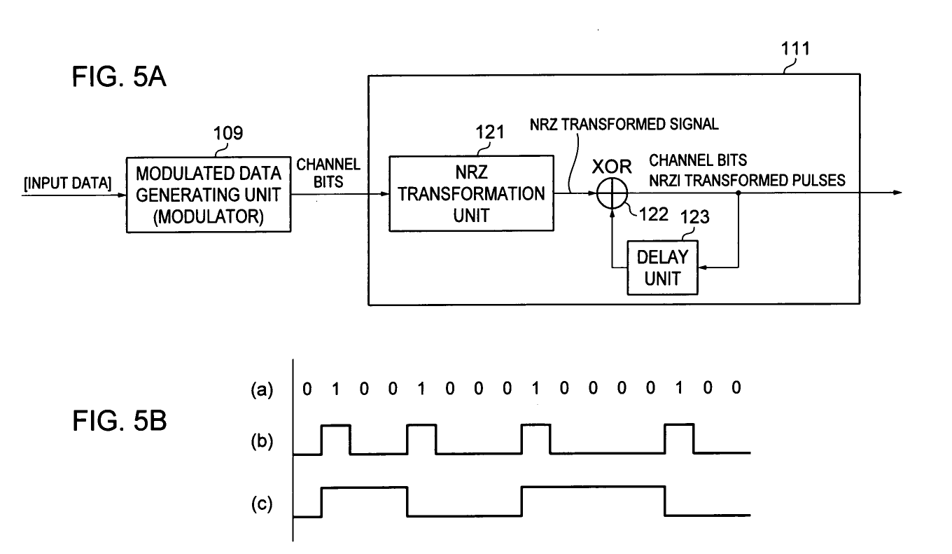

FIG. 5A shows the configuration of the recording-signal processing circuit 111 in which processing for generating the NRZI signal as a recording signal is executed. Channel bits output from the modulated data generating unit 109, which are modulated data bits, are input to the recording-signal processing circuit 111, which includes an NRZ transformation unit 121, an XOR 122, and a delay unit 123. In FIG. 5B, portion (a) shows channel bits, portion (b) shows an output signal from the NRZ transformation unit 121, and portion (c) shows NRZI transformed pulses which are finally output as a recording signal from the recording-signal processing circuit 111. The recording signal is output to the pickup 102, and recording information is recorded on the information recording medium 101 under the control of a servo circuit 104.

In an embodiment, additional data, such as key information for use in decrypting content, content-playback control information, and copy-control information, is set, as acquirable data, based on correspondence between specific user control data, that is, the bit values (8 bits) of user control data for additional data, and eight DC control bits included in a DC-control-bit storage recording frame for determining a response to additional data.

For example, in the above setting, when the 8-bit value of the specific user control data coincides with the eight DC control bits included in the DC-control-bit storage recording frame for determining a response to additional data, it is indicated that each bit forming the additional data is “0”, while, when the 8-bit value of the specific user control data does not coincide with the eight DC control bits included in the DC-control-bit storage recording frame for determining a response to additional data, it is indicated that each bit forming the additional data is “1”.

When modulation of the DC-control-bit storage recording frame for determining a response to additional data is executed in the modulated data generating unit 109, the additional-data recording-area control unit 107 shown in FIG. 1 controls the switch 108 to be on, so that the DC control bit values selected in the DC-control-bit selecting unit 114 are output to the modulated data generating unit 109.

At DC-control-bit setting positions for additional data in the DC-control-bit storage recording frame for determining a response to additional data, the modulated data generating unit 109 sets, not DC control bits having values determined based on the above DSV measurement, but the DC control bit value selected by the DC-control-bit selecting unit 114.

The configuration shown in FIG. 1 is shown in the form of a schematic block diagram illustrating the configuration and processing of the information recording processor according to the first embodiment of the present invention. For example, processing, such as control processing for DC control bits to be set for additional data, can be executed such that a controller, such as a central processing unit, executes a program describing a processing sequence. Accordingly, in the information recording processor according to the first embodiment, hardware corresponding to the switch and other component blocks shown in FIG. 1 is not essential. The processing for generating the recording frame is executable on hardware including a CPU, which serves as a controller for executing processing in accordance with a predetermined program, and as a data processor, and a memory as a means of storing parameters, etc.

Additional data is encryption-key information for use as an encryption key for encrypted content, information forming partial data of the encryption-key information, encryption-key generating information, such as the data (e.g., seed) required for generating an encryption key, secret information, such as a password, control information of various types, such as content-playback control information ad copy-control information, or a bit string of data (e.g., “0, 0, 0, 1, 0, 0, 0, . . . ”) forming content attribute information. This bit string includes error-correcting codes set for the additional data in the additional-data error-correcting encoding unit 105. In an embodiment, bit information forming the additional data bit string is set by the above-described configuration.

In other words, by setting, in the DC-control-bit storage recording frame for determining a response to additional data, a DC control bit string coincident with eight bits of specific user control data, it is indicated that the additional data component bit is “0”. In addition, by setting, in the DC-control-bit storage recording frame for determining a response to additional data, a DC control bit string which is not coincident with eight bits of specific user control data, it is indicated that the additional data component bit is “1”.

One form of setting may be employed between setting in which:
when UCD=“DC control bits”, “additional data bit”=“0”; and
when UCD≠“DC control bits”, “additional data bit”=“1”, and setting in which:
when UCD=“DC control bits”, “additional data bit”=“1”; and
when UCD e DC control bits, the additional data bit=“0”.

The configuration of additional data in the first embodiment of the present invention is described below.

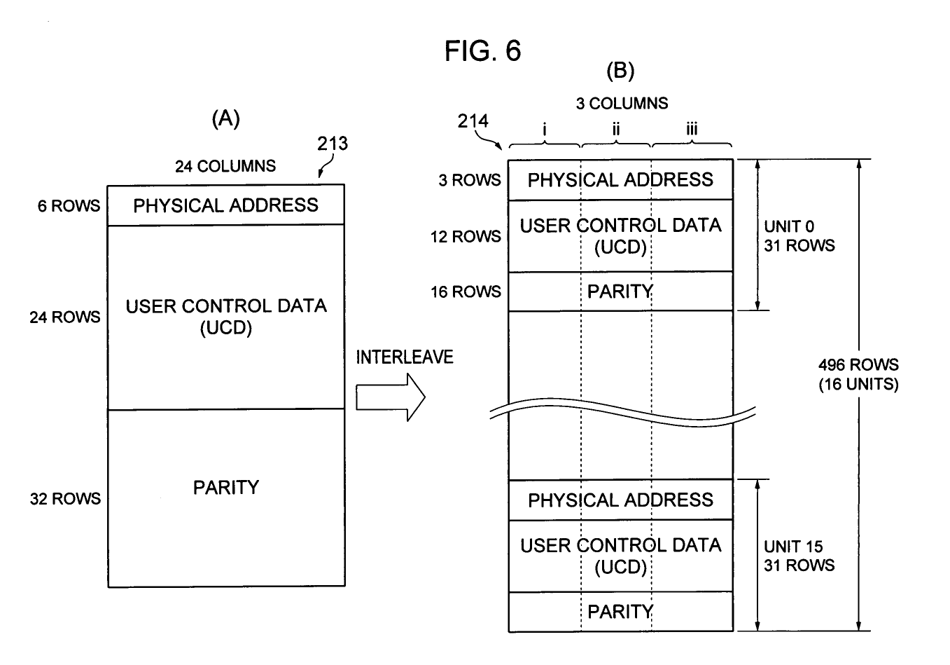

FIG. 6 shows details of the BIS block 213 and BIS cluster 214 generated based on the user control data 211 in the modulated data generating processing described with reference to FIGS. 2 and 3.

As described with reference to FIGS. 2 and 3, by combining the physical address data 221 of 16×9 bytes with the user control data 211, the access block 212 of 24 columns by 30 rows is generated. After that, the BIS block 213 is generated as a data block in which parity of 32 rows is added in each column. The generated block 213 is shown in portion (A) of FIG. 6.

By performing interleaving of the BIS block 213, the BIS cluster 214 of 3 columns by 496 rows is generated. The generated BIS cluster 214 is shown in portion (B) of FIG. 6.

As shown in portion (B) of FIG. 6, a 3-row physical address, 12-row user control data (UCD), and 16-row parity constitute one unit of 3 columns×31 rows. Sixteen units 0 to 15 constitute the BIS cluster 214 of 3 columns×496 rows.

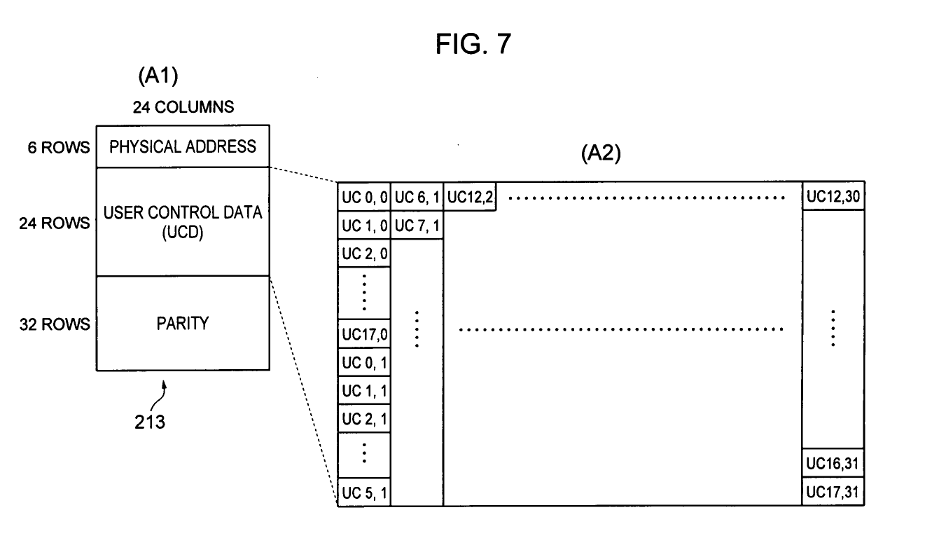

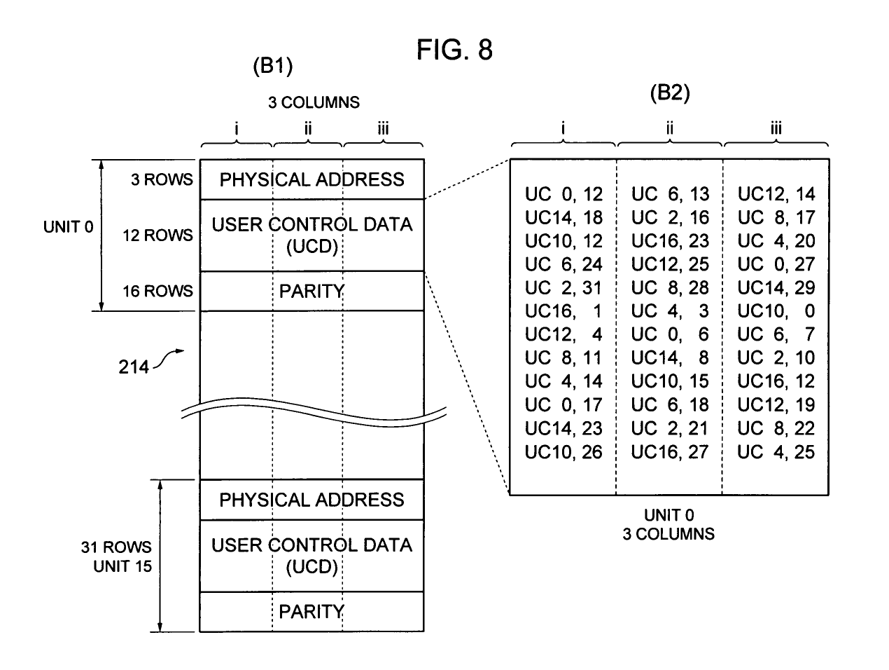

FIG. 7 shows details of the configuration in storage of the BIS block 213. FIG. 8 shows a detailed arrangement of user control data in the BIS cluster 214.

As shown in portion (Al) of FIG. 7, the BIS block 213 is constituted by a physical address of 24 columns×6 rows, user control data (UCD) of 24 columns×24 rows, and parity of 24 columns×32 rows.

As shown in portion (A2) of FIG. 7, the user control data (UCD) of 24 columns×24 rows is constituted by 576 (24×24) user-control-data-forming data items “UC 0,0” to “UC 17,31”, each data item having one byte (8 bits). By performing interleaving of the BIS block 213 having the user control data arrangement of 24 columns×24 rows, the BIS cluster 214 is generated.

As shown in portion (B1) of FIG. 8, the BIS cluster 214 has an arrangement of 3 columns×496 rows. A 3-row physical address and 12-row user control data (UCD), and 16-row parity constitute one unit of 3 columns×31 rows. Sixteen units 0 to 16 constitute the BIS cluster 214 of 3 columns×496 rows.

Portion (B2) of FIG. 8 shows user control data of 3 columns×12 rows in unit 0. The user control data in unit 0 stores 36 (=3×12) user-control-data-forming data items “UC 0,12” to “UC 4,25”, each data item having one byte (8 bits). Each of sixteen units 0 to 15 stores 36 (=3×12) user-control-data-forming data items. Accordingly, the BIS cluster 214 stores a total of 576 (=36×16) user-control-data-forming data items.

The user-control-data-forming data items stored in the BIS cluster 214 are arranged in distributed form in units 0 to 15 in the BIS cluster 214 by performing the interleaving of the BIS block 213 shown in portion (A2) of FIG. 7.

The user control data is set as a storage area for storing various types of information, such as content-playback control information, and its part is set as a reserve area or the like, in which arbitrary data can be written.

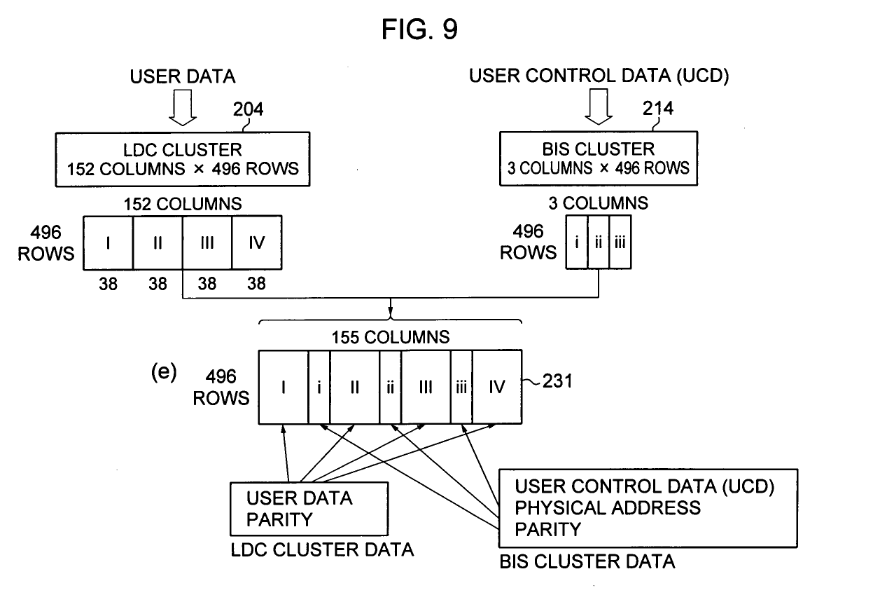

As shown in FIG. 9, each column of the BIS cluster 214 including the user control data is inserted among four-divided data items I to IV of the LDC cluster 204 set based on the user data such as content (as described with reference to FIGS. 2 and 3), whereby the ECC cluster 231 is generated.

As shown in FIG. 9, the ECC cluster 231 is set as a cluster in which a BIS cluster of 3 columns×496 rows is combined with an LDC cluster of 152 columns×496 rows.

As described with reference to FIG. 6, one of the physical address, the user control data, and the parity is set as each column of the BIS cluster. Therefore, the BIS cluster (i, ii, iii) included in each of 496 rows of the ECC cluster 231 is a type of data among a physical address, user control data, and parity.

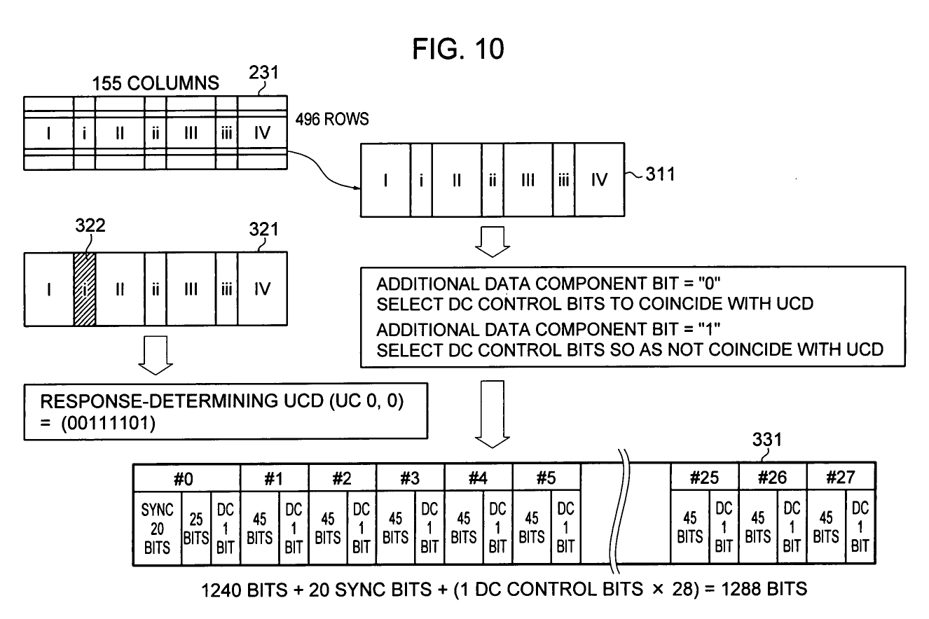

As shown in FIG. 10, a specific row selected from 496 rows constituting the ECC cluster 231 is set as:
(A) a DC-control-bit storage frame 311 for determining a response to additional data, or
(B) a UCD storing frame 321 for determining a response to additional data.
(A) The DC-control-bit storage frame 311 for determining a response to additional data is a frame storing the value of bits forming additional data such as an encryption key, and adjusted DC control bits having values determined based on user control data for determining a response to additional data. Part of the DC control bits set in the DC-control-bit storage frame 311 is determined by the DC-control-bit selecting unit 114 shown in FIG. 1 based on the value of bits forming additional data such as an encryption key, and user control data for determining a response to additional data.
(B) The UCD storing frame 321 for determining a response to additional data is a frame storing user control data for determining a response to additional data.

Although (A) the DC-control-bit storage frame 311 for determining a response to additional data and (B) the UCD storing frame 321 for determining a response to additional data may be set as separate frames, a single frame may be set both as the DC-control-bit storage frame 311 and as the UCD storing frame 321.

As shown in FIG. 10, in the UCD storing frame 321, user control data for use in determining a response to additional data, for example, the user control data “UC 0,0” formed by 8-bit data, is stored in user-control-data area (i) 322 which is a-BIS-cluster setting position.

It is assumed that the user control data “UC 0,0” formed by 8-bit data be set as user control data for determining a response to additional data. The user control data “UC 0,0” for determining a response to additional data has, for example, “00111101”.

In this case, among DC control bits to be stored in the DC-control-bit storage frame 311 for determining a response to additional data, eight bits (DC control bits) are adjusted. When the additional data component bit=“0”, eight bits (DC control bits) which are coincident with the 8-bit data “00111101” of “UC 0,0” is set. When the additional data component bit=“1”, eight bits (DC control bits) which are not coincident with the 8-bit data “00111101” of“UC 0,0” is set.

In the configuration shown in FIG. 1, the additional data is input to the additional-data error-correcting encoding unit 105. The additional-data error-correcting encoding unit 105 performs encoding for adding error-correcting codes to the input data. The additional data is encryption-key information for use as an encryption key for encrypted content, information forming part of the encryption-key information, encryption-key generating information such as the data (e.g., a seed) required for generating an encryption key, secret information such as a password, control information such as content playback control information or copy-control information, or other information such as content-attribute information.

A string of bits of the additional data having error-correcting codes added thereto is input to the DC-control-bit selecting unit 114. For example, the bit string “0, 0, 0, 1, 0, 0, 0, . . . ” is input. This bit string includes, for example, one type of additional data of encryption-key information, encryption-key generating information, content-playback control information, content copy control information, a password, and other content-attribute information, and the error-correcting codes set to the additional data by the additional-data error-correcting encoding unit 105.

Information of component bits of user control data for determining a response to additional data is input to the DC-control-bit selecting unit 114. For example, in the above example, the 8-bit data “00111101” of the user control data “UC 0,0” is input.

The DC-control-bit selecting unit 114 sequentially acquires, bit by bit, the bit string of the additional data having error-correcting codes added thereto. When the additional data component bit=“0”, the DC-control-bit selecting unit 114 selects DC control bit values so as to set DC control bits coincident with the 8-bit data “00111101” of the user control data “UC 0,0”, and outputs information of the selected DC control bit values to the modulated data generating unit 109 through the switch 108.

The modulated data generating unit 109 executes generating a DC-control-bit storage frame (for determining a response to additional data) having the DC control bit values input from the DC-control-bit selecting unit 114, and modulating the DC-control-bit storage frame.

The additional-data recording-area control unit 107 controls the switch 108 to be on with modulating-processing executing timing associated with the DC-control-bit storage frame so that the selected bit information from the DC-control-bit selecting unit 114 is output to the modulated data generating unit 109.

When executing processing for generating a frame other then the DC-control-bit storage frame for determining a response to additional data and modulating the frame, the switch 108 is controlled to be off. The DC-control-bit setting unit 110 executes normal DC-control-bit setting processing, that is, DC-control-bit setting processing based on digital-sum-variation measurement.

As shown in FIG. 10, in a DC-control-bit storage frame 331 for determining a response to additional data, synchronizing bits (20 bits) are set. In each of frame parts #0 to #27 each having 45 bits, one DC control bit is set.

As described above, the DC-control-bit storage frame 331 stores a total of 28 DC control bits in frame parts #0 to #27. Among these DC control bits, eight DC control bits are set as DC control bits for determining a response to additional data which are used to determine coincidence or non-coincidence with specific user control data, that is, user control data for determining a response to additional data.

The other DC control bits are set as DC control bits having bit values determined based on the normal bit-value setting processing, that is, digital-sum-variation measurement.

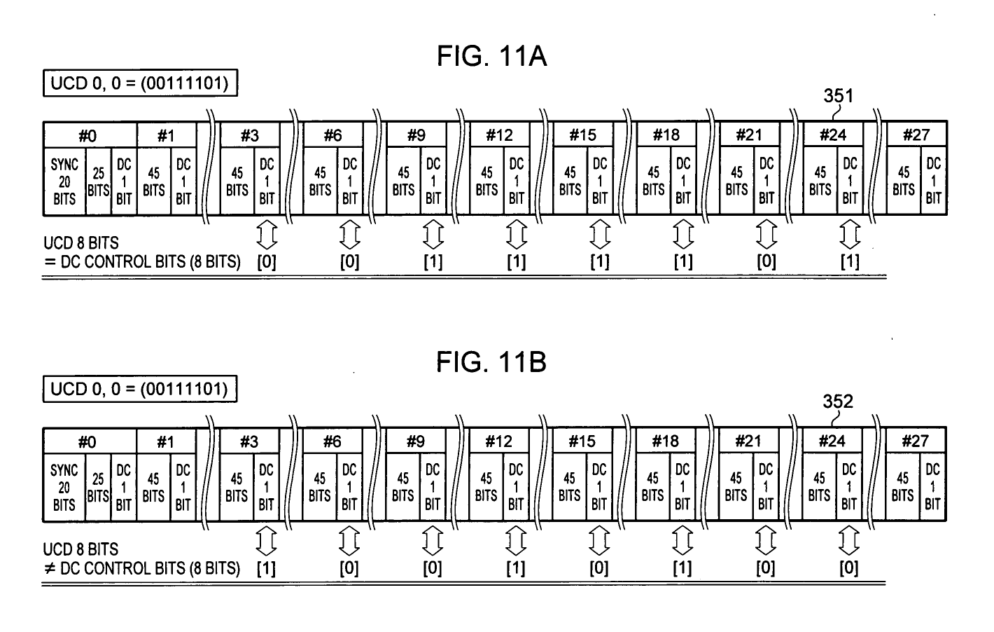

Details of the configuration of the DC-control-bit storage frame for determining a response to additional data are described below with reference to FIGS. 11A and 11B.

FIG. 11A shows details of the configuration of the DC-control-bit storage frame when the additional data component bit is “0”, and FIG. 11B shows details of the configuration of the DC-control-bit storage frame when the additional data component bit is “1”.

In this example, when the additional data component bit is “0”, DC control bits which are coincident with the bit values of user control data for determining a response to additional data are set in the DC-control-bit storage frame for determining a response to additional data. When the additional data component bit is “1”, DC control bits which are not coincident with the bit values of user control data for determining a response to additional data are set in the DC-control-bit storage frame for determining a response to additional data.

In FIG. 11A, the additional data component bit is “0”, and user control data for determining a response to additional data is the eight bits “00111101” of the user control data “UC 0,0”. In this case, the eight bits “00111101” are stored at response-determining DC-control-bit storage positions in the DC-control-bit storage frame for determining a response to additional data.

Here, the response-determining DC-control-bit storage positions in the DC-control-bit storage frame for determining a response to additional data are eight frame parts #3, #6, #9, #12, #15, #18, #21, and #24. The above response-determining DC-control-bit storage positions are examples. The DC control bits may be set at arbitrary positions. When valid playback-processing program is executed, from each bit position, a DC control bit is read. It is determined whether the read DC control bit is coincident with response-determining user control data, and the bit values of additional data are acquired. Details of the playback processing are described later.

In the example shown in FIG. 11B, the additional data component bit is “1”, and the user control data for determining a response to additional data is the eight bits “00111101” of the user control data “UC 0,0”. In this case, bits different from the eight bits “00111101” are stored at DC-control-bit storage positions (for determining a response to additional data) in a DC-control-bit storage frame 352 for determining a response to additional data, that is, frame parts #3, #6, #9, #12, #15, #18, #21, and #24. An arbitrary bit string may be used as the above eight DC control bits if different from the bits “00111101”. In the example shown in FIG. 11B, the bits “10010100” are stored at DC-control-bit storage positions in the DC-control-bit storage frame 352, that is, frame parts #3, #6, #9, #12, #15, #18, #21, and #24.

As described above, in an embodiment, part of user control data included in data recorded on a recording medium (disk) is set as user control data for determining a response to additional data, and depending on whether an additional data component bit is “0” or “1”, DC control bits set in a DC-control-bit storage frame for determining a response to additional data is controlled to be coincident with or not to be coincident with user control data for determining a response to additional data. By using a plurality of DC-control-bit storage frames for determining a response to additional data, additional data information, such as encryption-key information, is embedded.

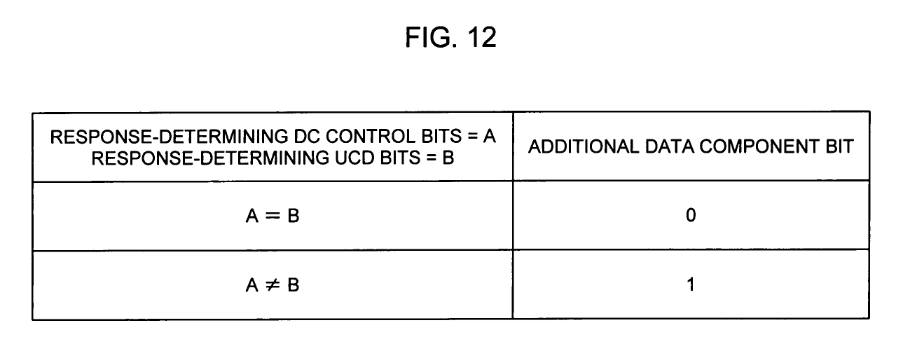

As FIG. 12 shows, in a case in which DC-control-bit information (8 bits) in the DC-control-bit storage frame for determining a response to additional data is represented by A, and bit information of user control data for determining a response to additional data is represented by B, when A=B, the additional data component bit=“0”, and when A≠B, the additional data component bit=“1”. Under these conditions, data recording and playback are executed.

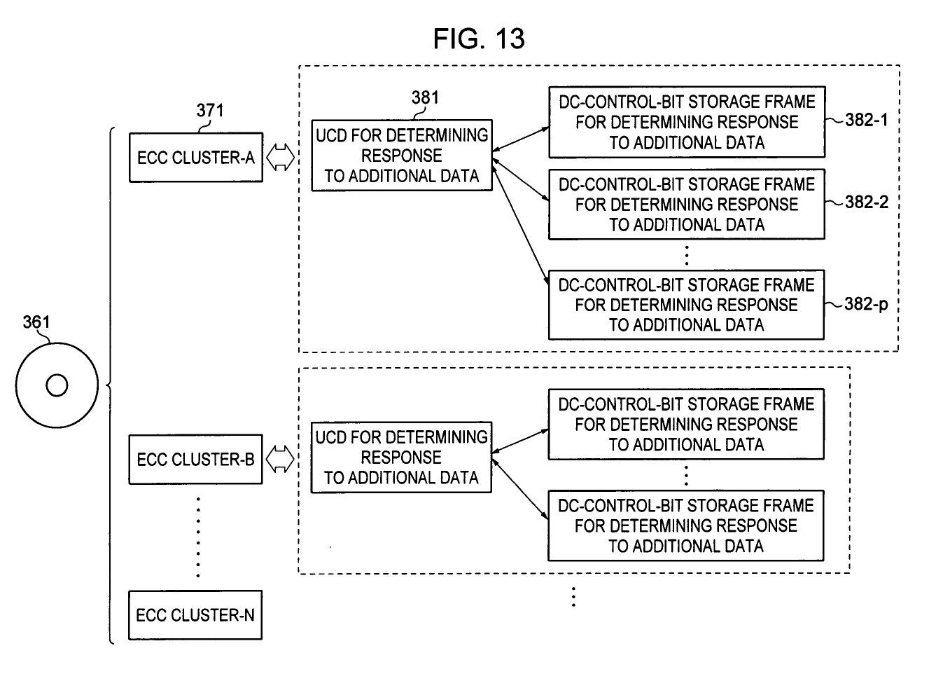

Additional data recording/storing processing, based on determination of correspondence between DC control bits (for determining a response to additional data) on a recording medium and user control data for determining a response to additional data, is described below with reference to FIG. 13.

On a recording medium (disk) 361, items of main data, such as content, and ECC clusters (see FIG. 3) generated based on user control data (UCD), such as control information, are set. Recording-data generating processing is executed in each cluster unit. A recording frame having DC control bits set therein is set, and a recording signal based on the recording frame is generated and recorded.

In the case of recording additional data in the configuration according to the first embodiment of the present invention, one user control data item for determining a response to additional data is set in, for example, an ECC cluster-A 371. For example, it is assumed that eight bits of the user control data “UC 0,0” are used as a user control data item included in the ECC cluster-A 371, and are set as user control data 381 for determining a response to additional data. In addition, a plurality of frames included in the ECC cluster-A 371 are set as DC-control-bit storage frames 382-1 to 382-P for determining a response to additional data. By sequentially comparing the p DC-control-bit storage frames 382 with the UCD bits of the user control data 381, and performing determination so that, when both have correspondence (coincidence), the additional data component bit=0, and when both have not correspondence (non-coincidence), the additional data component bit=1, additional-data-forming-bit information of p bits is acquired in one ECC cluster. In the case of a disk containing N ECC clusters, additional data of p×N bits can be stored.

Although FIG. 13 shows a case in which one user control data item for determining a response to additional data is set in one ECC cluster, a construction may be employed in which a plurality of user control data items for determining a response to additional data are set and a user control data item, which executes response determination, is changed in each DC-control-bit storage frame.

Based on information set beforehand, the additional-data recording-area control unit 107 shown in FIG. 1 identifies a DC-control-bit storage frame for determining a response to additional data. When the modulated data generating unit 109 performs modulating processing on the DC-control-bit storage frame, by changing over the switch 108, it controls the DC-control-bit selecting unit 114 to output the set values of DC control bits (for determining a response to additional data) included in the DC-control-bit storage frame to the modulated data generating unit 109.

Bit information of user control data for determining a response to additional data, and an additional data bit are input to the DC-control-bit selecting unit 114. When the additional data bit is “0”, bit values which are coincident with the bit information of the user control data for determining a response to additional data are selected as DC control bits and are output to the modulated data generating unit 109. When the additional data bit is “1”, bit values which are not coincident with the bit information of the user control data for determining a response to additional data are selected as DC control bits and are output to the modulated data generating unit 109.

Based on the bit values input from the DC-control-bit selecting unit 114, the modulated data generating unit 109 sets the input bit values at DC-control-bit setting positions for determining response to specific additional data in the DC-control-bit storage frame, and performs modulating processing.

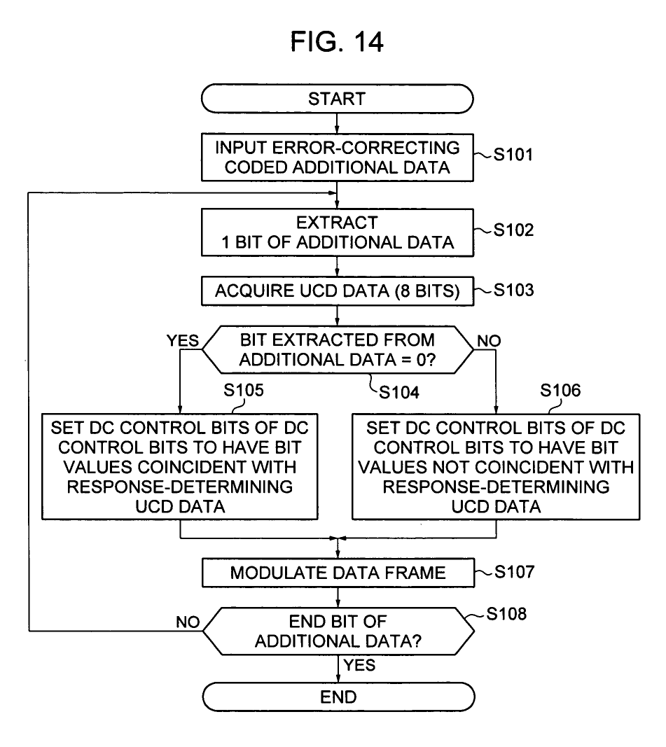

An additional data recording process executed in the information recording processor according to the first embodiment of the present invention is described below with reference to FIG. 14.

In step S101, error-correcting coded additional data is input. The input data is data output from the additional-data error-correcting encoding unit 105 shown in FIG. 1. The additional data is encryption-key information for use as an encryption key for encrypted content, information forming partial data of the encryption-key information, encryption-key generating information such as the data (e.g., a seed) required for generating an encryption key, secret information such as a password, control information such as content-playback control information or copy-control information, or other data. A bit string of additional data to which error-correcting codes are added, for example, the data string “0, 0, 0, 1, 0, 0, 0, . . . ” is input.

In step S102, from the input data string “0, 0, 0, 1, 0, 0, 0 . . . ”, each bit is sequentially extracted as a recording bit.

In step S103, bit information of user control data for determining a response to additional data is performed. The bit information is, for example, the 8-bit information “UC 0,0”.

In step S104, it is determined whether the additional data component bit acquired in step S102 is “0”.

When the additional data component bit is “0”, the process proceeds to step S105, and DC control bits set in the DC-control-bit storage frame for determining a response to additional data, for example, eight bits set in eight frame parts #3, #6, #9, #12, #15, #18, #21, and #24 are set to have values coincident with the bit values of the user control data acquired in step S103.

In step S104, when the additional data component bit is “1”, the process proceeds to step S106, and DC control bits set in the DC-control-bit storage frame for determining a response to additional data, for example, eight bits set in eight frame parts #3, #6, #9, #12, #15, #18, #21, and #24, are set to have values not coincident with the bit values of the user control data acquired in step S103.

Proceeding to step S107, the DC-control-bit storage frame for determining a response to additional data is modulated.

In step S103, it is determined whether processing on the end bit of the additional data has finished. If there is unprocessed data, steps S102 and the subsequent steps are repeatedly executed.

In step S108, if the process has determined that there is no unprocessed data, the process ends. In other words, in the above-described process, recording data in which the additional data bits are inserted is generated.

Although the flowchart in FIG. 14 shows only processing on the DC-control-bit storage frame for determining a response to additional data, for each frame other the DC-control-bit storage frame, a recording frame in which DC control bits based on digital-sum-variation measurement are set is generated and modulation thereof is performed. In addition, regarding eight bits set at positions for setting DC control bits for determining a response to additional data in the DC-control-bit storage frame for determining a response to additional data, that is, in eight frame parts #3, #6, #9, #12, #15, #18, #21, and #24, values selected in accordance with the above process are set as DC control bits. However, in frame parts other than the DC-control-bit storage frame, DC control bits based on digital-sum-variation measurement are set.

Positions at which DC control bits for determining a response to additional data are stored in the DC-control-bit storage frame are not limited to frame parts #3, #6, #9, #12, #15, #18, #21, and #24, but may be arbitrarily set.

In the above embodiment, all the eight bits of the user control data for determining a response to additional data are set as response-determining bits.

However, only part of the eight bits, for example, upper four bits may be used, as the response-determining bits. In this case, also the positions at which the DC control bits for determining a response to additional data are stored in the DC-control-bit storage frame are limited to only four positions.

The above embodiment describes an example of a process in which, depending on whether the bit values of the user control data for determining a response to additional data are coincident with the DC control bits in the DC-control-bit storage frame, it is determined whether the additional data component bit is “0”. However, when the bit values of the user control data for determining a response to additional data are coincident with the DC control bits in the DC-control-bit storage frame, the bit values itself of the user control data for determining a response to additional data may be set as additional data component bits.

In the case of the above setting, the DC-control-bit selecting unit 114 performs a process of changing the user control data (for determining a response to additional data) in response to additional data. According to the above-described construction, eight bits constituting one user control data item can be associated with the additional data.

Next, the configuration and playback processing of an information playback processor for performing a process of playing back an information recording medium containing the above-described additional data and content (main data) such as movie and music are described below.

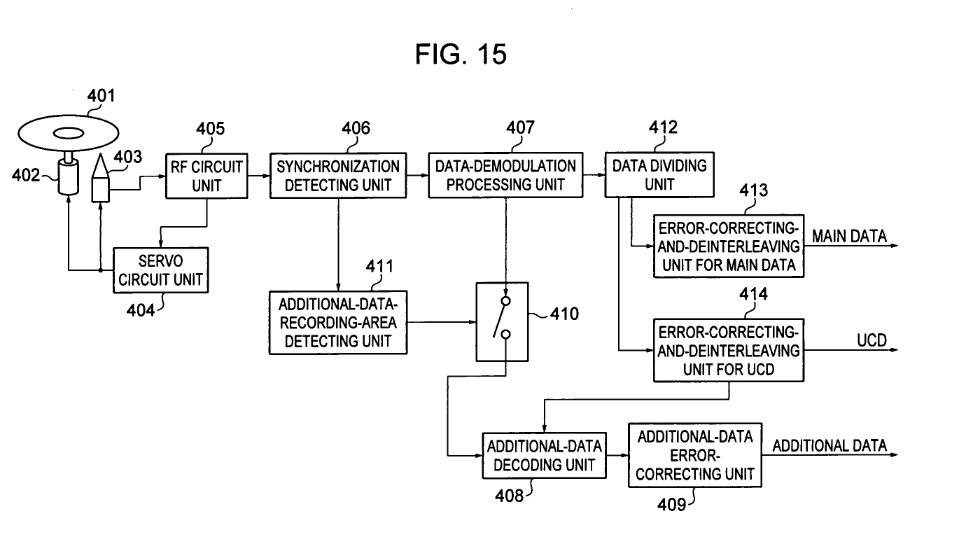

The configuration and process of the information playback processor are described with reference to FIG. 15.

The information playback processor includes an information recording medium 401, a pickup 403 for reading data from the information recording medium 401, a spindle motor 402 for driving the information recording medium 401, a servo circuit 404 for controlling the pickup 403 and the spindle motor 402, an RF circuit unit 405 for performing signal processing, such as gain adjustment of a read signal, and generating an RF signal, a synchronization detecting unit 406 for extracting a synchronizing signal from the RF signal, a data-demodulation processing unit 407 for. executing a data demodulating process, a switch 410 for outputting only an additional data area of a read signal from the information recording medium 401 to an additional-data decoding unit 408, an additional-data-recording-area detecting unit 411 for detecting the additional data area and controlling the switch 410, an additional-data decoding unit 408 for executing an additional data decoding process, a data dividing unit 412 which, based on demodulated data output from the data-demodulation processing unit 407, divides main data and user control data, an error-correcting-and-deinterleaving unit 413 for main data which performs error correction of main data and a deinterleaving process, an error-correcting-and-deinterleaving unit 414 for user control data which performs error correction of user control data and a deinterleaving process, and an additional-data error-correcting unit 409 for performing an additional-data error-correction process.

The content data recorded on the information recording medium 401 is, for example, encrypted content data. The additional data recorded on the information recording medium 401 is encryption-key information for use as an encryption key for encrypted content, information constituting part of the encryption-key information, encryption-key generating information such as the data (e.g., seed) required for generating an encryption key, secret information such as a password, control information such as content-playback control information or copy-control information, or other information such as content-attribute information.

Data read from the information recording medium 401 through the pickup 403 is processed (signal processing such as gain adjustment) in the RF circuit unit 405, and the processed signal is input to the synchronization detecting unit 406. The synchronization detecting unit 406 detects a synchronizing signal from the recorded signal and outputs the detected signal to the additional-data-recording-area detecting unit411.

Based on the synchronizing signal input from the synchronization detecting unit 406, the additional-data-recording-area detecting unit 411 identifies an additional data recording area and controls the switch 410 based on the identification information. By controlling the switch 410, a recording frame in the area required for decoding additional data, that is, an additional-data-set recording frame in which DC control bits based on the additional data are set, is input from the data-demodulation processing unit 407 to the additional-data decoding unit 408, which executes an additional data decoding process.

Based on the DC-control-bit storage frame for determining a response to additional data which is input from the data-demodulation processing unit 407 through the switch 410, and user control data for determining a response to additional data which is input from the error-correcting-and-deinterleaving unit 414 for user control data, the additional-data decoding unit 408 detects the correspondence between DC-control-bit information for determining a response to additional data and user-control-data-bit information, that is, whether both are coincident, and executes a decoding process for acquiring the additional data.

In other words, an additional-data-component-bit identifying process is performed in which, when the DC-control-bit information is coincident with the user-control-data-bit information, the additional data component bit=“0”, and when the DC-control-bit information is not coincident with the user-control-data-bit information, the additional data component bit=“1”.

As described above in the configuration of the information recording processor, in a case in which, when the DC control bits for determining a response to additional data is associated with the user control data for determining a response to additional data, that is, when there is coincidence between both, a recording process is performed with the eight bits of the user control data set as additional data component bits, the additional-data decoding unit 408 determines whether the DC control bits for determining a response to additional data is associated with the user control data for determining a response to additional data, and acquires, based on the affirmative determination, bits constituting the user control data as additional data component bits.

In the playback processor, when data processed by the data-demodulation processing unit 407 is a DC-control-bit storage frame for determining a response to additional data, the data of the frame is input to the additional-data decoding unit 408 through the switch 410. The additional-data decoding unit 408 acquires specific DC control bits of the DC-control-bit storage frame and executes a process of identifying additional data component bits on the basis of determination of coincidence with the user control data bits. While the data-demodulation processing unit 407 is executing processing the DC-control-bit storage frame, the additional-data-recording-area detecting unit 411 controls the switch 410 to be on.

By executing similar processing based on the additional-data-set recording frame, which is intermittently input, the additional-data decoding unit 408 acquires additional data such as n-bit information used as key information, key-information generating information, content-playback control information, copy-control information, or other content-attribute information. As mentioned in the above description of the information recording processor, the additional data includes error-correcting codes. The additional data is output after the additional-data error-correcting unit 409 performs error correction.

When the additional data is key information for use in, for example, content decryption, it is output to a decrypting processing unit for executing a content decrypting process. When the additional data is content-playback control information, it is output to a playback control unit.

In addition, ordinary data other than the additional data is output from the synchronization detecting unit 406 to the data-demodulation processing unit 407. By sequentially executing data conversion inverse to that described with reference to FIGS. 2 and 3, the data-demodulation processing unit 407 acquires playback data.

Based on demodulated data output from the data-demodulation processing unit 407, the DCT unit 412 divides the main data and the user control data. The error-correcting-and-deinterleaving unit error-correcting-and-deinterleaving unit 413 for main data executes error correction and the deinterleaving process on the main data. The error-correcting-and-deinterleaving unit 414 for user control data executes error correction and the deinterleaving process on the user control data, and outputs the processed user control data.

When the output main data is, for example, encrypted content, the encrypted content is decrypted by using an encryption key generatable based on key-generating information output as additional data, and the decrypted content is output through an output unit such as a display and a speaker.

The configuration shown in FIG. 15 is a schematic block diagram illustrating the configuration and process of the information playback processor according to the first embodiment of the present invention. For example, a process of acquiring a DC-control-bit storage frame for determining a response to additional data, and processes of acquiring and analyzing additional data can be executed such that a control unit, such as a CPU, executes a program describing the processes, etc. Therefore, in the information playback processor according to the first embodiment of the present invention, items of hardware which correspond to the switch 410 shown in FIG. 15 and component elements in the other blocks shown in FIG. 15 are not essential. On hardware including a control unit for executing processing in accordance with a predetermined program, a CPU used as a data processing unit, and a memory used for storing data and parameters, processes of acquiring and playing back additional data are executable.

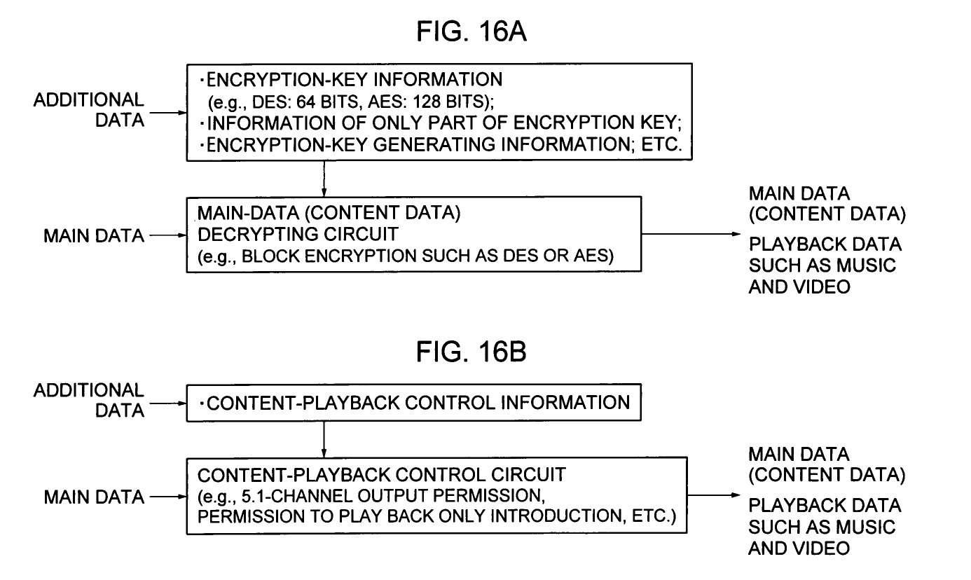

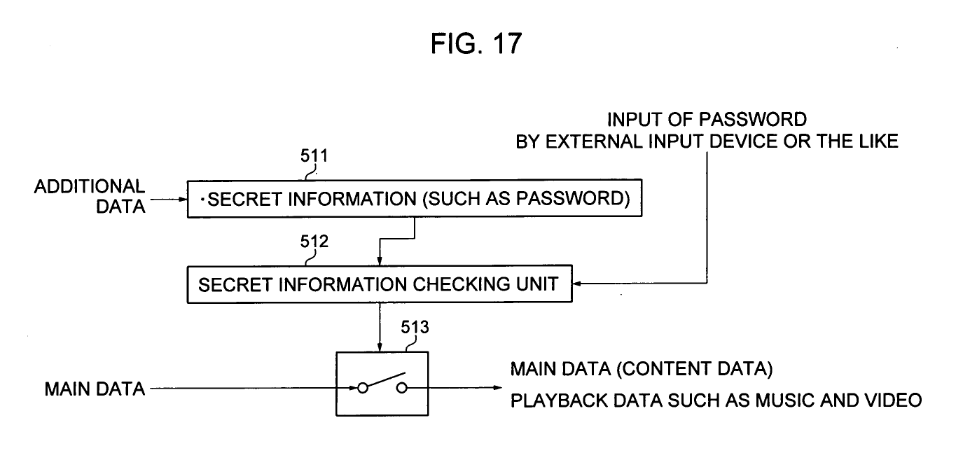

An application of the additional data acquired by the information playback processor is described below with reference to FIGS. 16A, 16B, and 17.

As described above, the additional data is, for example, encryption-key information for use as an encryption key for encrypted content, information forming part of the encryption-key information, encryption-key generating information such as the data (e.g., a seed) required for generating an encryption key, secret information such as a password, control information such as content playback control information or copy-control information, or other information such as content-attribute information.

FIG. 16A shows an example of processing in a case in which the additional data is encryption-key information for use as an encryption key for encrypted content, information forming part of the encryption-key information, or encryption-key generating information such as the data (e.g., a seed) required for generating an encryption key. The information playback processor uses the acquired encryption-key information to execute a main data decrypting process. This plays back content such as music and video. An encryption algorithm, such as DES or AES, is applied to the decrypting process.

FIG. 16B shows an example of a process in a case in which the additional data is content-playback control information corresponding to content recorded as the main data. In this case, control of playback of the main data (content) is executed in accordance with the content-playback control information acquired as the additional data. In the case of playing back the content, for example, control of a playback allowable range, such as output-form control such as 5.1-channel output control, and control of an introduction part of the content, are executed in accordance with the content-playback control information.

FIG. 17 shows an example of processing in a case in which the additional data is secret information such as a password, and content playback is allowed by checking the password. A password 511 is input as the additional data to a secret information checking unit 512. The secret information checking unit 512 compares the input password 511 with password information input from an external input device or the like. Only when both match each other does the secret information checking unit 512 set a switch 513 to be on. This allows the content as the main data, for example, data, such as music and video, to be played back.

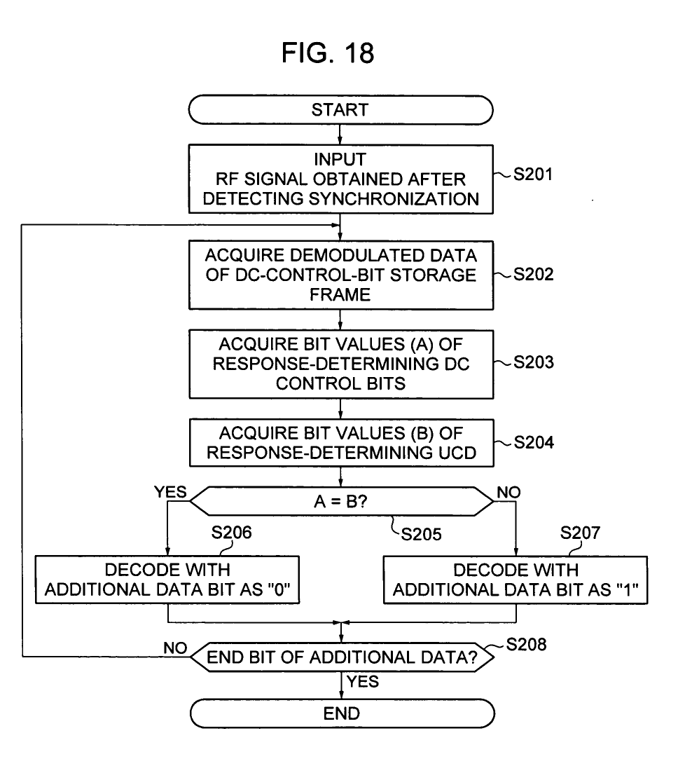

Next, a playback process including reading of the additional data is described below with reference to FIG. 18. The process shown in FIG. 18 is executed by the information playback processor shown in FIG. 15.

In step S201, an RF signal is generated based on the information recording medium 401. In step S202, demodulating processing based on the RF signal is executed. As data in the process of demodulation, demodulated data of the DC-control-bit storage frame for determining a response to additional data is acquired.

The additional-data-recording-area detecting unit 411 shown in FIG. 15 recognizes timing of demodulating the DC-control-bit storage frame, whereby the DC-control-bit storage frame is output from the data-demodulation processing unit 407 to the additional-data decoding unit 408.

In addition, in step S203, the additional-data decoding unit 408 acquires, from the DC-control-bit storage frame input from the data-demodulation processing unit 407, the value of DC control bits set at positions at which the DC control bits for determining a response to additional data are stored, for example, eight frame parts #3, #6, #9, #12, #15, #18, #21, and #24. The value of DC control bits is referred to as DC bit information A.

In step S204, the additional-data decoding unit 408 acquires user control data for determining a response to additional data from the error-correcting-and-deinterleaving unit 414. The acquired user control data is referred to as UCD bit information B.

In step S205, the additional-data decoding unit 408 determines whether the relationship “DC bit information A”=“UCD bit information B” holds.

When the relationship “DC bit information A”=“UCD bit information B” holds, in step S206, it is determined that the additional data bit=0.

When the relationship “DC bit information A”=“UCD bit information B” does not hold, in step S207, it is determined that the additional data bit=1.

In step S208, it is determined whether the end bit of the additional data has been processed. If there is an unprocessed bit, step S202 and the subsequent steps are repeatedly executed, and the process ends when the end bit of the additional data has been processed.

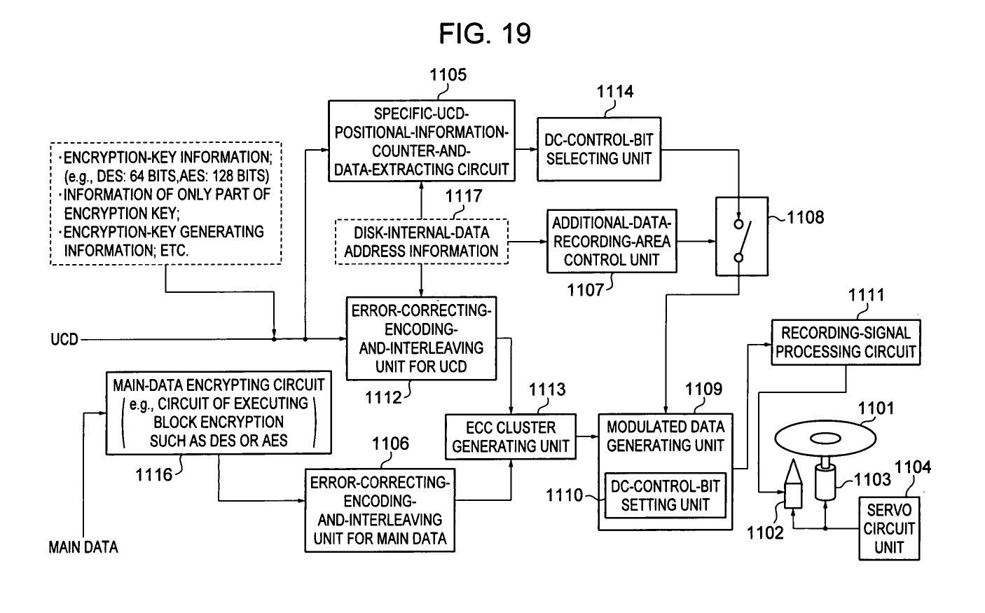

The configuration and processing of information recording processor according to an embodiment are described below with reference to FIG. 19.

The information recording processor described below includes a mastering apparatus that is an apparatus for producing a so-called “master disk”, and includes an apparatus having an information recording medium drive, which is usable by a general user, such as a DVD (digital versatile disk) recording/playback apparatus or a personal computer. In other words, the information recording processor includes an information processing apparatus capable of recording data not only to a master disk, but also to various information recording media of recordable and rewritable types.

As shown in FIG. 19, the information recording processor includes an information recording medium 1101 on which data can be recorded, a pickup 1102 for outputting a data recording signal to the information recording medium 1101, a spindle motor 1103 for driving the information recording medium 1101, a servo circuit 1104 for controlling the pickup 1102 and the spindle motor 1103, a specific-UCD-positional-information-counter-and-data-extracting circuit 1105, an error-correcting-encoding-and-interleaving unit 1106 for main data, an additional-data recording-area control unit 1107, a switch 1108, a modulated data generating unit 1109, a DC-control-bit setting unit 1110, a recording-signal processing circuit 1111, an error-correcting-encoding-and-interleaving unit 1112 for user control data, an ECC cluster generating unit 1113, a DC-control-bit selecting unit 1114, and a main-data encrypting circuit 1116.

Recording data to be recorded on the information recording medium 1101 includes main data formed by substantial data of data (such as content) to be played back, and user control data (UCD) including various types of control data such as playback-control information, and additional data such as encryption-key information for use as an encryption key for encrypted content, information forming partial data of the encryption-key information, encryption-key generating information, such as the data (e.g., seed) required for generating an encryption key, secret information such as a password, or control information such as content-playback information or copy-control information.

The additional data is set as acquirable data based on correspondence between bit values of specific user control data and DC control bits set in the recording data.

Content data to be recorded on the information recording medium 101 is, for example, encrypted content data. The main data is encrypted by using an encryption key in the main-data encrypting circuit 1116. The main-data encrypting circuit 1116 generates encryption main data by receiving, for example, a 64-bit DES (data encryption standard) encryption key, 128-bit AES (advanced encryption standard) encryption key, information of a component of the encryption key, or a seed which is encryption-key generating information, and executing block-encryption processing, such as DES algorithm or AES algorithm, on the main data, such as content data, by using an encryption key generated based on the input information.

The encrypted main data is input to the error-correcting-encoding-and-interleaving unit 1106. The error-correcting-encoding-and-interleaving unit 1106 generates error-correcting codes and performs coding of the input data, and also performs interleaving processing. Details of these processes are described below.

The error-correcting-encoding-and-interleaving unit 1112 generates error-correcting codes and performs coding of also on the user control data including the various types of control data, such as playback-control information, and performs interleaving processing.

In the configuration of the second embodiment, in at least one part of the user control data, data corresponding to additional data, such as the key information for use in decrypting content, content-playback control information, or copy-control information, or data for use in additional data derivation, is stored.

User control data which has a possibility of storing the additional data is called “specific user control data (UCD)”. Specific user control data has two states. In one state, the specific user control data stores additional data, and in the other state, the specific user control data stores no user control data. Based on correspondence between bits (eight bits) stored in specific user control data and DC control bits set in a DC-control-bit storage frame (for determining response to specific user control data) which is included in the recording data, it is determined whether the specific user control data stores additional data. Details of this determination are described later.

The specific-UCD-positional-information-counter-and-data-extracting circuit 1105 includes a circuit that counts storage positions or storage-start positions of specific user control data in units of “clusters”, each of which is a constitutional unit of user control data, on the basis of disk-internal-data address information 1117.

The DC-control-bit selecting unit 1114 executes bit-value selecting processing on DC control bits set in a frame (DC-control-bit storage frame for specific user control data) designated by bit information of additional-data-information storing user control data and an address representing an additional data storage position or storage-start position, which are input from the specific-UCD-positional-information-counter-and-data-extracting circuit 1105.

Specifically, the component bit “0” or “1” of the additional data stored in specific user control data storing the additional data, and a DC control bit set in the DC-control-bit storage frame for specific user control data are set to be equal. In addition, in the case of specific user control data storing no additional data, DC-control-bit selecting processing is executed in order to the bit values of the specific user control data and the DC control bit set in the DC-control-bit storage frame for specific user control data are set to differ. Details of the processing are described later.

The ECC cluster generating unit 1113 generates ECC clusters based on the interleaving-processed main data and user control data, and the modulated data generating unit 1109 receives the ECC clusters and executes modulating on the received ECC clusters. The modulated data generating unit 1109 executes modulation based on the RLL (run length limited) (1, 7) modulation system in which modulation of two-bit data into three-bit data is basically performed.

In the modulation based on the (1, 7) RLL modulation system, data transformation is performed to produce modulated data in accordance with run-length limitation of (1, 7) RLL in which the number of consecutive 0's is a minimum of one and a maximum of seven. In this transformation processing, a transformation table is used. A specific example of using the transformation table is described later.

Based on modulated data based on the (1, 7) RLL system, a recording unit in which a synchronizing signal is set, which is called a “recording frame”, is generated and is recorded on the information recording medium 1101 through the recording-signal processing circuit 1111.

The modulating processing is performed after the DC-control-bit setting unit 110 selects “0” or “1” as each DC control bit for insertion so that the absolute value of a digital sum variation (DSV) decreases at regular intervals of the input main data.

The digital sum variation is a DC balance index of an NRZI (nonreturn to zero change on one) transformation signal generated as a recording signal for the information recording medium 101. Specifically, by totaling bits of a recording bit series (NRZI transformation signal), with each bit “0” as “−1”, and each bit “1” as “+1”, the total is obtained and is used as a digital sum variation. After the DC control bit “0” or “1” is selectively inserted so that the divergence of the digital sum variation from “0” is minimum, the modulating processing is performed. Details of the NRZI transformation processing are described later.

In an embodiment, in the DC-control-bit setting, for a selected specific recording frame, that is, a DC-control-bit storage frame for specific user control data, DC control bits in accordance with the above rule are not set, but bits selected by the DC-control-bit selecting unit 1114 are set as DC control bits. In other words, processing is executed, such as setting of the additional data component bit “0” or “1” set in the user control data and a DC control bit set in the DC-control-bit storage frame for specific user control data to be equal or differ.

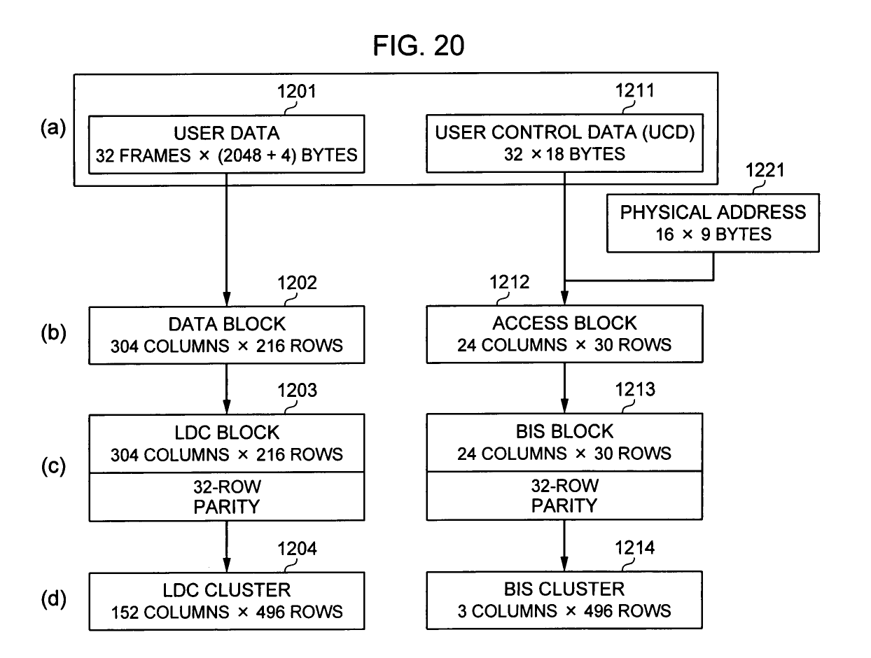

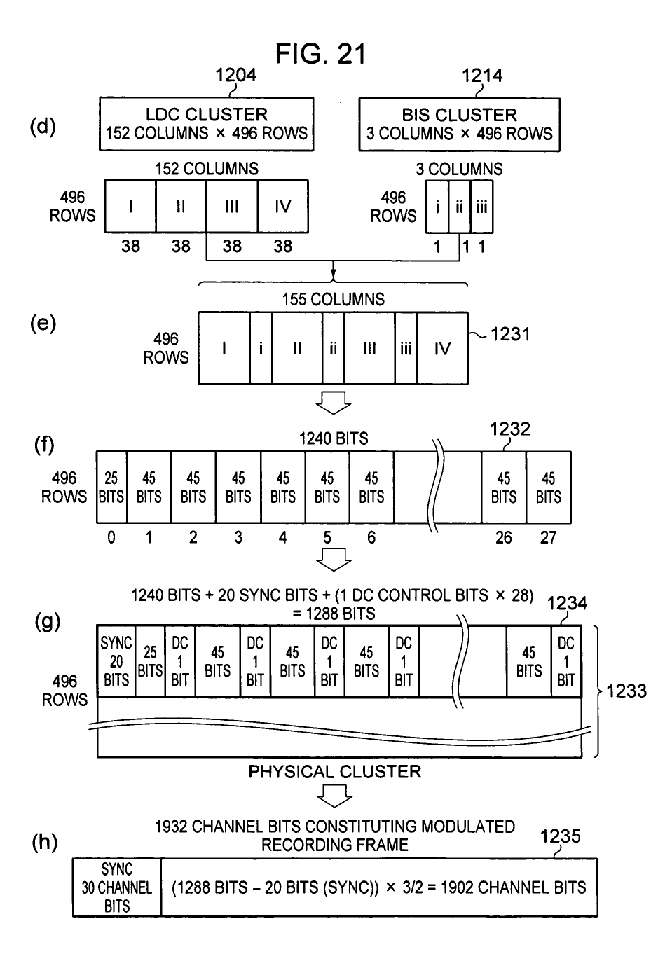

Details of ECC-cluster setting processing and modulated-data generating processing, which are based on main data and user control data, are described below with reference to FIGS. 20 and 21.

The ECC-cluster setting processing and the modulated-data generating processing are executed by the error-correcting-encoding-and-interleaving unit 1106, the error-correcting-encoding-and-interleaving unit 1112, the ECC cluster generating unit 1113, and the modulated data generating unit 1109, which are shown in FIG. 19.

As shown in portion (a) of FIG. 20, the recording data is constituted by user data 1201 as main data, and user control data 1211. The user data 1201 corresponds to the main data including the substantial data of data to be played back, such as content. The user control data 1211 includes various types of control data such as playback-control information.

The user data 1201 is set in 32-frame units, each consisting of 2048-byte data and 4-byte parity. The user control data 211 is formed by 32 units of 18-byte data.

Based on the user data 1201, which has 32 frames by (2048+4) bytes, a data block 1202 is formed. The data block 1202 has an arrangement of 304 columns by 216 rows. One column by one row stores one-byte data (eight bits).

For the data block 1202, an LDC block 1203 is generated as a data block with parity of 32 rows added in each column. Interleaving processing on the LDC block 1203 generates an LDC cluster 1204 of 152 columns by 496 rows.

In addition, the user control data 1211 is combined with physical address data 1221 having 16 by 9 bytes to generate an access block 1212 of 24 columns by 30 rows. After that, a BIS block 1213 is generated as a data block in which parity of 32 rows is added in each column in the access block 1212. Interleaving of the BIS block 1213 generates a BIS cluster 1214 of 3 columns by 496 rows.

Portion (d) of FIG. 21 shows data identical to that shown in portion (d) of FIG. 20, that is, the LDC cluster 1204 of 152 columns by 496 rows which is generated based on the user data 1201, and the BIS cluster 1214 of 3 columns by 496 rows.

As shown in portion (d) of FIG. 21, the LDC cluster 1204 of 152 columns by 496 rows is divided into four parts I to IV in 38-column units. The BIS cluster 1214 of 3 columns by 496 rows is divided into three parts i to iii in column units. By combining the parts I to IV and the parts i to iii, the ECC cluster 1231, shown in portion (e) of FIG. 21, of 155 columns by 496 rows is generated.

As shown in portion (f) of FIG. 21, the ECC cluster 1231 is set as a cluster 1232 partitioned into 28 parts 0 to 27. Only part 0 has 25 bits, and the other parts 1 to 27 each have 45 bits. The numbers of bits, shown in portion (f) of FIG. 21, are values per row.

As shown in portion (g) of FIG. 21, a 20-bit synchronizing (Sync) part is set. In addition, in the parts 0 to 27 shown in portion (f) of FIG. 21, a one-bit DC-control-bit part is set between two parts.

This sets a physical cluster 233 of [1240 bits+20 bits (Sync)+(1 DC-control bit×28)=1288 bits]×496 rows. Each row of the physical cluster 1233 is used as a recording frame 1234 which is a modulated-data generating unit.

The DC control bits are a DC balance index of an NRZI transformation signal generated as a recording signal for the information recording medium 1101. Specifically, by totaling bits of a recording bit series (NRZI transformation signal), with each bit “0” as “−1”, and each bit “1” as “+1”, the total is obtained and is used as a digital sum variation. After the DC control bit “0” or “1” is selectively inserted so that the divergence of the digital sum variation from “0” is minimum, the modulating processing is performed.

As described above, in an embodiment, in this DC control bit setting, for a selected specific recording frame, that is, a DC-control-bit storage recording frame determining a response to additional data, bit values selected by the DC-control-bit selecting unit 1114 are set as DC control bits without using DC-control-bit setting in accordance with the above rule. In other words, DC-bit setting is performed in which, in response to the additional data component bit “0” or “1”, DC control bits are set to have a bit string coincident with the bit values (eight bits) of specific user control data, or to have a bit string not coincident with the bit values. Details of this processing are described below.

Modulating processing on a frame in which the DC control bits, that is, the recording frame 234 shown in portion (g) of FIG. 21 which is formed by 1288-bit data, is performed. In the modulating processing, 2-bit data is transformed into 3-bit data. This data transformation executes (1, 7) RLL data transformation that produces modulated data in accordance with run-length limitation in which the number of consecutive 0's is a minimum of one and a maximum of seven, whereby the modulated recording frame 1235 is generated.

The modulated recording frame 235, shown in portion (h) of FIG. 21, has a total of 1932 channel bits consisting of 30 (synchronizing) channel bits (modulated data bits) and 1902 channel bits consisting of (1288−20) synchronizing bits×⅔.

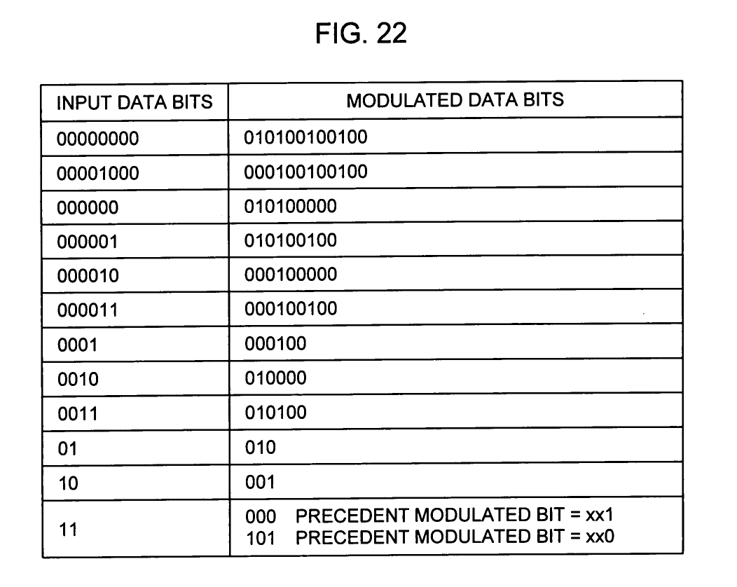

In the data modulating processing for transformation from 2-bit data to 3-bit data in accordance with the (1, 7) RLL run-length rule, a transformation table is used. A specific example of the transformation table is shown in FIG. 22.

As shown in FIG. 22, the transformation table indicates correspondence between strings of modulated data bits and corresponding strings of input bits. For example, when input data is “00000000”, a corresponding string of modulated data bits is “010100100100”. When input data is “11”, if precedent modulated data bits are “xx1”, corresponding modulated data bits are “000”, and if precedent modulated data bits are “xx0”, corresponding modulated data bits are “101”.

By using this transformation table to execute transformation from 2-bit data into 3-bit data, modulated data bits is generated in accordance with the (1, 7) RLL run-length rule.

Referring back to FIG. 19, the configuration and processing of the information recording processor according to the second embodiment of the present invention is continuously performed below.

In the modulated data generating unit 1109 shown in FIG. 19, the modulated data generating processing, described with reference to FIGS. 20 to 22, is executed, and the recording-signal processing circuit 1111 generates a recording signal based on the generated modulated data.

The recording-signal processing circuit 1111 generates a NRZI signal in which the polarity of each pulse is inverted in response to the value “0” or “1” of the modulated data generated in the modulated data generating unit 1109. The recording-signal processing circuit 1111 records the NRZI signal as a recording signal on the information recording medium 1101.

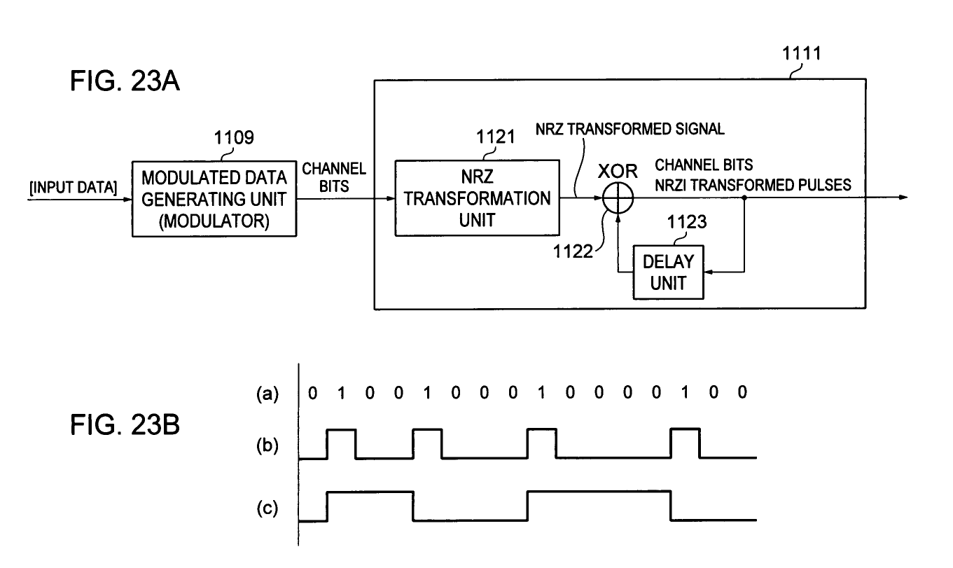

FIG. 23A shows the configuration of the recording-signal processing circuit 1111 in which processing for generating the NRZI signal as a recording signal is executed. Channel bits output from the modulated data generating unit 1109, which are modulated data bits, are input to the recording-signal processing circuit 1111, which includes an NRZ transformation unit 1121, an XOR 1122, and a delay unit 1123. In FIG. 23B, portion (a) shows channel bits, portion (b) shows an output signal from the NRZ transformation unit 121, and portion (c) shows NRZI transformed pulses which are finally output as a recording signal from the recording-signal processing circuit 1111. The recording signal is output to the pickup 1102, and recording information is recorded on the information recording medium 1101 under the control of a servo circuit 1104.

In the construction of the second embodiment, additional data, such as key information for use in decrypting content, content-playback control information, and copy-control information, is stored in specific user control data.

For example, the 8-bit value of specific user control data is set as a component bit value of key information for use in decrypting content, content-playback control information, copy-control information, and the like.

When the eight bits of the specific user control data are equal to the values of eight DC control bits included in the DC-control-bit storage frame for specific user control data, the eight bits of the specific user control data are additional data component bits. When the eight bits of the specific user control data are not equal, they are not additional data component bits.

In data recording, when specific user control data, that is, eight bits of specific user control data are additional data such as encryption-key information, the values of eight DC control bits included in a DC-control-bit storage frame for specific user control data are adjusted to be equal to the eight bit values of specific user control data before a recording frame is set. When the eight bits of specific user control data are not additional data such as encryption-key information, the values of eight DC control bits included in a DC-control-bit storage frame for specific user control data are adjusted to be not equal to the eight bit values of specific user control data before a recording frame is set and recorded.

By performing comparison with the values of eight DC control bits included in the DC-control-bit storage frame for specific user control data, the information playback processor for executing playback of content and playback of additional data determines whether the eight bits of specific user control data are information of bits constituting additional data. Specifically, when the eight bit values of specific user control data are equal to the values of eight DC control bits included in the DC-control-bit storage frame for specific user control data, it is determined that the eight bits of the specific user control data are information of bits constituting additional data. When eight bit values of specific user control data are not equal, it is determined that the eight bits of the specific user control data are not information of bits constituting additional data.

When modulation of the DC-control-bit storage recording frame for specific user control data is executed in the modulated data generating unit 1109, the additional-data recording-area control unit 1107 shown in FIG. 19 controls the switch 1108 to be on, so that the DC control bit value selected in the DC-control-bit selecting unit 1114 is output to the modulated data generating unit 1109.

At DC-control-bit setting positions for additional data in the DC-control-bit storage recording frame for specific user control data, the modulated data generating unit 1109 sets, not DC control bits having bit values determined based on the above DSV measurement, but the DC control bit values selected by the DC-control-bit selecting unit 1114.

The configuration shown in FIG. 19 is shown in the form of a schematic block diagram illustrating the configuration and processing of the information recording processor according to an embodiment. For example, processing, such as control processing for DC control bits to be set for specific user control data, can be executed such that a controller, such as a central processing unit, executes a program describing a processing sequence. Accordingly, in the information recording processor according to the first embodiment, hardware corresponding to the switch and other component blocks shown in FIG. 19 is not essential. The processing for generating the recording frame is executable on hardware including a CPU, which serves as a controller for executing processing in accordance with a predetermined program, and as a data processor, and a memory as a means of storing parameters, and the like.

Additional data is encryption-key information for use as an encryption key for encrypted content, information forming partial data of the encryption-key information, encryption-key generating information, such as the data (e.g., seed) required for generating an encryption key, secret information, such as a password, control information of various types, such as content-playback control information ad copy-control information, or a bit string of data (e.g., “0, 0, 0, 1, 0, 0, 0, . . . ”) forming content attribute information. This bit string includes error-correcting codes set for the additional data in the additional-data error-correcting encoding unit 1105. In the first embodiment of the present invention, bit information forming the additional data bit string is set by the above-described configuration.

In other words, by setting, in a DC-control-bit storage frame for specific user control data, a DC-control-bit string coincident with eight bits of specific user control data, the set eight bits are used as component bits of encryption-key generating information, secret information such as a password, control information such as copy-forgery-inhibited-pattern-image printing-setting information or copy-control information, or content-attribute information.

Specifically, when “specific user control data”=“DC control bits for specific user control data, “8 bits constituting specific user control data”=“additional data component bits”.

When “specific user control data”≠“DC control bits for specific user control data, “8 bits constituting specific user control data”≠“additional data component bits”.

The configuration of additional data in the second embodiment of the present invention is described below.

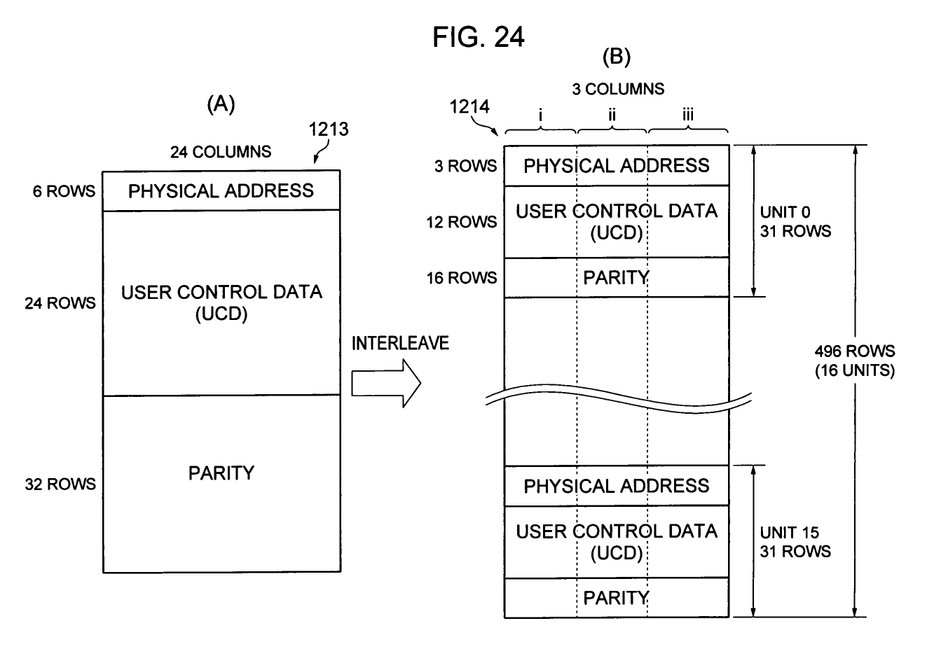

FIG. 24 shows details of the BIS block 1213 and BIS cluster 1214 generated based on the user control data 1211 in the modulated data generating processing described with reference to FIGS. 20 and 21.

As described with reference to FIGS. 20 and 21, by combining the physical address data 221 of 16×9 bytes with the user control data 1211, the access block 1212 of 24 columns by 30 rows is generated. After that, the BIS block 1213 is generated as a data block in which parity of 32 rows is added in each column. The generated block 1213 is shown in portion (A) of FIG. 24.

By performing interleaving of the BIS block 1213, the BIS cluster 1214 of 3 columns by 496 rows is generated. The generated BIS cluster 1214 is shown in portion (B) of FIG. 24.

As shown in portion (B) of FIG. 24, a 3-row physical address, 12-row user control data (UCD), and 16-row parity constitute one unit of 3 columns×31 rows. Sixteen units 0 to 15 constitute the BIS cluster 1214 of 3 columns×496 rows.

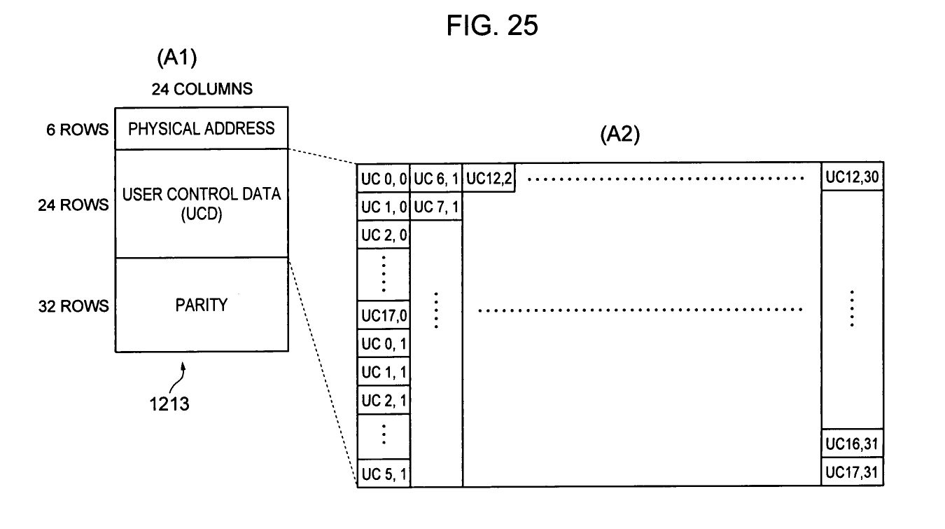

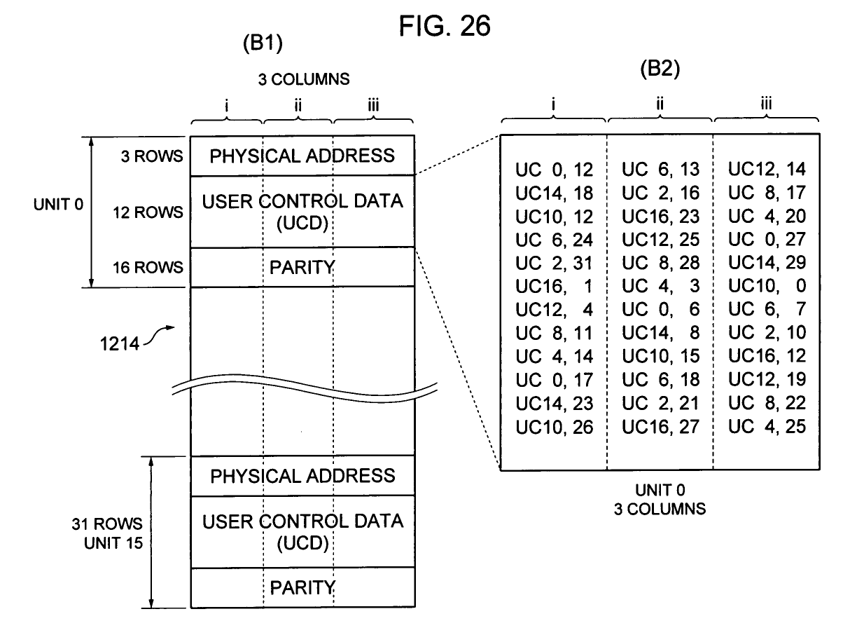

FIG. 25 shows details of the configuration in storage of the BIS block 1213. FIG. 26 shows a detailed arrangement of user control data in the BIS cluster 1214.

As shown in portion (A1) of FIG. 25, the BIS block 1213 is constituted by a physical address of 24 columns×6 rows, user control data (UCD) of 24 columns×24 rows, and parity of 24 columns×32 rows.

As shown in portion (A2) of FIG. 25, the user control data (UCD) of 24 columns×24 rows is constituted by 576 (24×24) user-control-data-forming data items “UC 0,0” to “UC 17,31”, each data item having one byte (8 bits). By performing interleaving of the BIS block 213 having the user control data arrangement of 24 columns×24 rows, the BIS cluster 1214 is generated.

As shown in portion (B1) of FIG. 26, the BIS cluster 1214 has an arrangement of 3 columns×496 rows. A 3-row physical address and 12-row user control data (UCD), and 16-row parity constitute one unit of 3 columns×31 rows. Sixteen units 0 to 16 constitute the BIS cluster 1214 of 3 columns×496 rows.

Portion (B2) of FIG. 26 shows user control data of 3 columns×12 rows in unit 0. The user control data in unit 0 stores 36 (3×12) user-control-data-forming data items “UC 0,12” to “UC 4,25”, each data item having one byte. Each of sixteen units 0 to 15 stores 36 (3×12) user-control-data-forming data items. Accordingly, the BIS cluster 1214 stores a total of (36×16) 576 user-control-data-forming data items.

The user-control-data-forming data items stored in the BIS cluster 1214 are arranged in distributed form in units 0 to 15 in the BIS cluster 214 by performing the interleaving of the BIS block 213 shown in portion (A2) of FIG. 25.

The user control data is set as a storage area for storing various types of information, such as content-playback control information, and its part is set as a reserve area or the like, in which arbitrary data can be written.

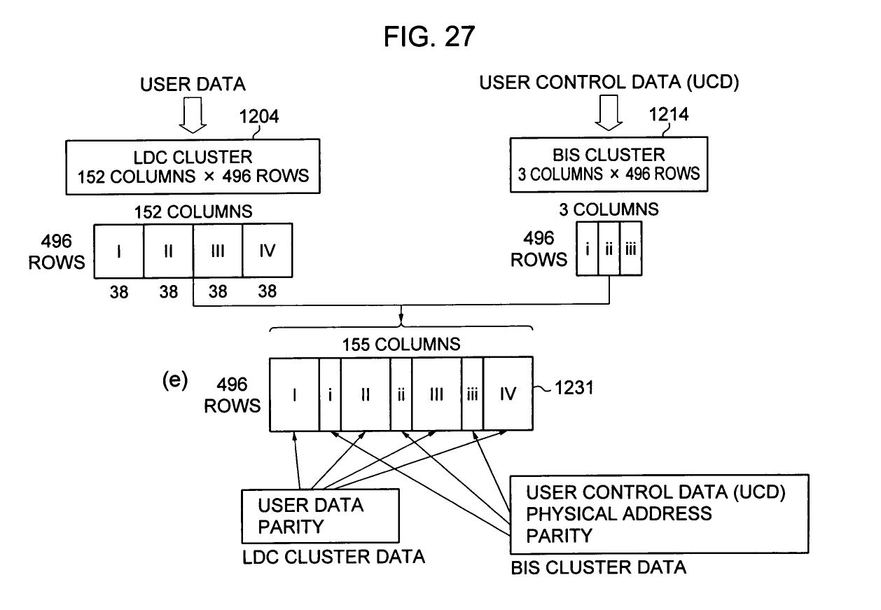

As shown in FIG. 27, each column of the BIS cluster 1214 including the user control data is inserted among four-divided data items I to IV of the LDC cluster 1204 set based on the user data such as content (as described with reference to FIGS. 20 and 21), whereby the ECC cluster 1231 is generated.

As shown in FIG. 27, the ECC cluster 1231 is set as a cluster a BIS cluster of 3 columns×496 rows is combined with an LDC cluster of 152 columns×496 rows.

As described with reference to FIG. 24, one of the physical address, the user control data, and the parity is set as each column of the BIS cluster. Therefore, the BIS cluster (i, ii, iii) included in each of 496 rows of the ECC cluster 231 is a type of data among a physical address, user control data, and parity.

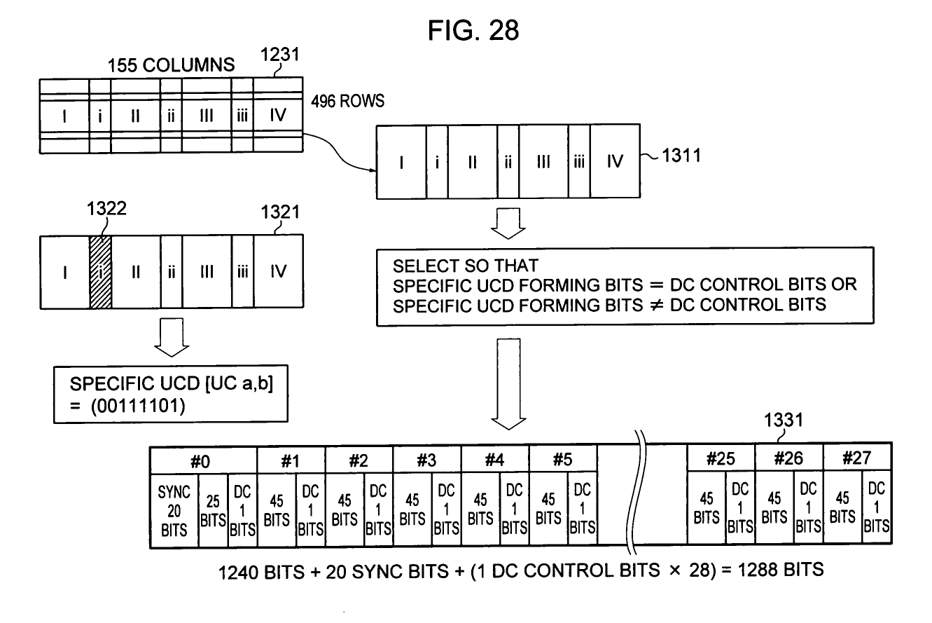

In an embodiment, as shown in FIG. 28, a specific row selected from 496 rows constituting the ECC cluster 231 is set as a DC-control-bit storage frame 1311 for specific user control data.

When specific user control data, for example, the data item “UC x,y” of the data items “UC 0,0” to “UC 17,31” shown in portion (A2) of FIG. 25, the values of eight DC control bits included in the DC-control-bit storage frame 1311 for specific user control data are set as bit values matching 8-bit data stored in the data item “UC x,y”, that is, correlated bit values.

As shown in FIG. 28, in a specific-user-control-data setting frame 1321, specific user control data, that is, specific user control data “UC a,b” storing 8-bit data, is stored in user-control-data area (i) 1322, which is a BIS cluster setting position.

A case in which the specific user control data “UC a,b” stores, for example, “00111101” as 8-bit data is described below.

When the eight bits “00111101” are additional data component bits, among the DC control bits stored in the DC-control-bit storage frame 1311 for specific user control data, eight DC control bits are adjusted to be equal to the eight bits “00111101” of the specific user control data “UC a,b”.

When the eight bits “00111101” of the specific user control data “UC a,b” are not additional data component bits, among the DC control bits stored in the DC-control-bit storage frame 1311 for specific user control data, eight DC control bits are adjusted to have different values from the values of the eight bits “00111101” of the specific user control data “UC a,b”.

In the example shown in FIG. 28, in one cluster, one DC-control-bit storage frame 1311 for specific user control data is set and the specific user control data “UC x,y” is set in one cluster. However, in order to set a plurality of DC-control-bit storage frames for specific user control data in one cluster, and associating the set frames with different specific user control data items “UC a,b”, “UC c,d”, and “UC e,f”, n specific user control data items may be set in one cluster, and additional data component bits composed of n×8 bits may be stored in one cluster.

In the configuration shown in FIG. 19, information of component bits of specific user control data is input to the DC-control-bit selecting unit 1114. For example, in the above example, the 8-bit data “00111101” of the specific user control data item “UC a,b” is input.

The DC-control-bit selecting unit 1114 selects the values of additional data component bits so that, when the component bits of the specific user control data are additional data component bits, among the DC control bits stored in the DC-control-bit storage frame 1311 for specific user control data, eight DC control bits are adjusted to have values equal to the values of eight bits “00111101” of the specific user control data item “UC a,b”, and so that the component bits of the specific user control data are not additional data component bits, among the DC control bits stored in the DC-control-bit storage frame 1311 for specific user control data, eight DC control bits are adjusted to have values different from the values of eight bits “00111101” of the specific user control data item “UC a,b”. The DC-control-bit selecting unit 1114 outputs information the selected values of the DC control bits to the modulated data generating unit 1109 through the switch 1108.

The modulated data generating unit 1109 executes generating a DC-control-bit storage frame (for specific user control data) having the DC control bit values input from the DC-control-bit selecting unit 1114, and modulating the DC-control-bit storage frame.

The additional-data recording-area control unit 1107 controls the switch 1108 to be on with modulating-processing executing timing associated with the DC-control-bit storage frame for specific user control data so that the selected bit information from the DC-control-bit selecting unit 1114 is output to the modulated data generating unit 1109.

When executing processing for generating a frame other then the DC-control-bit storage frame for user control data and modulating the frame, the switch 1108 is controlled to be off. The DC-control-bit setting unit 1110 executes normal DC-control-bit setting processing, that is, DC-control-bit setting processing based on digital-sum-variation measurement.

As shown in FIG. 28, in a DC-control-bit storage frame 331 for determining a response to additional data, synchronizing bits (20 bits) are set. In each of frame parts #0 to #27 each having 45 bits, one DC control bit is set.

As described above, the DC-control-bit storage frame 1331 stores a total of 28 DC control bits in frame parts #0 to #27. Among these DC control bits, eight DC control bits are set as DC control bits which are used to determine coincidence or non-coincidence with specific user control data.

The other DC control bits are set as DC control bits having values determined based on the normal bit-value setting processing, that is, digital-sum-variation measurement.

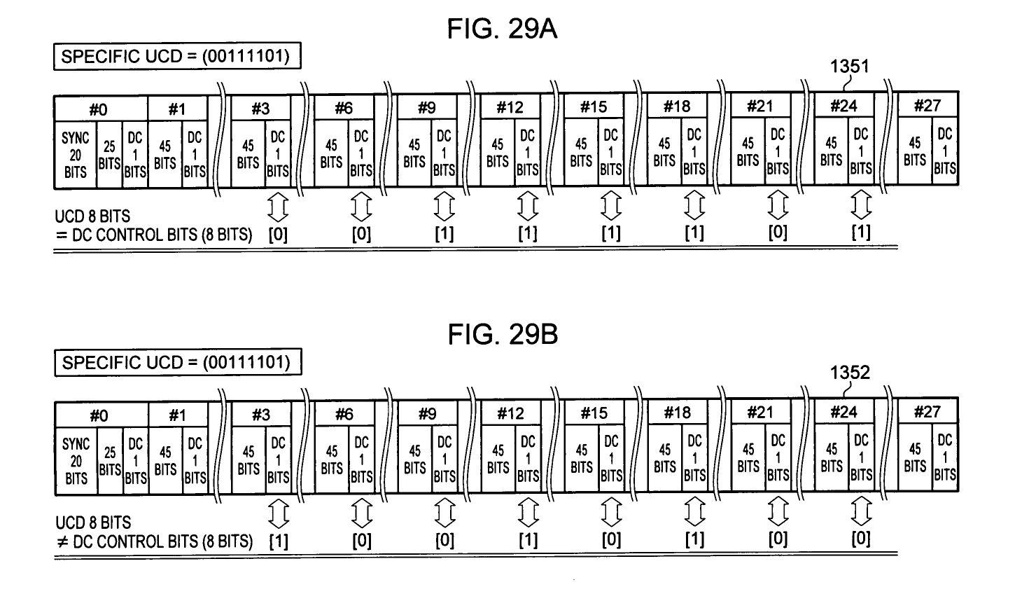

Details of the configuration of the DC-control-bit storage frame for specific user control data are described below with reference to FIGS. 29A and 29B.

FIG. 29A shows a detailed configuration of the DC-control-bit storage frame for specific user control data in the case of “specific user control data”=“additional data component bits”, and FIG. 29B shows a detailed configuration of the DC-control-bit storage frame for specific user control data in the case of “specific user control data”≠“additional data component bits”.

In this example shown in FIGS. 29A and 29B, the case of “component bits of specific user control data”=“00111101” is shown.

When “specific user control data”=“additional data component bits”, the eight bits “00111101” are stored at DC-control-bit storing positions selected from the DC-control-bit storage frame for specific user control data.

Here, the DC-control-bit storage positions in the DC-control-bit storage frame for specific user control data are eight frame parts #3, #6, #9, #12, #15, #18, #21, and #24. The above DC-control-bit storage positions are examples. The DC control bits may be set at arbitrary positions. When valid playback-processing program is executed, from each bit position, each DC control bit is read. It is determined whether the read DC control bit is coincident with specific user control data, and the bit value of additional data is acquired. Details of the playback processing are described later.

FIG. 29B shows the case of “specific user control data”≠“additional data component bits”, and Bits different from the eight bits “00111101” are stored at the DC-control-bit storage positions selected from the DC-control-bit storage frame for specific user control data.

In other words, bits different from the eight bits “00111101” are stored at the DC-control-bit storage positions in a DC-control-bit storage frame for specific user control data, that is, frame parts #3, #6, #9, #12, #15, #18, #21, and #24. An arbitrary bit string may be used as the above eight DC control bits if different from the bits “00111101”. In the example shown in FIG. 29B, the bits “10010100” are stored at DC-control-bit storage positions in the DC-control-bit storage frame 1352 for specific user control data, that is, frame parts #3, #6, #9, #12, #15, #18, #21, and #24.

As described above, in an embodiment, part of user control data included in data to be recorded on the information recording medium is set as specific user control data. Depending on whether information of bits in the specific user control data is used as additional data component bits, DC control bits set in DC-control-bit storage frame for specific user control data are controlled to be coincident or not coincident with corresponding user control data. By using DC-control-bit storage frames, additional data information, such as encryption-key information, is embedded.

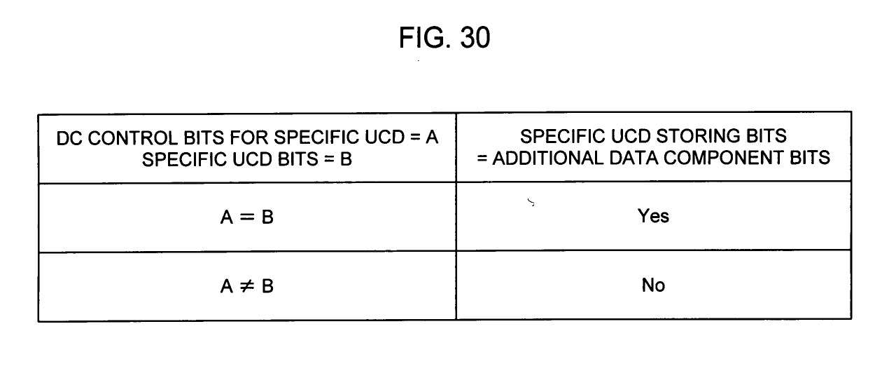

As FIG. 30 shows, in a case in which DC-control-bit information (8 bits) in the DC-control-bit storage frame for specific user control data is represented by A, and bit information of specific user control data is represented by B, if A=B, “bit information of specific user control data”=“additional data component bits”, and if A≠B, “bit information of specific user control data”≠“additional data component bits”. Under the these conditions, data recording and playback are executed.

Next, a method of selecting and setting which user control data item as specific user control data, that is, a method of selecting a user control data item in which additional data is to be stored, is described below.

As described above with reference to FIGS. 25 and 26, in one cluster, many user control data items “UC 0,0” to “UC 17,31”, each item storing 8-bit data, are stored. From among the user control data items, one or plural items are selected as specific user control data items.

In one technique of selecting specific user control data, a user control data item common to all clusters, for example, the user control data item “UC 0,0”, is set in common as specific user control data.

In addition, in another technique, a plurality of user control data items, such as “UC 0,0”, “UC 0,5”, and “UC 0,10”, are selected at predetermined intervals and are all set as specific user control data items.

However, as described above, in a case in which common user control data items, that is, “UC 0,0” and “UC 0,5”, are set as specific user control data items in all clusters, if it is found, in a certain cluster, which of user control data items is used as a specific user control data item, by acquiring identical user control data items from all the clusters, a possibility that secret information may leak out can be generated. Accordingly, it is preferable to employ a technique of setting different specific user control data items for the clusters.

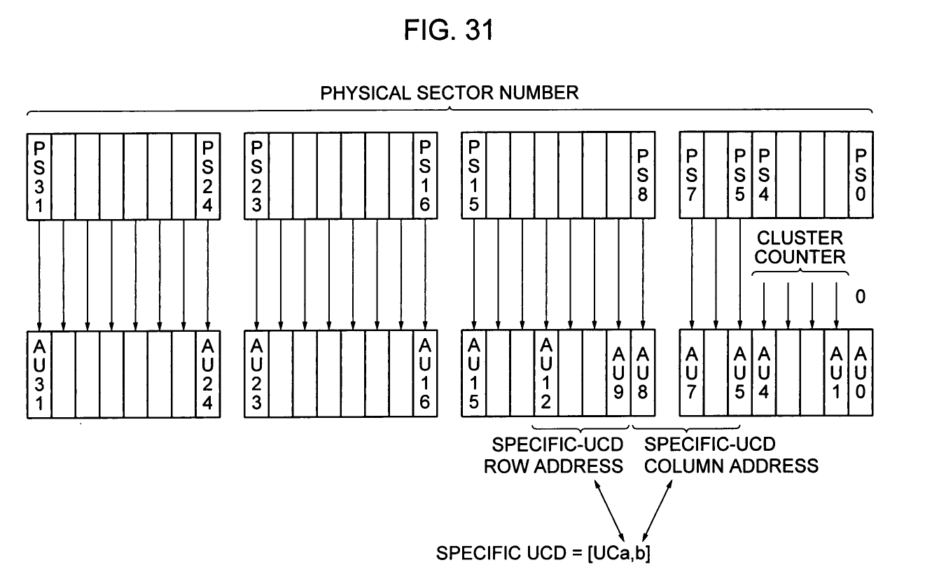

The technique of setting different specific user control data items for the clusters is described below with reference to FIG. 31.

On the information recording medium 1101, data is recorded in units of physical sectors, which are predetermined data-recording units, and physical sector numbers are assigned to the physical sectors, as shown in FIG. 31.

The physical sectors numbers are data of 32 bits from PS0 to PS31. The physical sector numbers PS0 to PS31, composed of 32 bits, are associated with address unit numbers AU0 to AU31 serving as address information.

In address units AU31 to AU27, the bit values “0000” are recorded, and in the address units AU26 to AU24, a layer number is recorded. In address units AU23 to AU5, a cluster number is recorded, and address unit AU4 to AU1 are used to perform counting in the inside of each cluster, and in address unit AU0, “0” is set.

User control data is formed in units of clusters. As described above with reference to FIGS. 25 and 26, in one cluster, the user control data items “UC 0,0” to “UC 17,31” are stored, each item storing 8-bit data.

Here, as specific cluster identification information, bit data of address units AU23 to AU5 having the cluster number recorded therein is used. As shown in FIG. 31, for example, the four bits of address units AU12 to AU9 are used as a specific-user-control-data (specific UCD) row information (address), and the four bits of address units AU8 to AU5 are used as a specific-UCD column information (address).

In a cluster in which lower eight bits (AU12 to AU5) of the cluster number are “00000000”, specific user control data is “UC 0000,0000”, that is, “UC 0,0”. In addition, a cluster in which lower eight bits (AU12 to AU5) of the cluster number are “00000001”, specific user control data is “UC 0000,0001”, that is, “UC 0,1”.

By employing the above setting, in clusters, different user control data items can be set as specific user control data items.

In the case of setting a plurality of specific user control data items in one cluster, intervals at which specific user control data items are determined beforehand. For example, user control data items at intervals of five columns are set as specific user control data items.

In the case of setting user control data items at intervals of five columns as specific user control data items, in clusters in which lower eight bits (AU12 to AU5) of the cluster number are “00000000”, specific user control data items are set as “UC 0,0”, “UC 0,5”, “UC 0,10”, etc. In clusters in which lower eight bits (AU12 to AU5) of the cluster number are “00000001”, specific user control data items are set as “UC 0,1”, “UC 0,6”, “UC 0,11”, and the like.

By employing the above-described setting of specific user control data, specific user control data items can be set at different positions in the clusters. This realizes a system having high resistance to leaking of secret information.

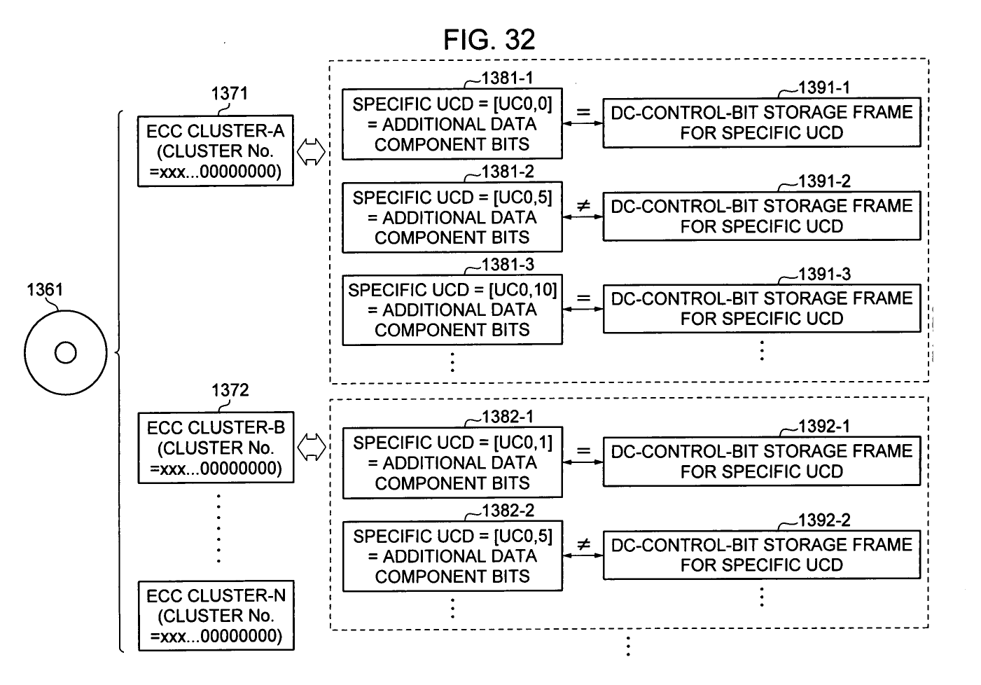

Next, processing for recording, on a recording medium (disk) 1361, specific user control data and a DC-control-bit storage frame for specific user control data is described below with reference to FIG. 32.

On the recording medium (disk) 1361, main data such as content, and plural ECC clusters (see FIG. 21) generated based on user control data (UCD), such as control information, are set. Recording-data generating processing is executed in each cluster unit. A recording frame having DC control bits set therein is set, and a recording signal based on the recording frame is generated and recorded.

For example, in ECC cluster-A 1371, a plurality of specific user control data items are set. It is assumed that “the lower eight bits of the cluster number of ECC cluster-A 1371”=00000000.

ECC cluster-A 1371 includes “UC 0,0” as a first specific UCD (user-control-data) item 1381-1, “UC 0,5” as a second specific UCD item 1381-2, and “UC 0,10” as a third specific UCD item 1381-3.

In this case, by determining whether each specific UCD item is coincident with DC control bits in a DC-control-bit storage frame for specific user control data, each specific UCD item is identified as additional data component bits.

For example, the first specific UCD item “UC 0,0” 1381-1 is compared with eight DC control bits in a corresponding DC-control-bit storage frame 1391 for specific user control data, for example, the eight DC control bits in frame parts #3, #6, #9, #12, #15, #18, #21, and #24, as described above with reference to FIG. 29.

When “8 bits of the specific UCD item “UC 0,0” 1381-1”=“8 DC control bits in the DC-control-bit storage frame 1391-1”, the eight bits of the specific UCD item “UC 0,0” 1381-1 are additional data component bits.

The second specific UCD item “UC 0,5” 1381-2 is compared with eight DC control bits in a corresponding DC-control-bit storage frame 1391-2 for specific user control data.

When “8 bits of the second specific UCD item “UC 0,5” 1381-2”≠“8 bits in the DC-control-bit storage frame 1391-2 for specific user control data”, it is determined that the 8 bits of the second specific UCD item “UC 0,5” 1381-2 are not additional data component bits.

The third specific UCD item “UC 0,10” 1381-3 is compared with eight DC control bits in a corresponding DC-control-bit storage frame 1391-3 for specific user control data.

When “8 bits of the third specific UCD item “UC 0,10” 1381-3”≠“8 DC control bits in the corresponding DC-control-bit storage frame 1391-3 for specific user control data, it is determined that the 8 bits of the third specific UCD item “UC 0,10” 1381-3 are additional data component bits.

Subsequently, similarly, a plurality of specific user control data items are extracted from ECC cluster-A 1371, and from among the extracted items, only those coincident with the 8 DC control bits in the DC-control-bit storage frame for specific user control data are extracted as additional data items.

Assuming that ECC cluster-B 1372 has a cluster number whose lower 8 bits=“00000001”, ECC cluster-B 1372 includes “UC 0,1” as a first specific UCD item 1382-1, and “UC 0,6” as a second specific UCD item 1382-2.

The first specific UCD item “UC 0,1” 1382-1 is compared with 8 DC control bits in a corresponding DC-control-bit storage frame 1392-1 for specific user control data.

When “8 bits of the first specific UCD item “UC 0,1” 1382-1”=“8 DC control bits in the DC-control-bit storage frame 1392-1 for specific user control data”, the 8 bits of the first specific UCD item “UC 0,1” 1382-1” are additional data component bits.

The second specific UCD item “UC 0,6” 1382-2 is compared with 8 DC control bits in a corresponding DC-control-bit storage frame 1392-2 for specific user control data.

When “8 bits of the second specific UCD item “UC 0,6” 1382-2”≠“8 DC control bits in a corresponding DC-control-bit storage frame for specific user control data”, it is determined that the 8 bits of the second specific UCD item “UC 0,6” 1382-2 are not additional data component bits.

As described above, setting positions of specific user control data items are set to differ in clusters recorded on the disk 1361, and determination of whether a specific user control data item is additional data component bits is performed depending on whether the specific user control data item is coincident with DC control bits in a corresponding DC-control-bit storage frame for specific user control data. This enables recording of additional data having high difficulty in analysis.

The additional-data recording-area control unit 1107 shown in FIG. 19 identifies a DC-control-bit storage frame for specific user control data on the basis of information set beforehand. When the modulated data generating unit 1109 performs processing of modulating the DC-control-bit storage frame, by changing over the switch 1108, the additional-data recording-area control unit 1107 allows the DC-control-bit selecting unit 1114 to output the set values of DC control bits for specific user control data to the modulated data generating unit 1109.

Bit information of specific user control data is input to the DC-control-bit selecting unit 1114.

When “bit information of specific user control data”=“additional data component bits”, the DC-control-bit selecting unit 1114 selectively outputs, to the modulated data generating unit 1109, bit values coincident with the bit information of the specific user control data.

When “bit information of specific user control data”≠“additional data component bits”, the DC-control-bit selecting unit 1114 selectively outputs, to the modulated data generating unit 1109, bit values which are not coincident with the bit information of the specific user control data.

Based on the bit values input from the DC-control-bit selecting unit 1114, the modulated data generating unit 1109 generates a recording frame by setting the input bit values at specific positions for setting DC control bits for specific user control data in a DC-control-bit storage frame for specific user control data, and performs modulating processing.

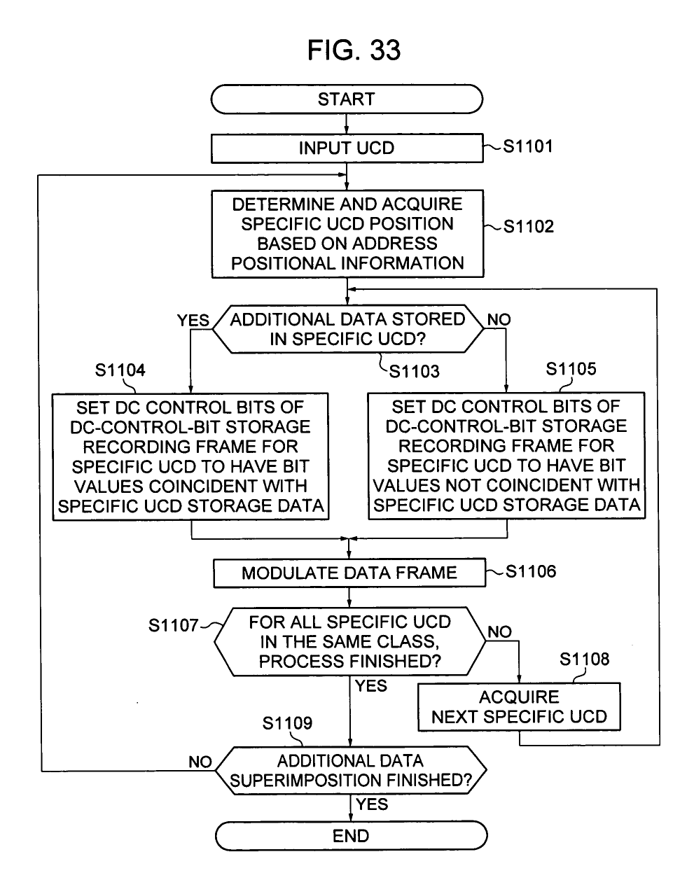

Next, an additional data recording process executed in the information recording processor according to the second embodiment of the present invention is described below with reference to FIG. 33.

In step S1101, user control data is input. As described above, the user control data is constituted by a plurality of user control data items (“UC 0,0” to “UC 17,31”), each item including 8-bit data.

In step S1102, based on address positional information, that is, specific bits of an address unit corresponding to a physical sector number as described with reference to FIG. 31, in other words, some component bits of a cluster number, Row-position information and column-position information are acquired, and user control data corresponding to the acquired information is identified and acquired as specific user control data.

In step S1103, it is determined whether the acquired specific user control data stores additional data. The additional data is encryption-key information for use as an encryption key for encrypted content, information forming part of the encryption-key information, encryption-key generating information such as the data (e.g., a seed) required for generating an encryption key, secret information such as a password, control information such as content playback control information or copy-control information, or other information.

The information required to determine whether the acquired specific user control data stores additional data is externally input to the apparatus by the user beforehand.

When the specific user control data selected is user control data storing additional data, the process proceeds to step S1104, DC control bits set in the DC-control-bit storage frame for specific user control data, for example, eight bits set in eight frame parts #3, #6, #9, #12, #15, #18, #21, and #24, are set to have values coincident with the bit values of the specific user control data acquired in step S1102.

In step S1103, if the process has determined that the selected specific user control data is not user control data storing additional data, the process proceeds to step S1105. the DC control bits set in the DC-control-bit storage frame for specific user control data, for example, eight bits set in eight frame parts #3, #6, #9, #12, #15, #18, #21, and #24 are set to have values which are not coincident with the bit values of the specific user control data acquired in step S1102.

Next, the process proceeds to step S1106, and executes processing of modulating the DC-control-bit storage frame for specific user control data.

In step S1107, it is determined whether processing on all items of the specific user control data in the same cluster has finished. If the processing has not finished yet, the process proceeds to step S1108. In step S1108, the next specific user control data is acquired and processing in steps S1103 to S1106 is repeatedly executed. The acquisition of the next specific user control data in step S1108 is executed, for example, when the first specific user control data item in a cluster to be processed is “UC 0,0”, as processing in which “UC 0,5” is acquired as the next user control data item, with the column-position information incremented by a predetermined value.

If the process has affirmatively determined in step S1107, it proceeds to step S1109, and it is determined whether superimposition of additional data has finished. If there is unprocessed data, step S1102 and the subsequent steps are repeatedly executed.

Determination of no unprocessed data in step S1109 terminates the process. In other words, in the process, which has been described, recording data in which additional data bits are inserted is generated.

Although the flowchart shown in FIG. 33 shows only processing on the DC-control-bit storage frame for specific user control data, for each frame other than the DC-control-bit storage frame, a recording frame in which DC control bits are set based digital sum variation measurement is generated and modulated. In addition, regarding eight bits set at positions for setting DC control bits for specific user control data in the DC-control-bit storage frame for determining a response to additional data, that is, in eight frame parts #3, #6, #9, #12, #15, #18, #21, and #24, values selected in accordance with the above process are set as DC control bits. However, in frame parts other than the DC-control-bit storage frame, DC control bits based on digital-sum-variation measurement are set.

Positions at which DC control bits for specific user control data are stored in the DC-control-bit storage frame are not limited to frame parts #3, #6, #9, #12, #15, #18, #21, and #24, but may be arbitrarily set.

In an embodiment, all the eight bits of the specific user control data are set or not set as additional data. However, only part of the eight bits, for example, upper four bits may be used as bit data of additional data.

In an embodiment, depending on whether the bit valued of specific user control data are coincident with DC control bits for determining response to specific user control data in the DC-control-bit storage frame for specific user control data, it is determined whether component bits of the specific user control data are additional data component bits. However, when the bit values of the specific user control data are coincident with the DC control bits for determining response to specific user control data, the additional data component bit may be set to be “1”. When both are not coincident, the additional data component bit may be set to be “0”. Alternatively, converse setting may be performed.

Next, the configuration and playback processing of an information playback processor for performing a process of playing back an information recording medium containing the above-described additional data and content (main data) such as movie and music are described below.

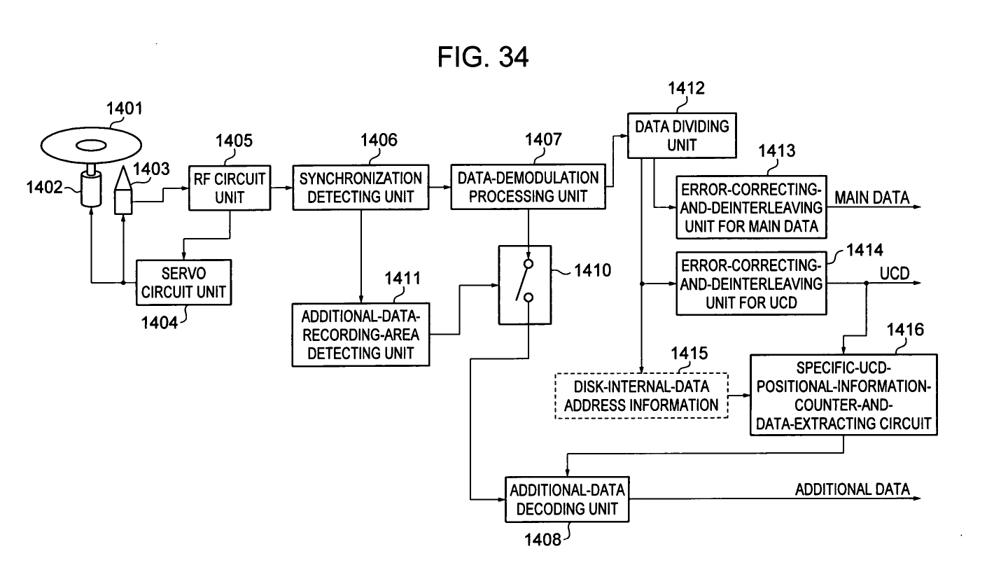

The configuration and process of the information playback processor are described with reference to FIG. 34.

The information playback processor includes an information recording medium 1401, a pickup 1403 for reading data from the information recording medium 1401, a spindle motor 1402 for driving the information recording medium 1401, a servo circuit 1404 for controlling the pickup 1403 and the spindle motor 1402, an RF circuit unit 1405 for performing signal processing, such as gain adjustment of a read signal, and generating an RF signal, a synchronization detecting unit 1406 for extracting a synchronizing signal from the RF signal, a data-demodulation processing unit 1407 for executing a data demodulating process, a switch 1410 for outputting only an additional data area of a read signal from the information recording medium 1401 to an additional-data decoding unit 1408, an additional-data-recording-area detecting unit 1411 for detecting the additional data area and controlling the switch 1410, an additional-data decoding unit 1408 for executing an additional data decoding process, a data dividing unit 1412 which, based on demodulated data output from the data-demodulation processing unit 1407, divides main data and user control data, an error-correcting-and-deinterleaving unit 1413 for main data which performs error correction of main data and a deinterleaving process, an error-correcting-and-deinterleaving unit 1414 for user control data which performs error correction of user control data and a deinterleaving process, and a specific-UCD-positional-counter-and-data-extracting circuit 1416 which acquires the disk internal address information 1415 (see FIG. 31) and calculates the position of user control data storing additional data, that is, the position of specific user control data, and which executes predetermined incrementing processing to selectively acquire the specific user control data.

The content data recorded on the information recording medium 1401 is, for example, encrypted content data. The additional data recorded on the information recording medium 1401 is encryption-key information for use as an encryption key for encrypted content, information constituting part of the encryption-key information, encryption-key generating information such as the data (e.g., seed) required for generating an encryption key, secret information such as a password, control information such as content-playback control information or copy-control information, or other information such as content-attribute information.

Data read from the information recording medium 1401 through the pickup 1403 is processed (signal processing such as gain adjustment) in the RF circuit unit 1405, and the processed signal is input to the synchronization detecting unit 1406. The synchronization detecting unit 1406 detects a synchronizing signal from the recorded signal and outputs the detected signal to the additional-data-recording-area detecting unit 1411.

Based on the synchronizing signal input from the synchronization detecting unit 1406, the additional-data-recording-area detecting unit 1411 identifies a recording area of the DC-control-bit storage frame for specific user control data and controls the switch 1410 based on the identification information. By controlling the switch 1410, a recording frame in the area required for decoding additional data, that is, the DC-control-bit storage frame for specific user control data, is input from the data-demodulation processing unit 1407 to the additional-data decoding unit 1408, which executes an additional data decoding process.

The additional-data decoding unit 1408 receives a DC-control-bit storage frame for specific user control data from the data-demodulation processing unit 1407 through the switch 1410, and specific user control data from the specific-UCD-positional-counter-and-data-extracting circuit 1416. The additional-data decoding unit 1408 compares the DC control bits for specific user control data and the bit values of the specific user control data, and executes processing of acquiring only coincident ones as additional data component bits.

The specific-UCD-positional-counter-and-data-extracting circuit 1416 acquires the disk-internal-data address information 1415 (see FIG. 31) and calculates the position of user control data storing additional data, that, specific user control data. In addition, the specific-UCD-positional-counter-and-data-extracting circuit 1416 executes predetermined incrementing processing to selectively acquire the specific user control data.

For items of the specific user control data sequentially input from the specific-UCD-positional-counter-and-data-extracting circuit 1416, the additional-data decoding unit 1408 selects only those storing additional data, and acquires additional data based on the bit information of those storing additional data.

In other words, only when DC-control-bit information for determining response to specific user control data is coincident with the bit information of specific user control data does the additional-data decoding unit 1408 determines that bit information stored in the specific user control data is additional data component bits. Based on the bit information, the additional-data decoding unit 1408 acquires the additional data.

In the playback processor, when data to be processed in the data-demodulation processing unit 1407 is a DC-control-bit storage frame for specific user control data, data of the frame is input to the additional-data decoding unit 1408 through the switch 1410. The additional-data decoding unit 1408 acquires specific DC control bits in the DC-control-bit frame for determining response, and executes, based on determination of correspondence with the specific user control data bits, processing of determining whether the specific user control data is additional data component bits. The additional-data-recording-area detecting unit 1411 controls the switch 1410 to be one when the data-demodulation processing unit 1407 executes processing of the DC-control-bit storage frame for specific user control data.

By executing similar processing based an intermittently-input DC-control-bit storage frame (for specific user control data) and specific user control data, the additional-data decoding unit 1408 acquires additional data such as n-bit information used as key information, key-information generating information, content-playback control information, copy-control information, or other content-attribute information.

When the additional data is key information for use in, for example, content decryption, it is output to a decrypting processing unit for executing a content decrypting process. When the additional data is content-playback control information, it is output to a playback control unit.

In addition, ordinary data other than the additional data is output from the synchronization detecting unit 1406 to the data-demodulation processing unit 1407. By sequentially executing data conversion inverse to that described with reference to FIGS. 20 and 21, the data-demodulation processing unit 1407 acquires playback data.

Based on demodulated data output from the data-demodulation processing unit 1407, the DCT unit 1412 divides the main data and the user control data. The error-correcting-and-deinterleaving unit error-correcting-and-deinterleaving unit 1413 for main data executes error correction and the deinterleaving process on the main data. The error-correcting-and-deinterleaving unit 1414 for user control data executes error correction and the deinterleaving process on the user control data, and outputs the processed user control data.

When the output main data is, for example, encrypted content, the encrypted content is decrypted by using an encryption key generatable based on key-generating information output as additional data, and the decrypted content is output through an output unit such as a display and a speaker.

The configuration shown in FIG. 34 is a schematic block diagram illustrating the configuration and process of the information playback processor according to the second embodiment of the present invention. For example, a process of acquiring a DC-control-bit storage frame for specific user control data, and processes of acquiring and analyzing additional data can be executed such that a control unit, such as a CPU, executes a program describing the processes, etc. Therefore, in the information playback processor according to an embodiment, items of hardware which correspond to the switch 1410 shown in FIG. 34 and component elements in the other blocks shown in FIG. 34 are not essential. On hardware including a control unit for executing processing in accordance with a predetermined program, a CPU used as a data processing unit, and a memory used for storing data and parameters, processes of acquiring and playing back additional data are executable.

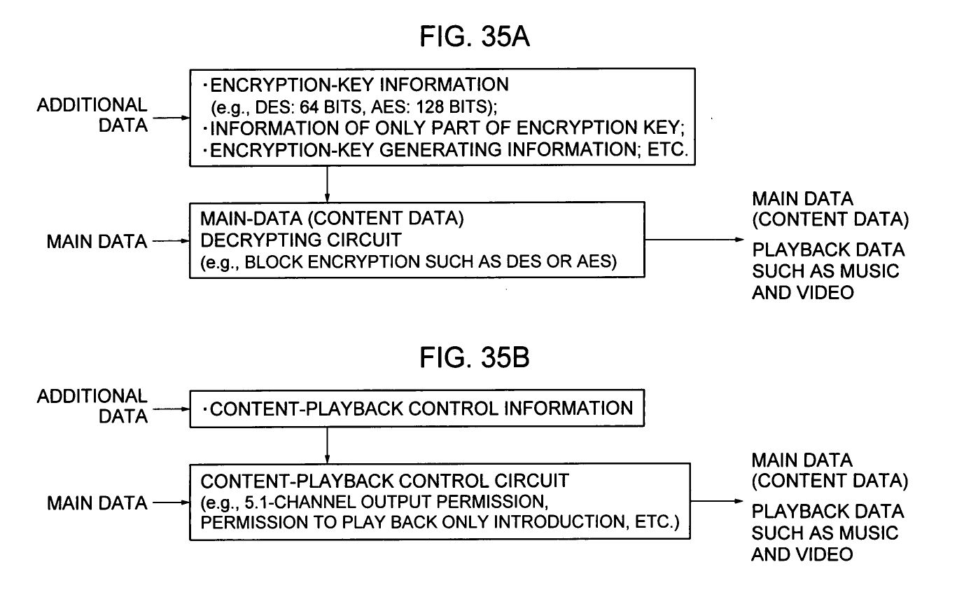

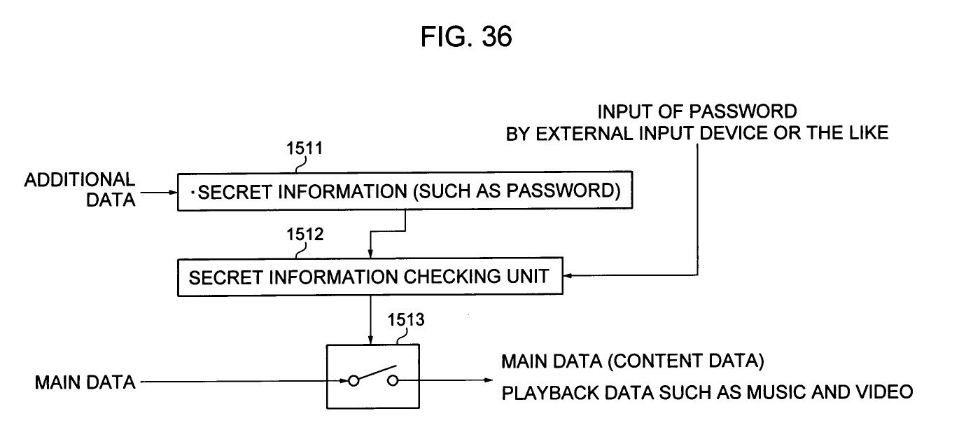

An application of the additional data acquired by the information playback processor is described below with reference to FIGS. 35A, 35B and 36.

As described above, the additional data is, for example, encryption-key information for use as an encryption key for encrypted content, information forming part of the encryption-key information, encryption-key generating information such as the data (e.g., a seed) required for generating an encryption key, secret information such as a password, control information such as content playback control information or copy-control information, or other information such as content-attribute information.

FIG. 36A shows an example of a process in a case in which the additional data is encryption-key information for use as an encryption key for encrypted content, information forming part of the encryption-key information, or encryption-key generating information such as the data (e.g., a seed) required for generating an encryption key. The information playback processor uses the acquired encryption-key information to execute a main data decrypting process. This plays back content such as music and video. An encryption algorithm, such as DES or AES, is applied to the decrypting process.

FIG. 35B shows an example of a process in a case in which the additional data is content-playback control information corresponding to content recorded as the main data. In this case, control of playback of the main data (content) is executed in accordance with the content-playback control information acquired as the additional data. In the case of playing back the content, for example, control of a playback allowable range, such as output-form control such as 5.1-channel output control, and control of an introduction part of the content, are executed in accordance with the content-playback control information.

FIG. 36 shows an example of a process in a case in which the additional data is secret information such as a password, and content playback is allowed by checking the password. A password 1511 is input as the additional data to a secret information checking unit 1512. The secret information checking unit 1512 compares the input password 1511 with password information input from an external input device or the like. Only when both match each other does the secret information checking unit 1512 set a switch 1513 to be on. This allows the content as the main data, for example, data, such as music and video, to be played back.

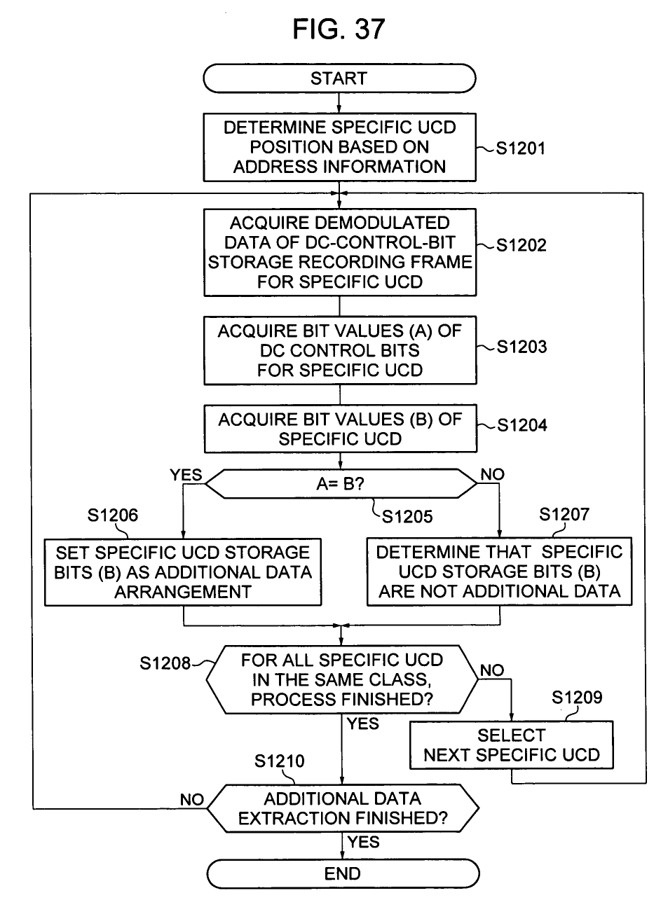

Next, a playback process including reading of the additional data is described below with reference to FIG. 37. The process shown in FIG. 37 is executed by the information playback processor shown in FIG. 34.

In step S201, positional information of specific user control data is acquired based on the address information (see FIG. 31) written in the disk 1401. In step S202, demodulated data of a DC-control-bit storage frame for specific user control data is acquired. The additional-data-recording-area detecting unit 1411 shown in FIG. 34 recognizes timing of demodulating the DC-control-bit storage frame for specific user control data, whereby the DC-control-bit storage frame for specific user control data is output from the data-demodulation processing unit 1407 to the additional-data decoding unit 1408.

In step S203, the additional-data decoding unit 1408 acquires, from the DC-control-bit storage frame input from the data-demodulation processing unit 1407, the value of DC control bits set at positions at which the DC control bits for determining a response to additional data are stored, for example, eight frame parts #3, #6, #9, #12, #15, #18, #21, and #24. The value of DC control bits is referred to as DC bit information A.

In step S204, the additional-data decoding unit 1408 acquires specific user control data from the specific-UCD-positional-counter-and-data-extracting circuit 1416. The acquired user control data is referred to as UCD bit information B.

In step S1205, the additional-data decoding unit 1408 determines whether the relationship “DC bit information A”=“specific-UCD bit information B” holds.

When the relationship “DC bit information A”=“specific-UCD bit information B” holds, in step S1206, it is determined that “specific-UCD bit information B”=“additional data component bits”.

When the relationship “DC bit information A”≠“specific-UCD bit information B” holds, in step S1207, it is determined that “specific-UCD bit information B”≠“additional data component bits”.

In step S1208, it is determined whether processing on all items of the specific user control data in the same cluster has finished. If the processing has not finished yet, the process proceeds to step S1209. In step S1209, the next specific user control data is acquired and steps S1202 to S1208 are repeatedly executed.

The acquisition of the next specific user control data in step S1209 is executed, for example, when the first specific user control data item in a cluster to be processed is “UC 0,0”, as processing in which “UC 0,5” is acquired as the next user control data item, with the column-position information incremented by a predetermined value.

If the process has affirmatively determined in step S1208, it proceeds to step S1210, and it is determined whether extraction of additional data has finished. If there is unprocessed data, step S1202 and the subsequent steps are repeatedly executed. If it is determined that all additional data has been acquired, the process ends.

Next, an example of processing according to an embodiment is described below. In the example of processing, values are calculated as the result of arithmetic processing (e.g., exclusive OR (XOR) or exclusive NOR (XNOR)) on data items in user control data and additional data, and the values are set as DC control bits set in a DC-control-bit storage frame for specific user control data.

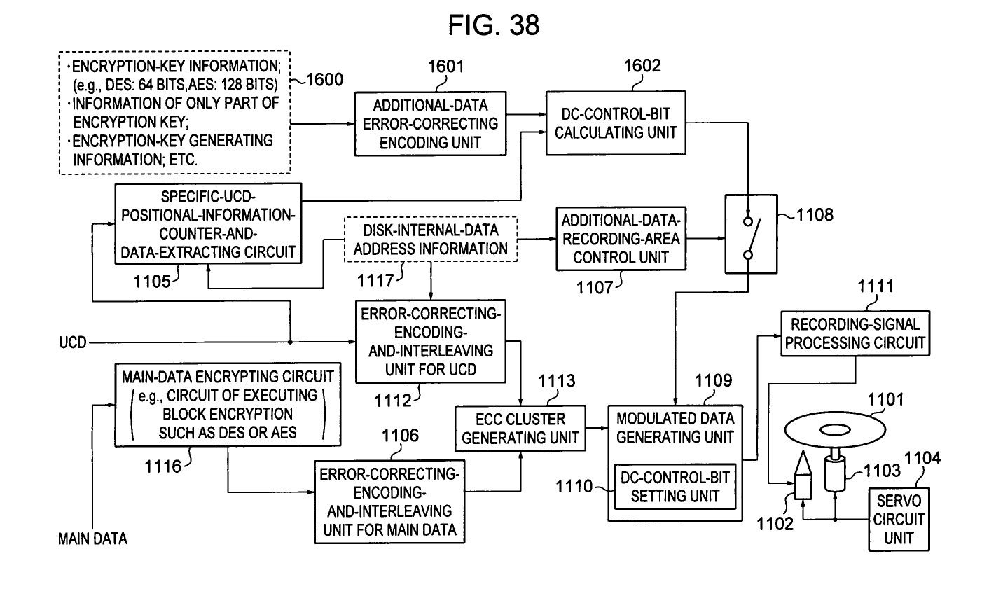

FIG. 38 shows the configuration of an information recording processor according to the third embodiment. In FIG. 38, components identical to those shown in the information recording processor (shown in FIG. 19) according to an embodiment are denoted by identical reference numerals.

In the information recording processor according to the third embodiment, for example, additional data 1600, such as encryption-key information for use as an encryption key for encrypted content, information constituting part of the encryption-key information, encryption-key generating information such as the data (e.g., seed) required for generating an encryption key, secret information such as a password, control information such as content-playback control information or copy-control information, is processed for error-correcting encoding by an additional-data error-correcting encoding unit 1601. The error-correcting-coded additional data is input to a DC-control-bit calculating unit 1602.

The DC-control-bit calculating unit 1602 also receives specific user control data input from a specific-UCD-positional-information-counter-and-data-extracting unit 1105.

The specific-UCD-positional-information-counter-and-data-extracting unit 1105 is similar to the specific-UCD-positional-information-counter-and-data-extracting unit 1105 (shown in FIG. 19) according to the second embodiment. It executes processing of identifying and acquiring specific user control data.

By executing arithmetic processing based on additional data component bits and stored-bit information in the specific user control data, the DC-control-bit calculating unit 1602 determines the values of DC control bits to be set in the DC-control-bit storage frame for specific user control data.

The DC-control-bit calculating unit 1602 executes arithmetic processing on data items in the specific user control data and additional data, for example, XOR or XNOR. The DC-control-bit calculating unit 1602 outputs the calculated results to a modulated data generating unit 1109 through a switch 1108. The modulated data generating unit 1109 generates a DC-control-bit storage frame (for specific user control data) in which DC control bits based on the calculated result are set.

The other components shown in FIG. 38 are identical to those described with reference to FIG. 19. Accordingly, a description of them is omitted.

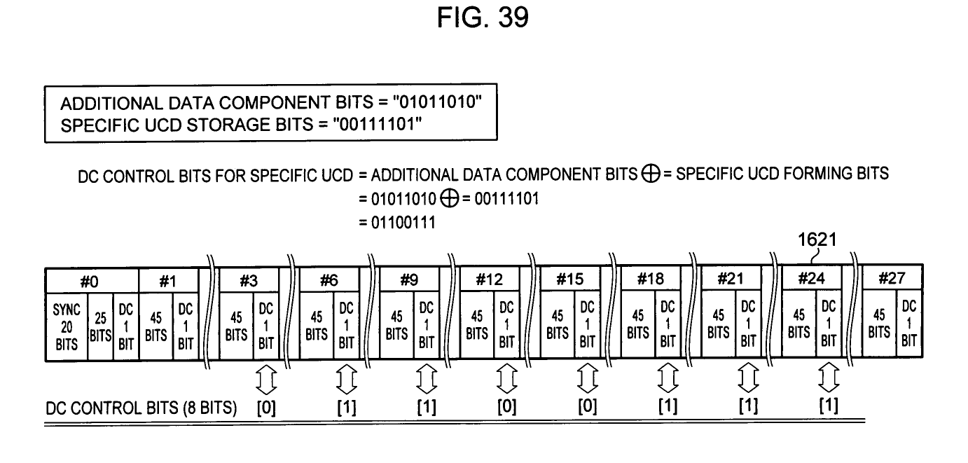

The arithmetic processing executed in the DC-control-bit calculating unit 1602 is described below with reference to FIG. 39.

FIG. 39 shows an example in which XOR is executed as arithmetic processing using data items in specific user control data and additional data and in which the result of XOR is set as DC control bits set in the DC-control-bit storage frame for specific user control data.

In the example shown in FIG. 39, the following settings are used:
“additional data component bits”=“01011010”; and
“specific UCD storing bits”=“00111101”.

The additional data component bits are some bits included in additional data, for example, encryption-key information for use as a key for encrypted content, information forming part of the encryption-key information, encryption-key generating information such as the data (e.g., seed) required for generating an encryption key, secret information such as a password, or control information such as content-playback control information or copy-control information.

The DC-control-bit calculating unit 1602 executes XOR of the additional data component bits “01011010” and the specific-user-control data storage bits “00111101”, and produces the arithmetic processing result “01100111”.

The resultant values “01100111” are used as DC control bits set in the DC-control-bit storage frame for specific user control data.

The resultant values are output to the modulated data generating unit 1109 through the switch 1108, and a DC-control-bit storage frame for specific user control data in which DC control bits based on the resultant values are set is generated.

For example, in the DC-control-bit storage frame 1621 for specific user control data, shown in FIG. 39, in eight frame parts #3, #6, #9, #12, #15, #18, #21, and #24, the resultant values “01100111” are stored which are obtained by executing XOR of the additional data component bits “01011010” and the specific-user-control-data storage bits “00111101”.

Positions at which the DC control bits for user control data are stored are only illustrative. The DC control bits may be stored at arbitrary positions if they are set beforehand. When a valid playback processing program is executed, the DC control bits are read at the bit positions and are arithmetically processed (XORed) with the specific user control data, and additional data is acquired as the result of arithmetic processing.

In other words, in the information playback processor, the DC control bits “01100111” and the specific-user-control-data storage bits “00111101” are XORed, whereby the additional data component bits “01011010” are acquired.

Although, in FIG. 39, the case of executing XOR as arithmetic processing is shown, XNOR or other arithmetic processing may be executed. However, it is required for arithmetic processing to be executed so that, in data recording processing, DC control bits are calculated by arithmetically processing additional data and specific user control data, and so that, in data playback processing, additional data is calculated by arithmetically processing specific user control data and DC control bits.

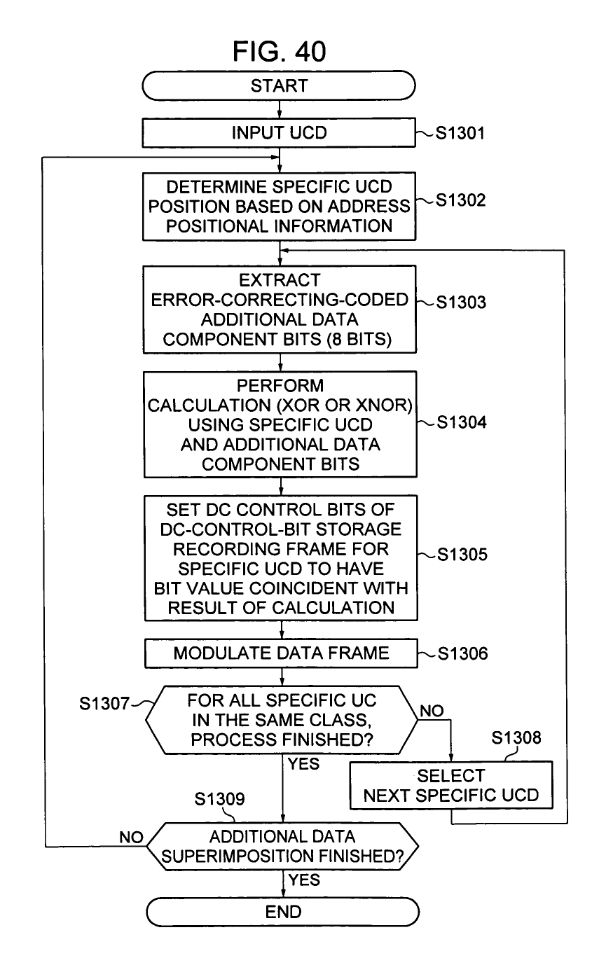

Next, an additional data recording process executed by the information recording processor according to the third embodiment is described below with reference to FIG. 40.

In step S1301, user control data is input. As described above, the user control data is constituted by a plurality of user control data items (“UC 0,0” to “UC 17,31”), each item including 8-bit data.

In step S1302, based on address positional information, that is, specific bits of an address unit as address information corresponding to a physical sector number, described above with reference to FIG. 31, in other words, component bits included in a cluster number, row-position information and column-position information of user control data are acquired and user control data corresponding to the information of both is determined and acquired as specific user control data.

In step S1303, additional data component bits which are error-correcting-encoded are acquired. The additional data is encryption-key information for use as an encryption key for encrypted content, information forming part of the encryption-key information, encryption-key generating information such as the data (e.g., a seed) required for generating an encryption key, secret information such as a password, control information such as content playback control information or copy-control information, or other information such as content-attribute information.

Here, in order to execute arithmetic processing with the specific user control data (8 bits), that is, XOR or XNOR, the additional data is acquired in units of eight bits.

In step S1304, calculation using the specific user control data (8 bits) and the additional data, that is, XOR or XNOR, is executed.

In step S1305, DC control bits in the DC-control-bit storage frame for specific user control data are set to have bit values coincident with the result of the calculation. For example, eight bits in eight frame parts #3, #6, #9, #12, #15, #18, #21, and #24 are set to the bit values calculated in step S1304.

The process proceeds to step S1306, and the DC-control-bit storage frame for specific user control data is modulated.

In step S1307, it is determined whether processing on all specific user control data in the same cluster has finished. If the processing has not finished yet, the process proceeds to step S1308. The next specific user control data is acquired, and steps S1303 to S1306 are repeatedly executed. In the processing of acquiring the next specific user control data in step S1308, when the first user control data in a cluster to be processed is “UC 0,0”, the column-position information is incremented by a predetermined value and “UC 0,5” is to be acquired as the next specific user control data.

In step S1307, if the process has determined that the processing on all specific user control data in the same cluster has finished, the process proceeds to step S1309. In step S1309, it is determined whether additional data superimposition has finished. If there is unprocessed data, step S1302 and the subsequent steps are repeatedly executed.

In step S1309, determination of no unprocessed data terminates the process. In other words, in accordance with the above-described processing, recording data in which additional data bits are inserted is generated.

Although the flowchart shown in FIG. 40 only shows processing on a DC-control-bit storage frame for specific user control data, in each frame other than the DC-control-bit storage frame for specific user control data, a recording frame in which DC control bits based on digital-sum-variation measurement are set is generated and modulated. In addition, regarding eight bits set at positions for setting DC control bits for specific user control data in the DC-control-bit storage frame for specific user control data, that is, in eight frame parts #3, #6, #9, #12, #15, #18, #21, and #24, values calculated in accordance with the above process are set as DC control bits. However, in frame parts other than the DC-control-bit storage frame, DC control bits based on digital-sum-variation measurement are set.

Positions at which DC control bits for specific user control data are stored in the DC-control-bit storage frame are not limited to frame parts #3, #6, #9, #12, #15, #18, #21, and #24, but may be arbitrarily set.

Next, the configuration and playback process of the image playback processor according to the third embodiment are described below.

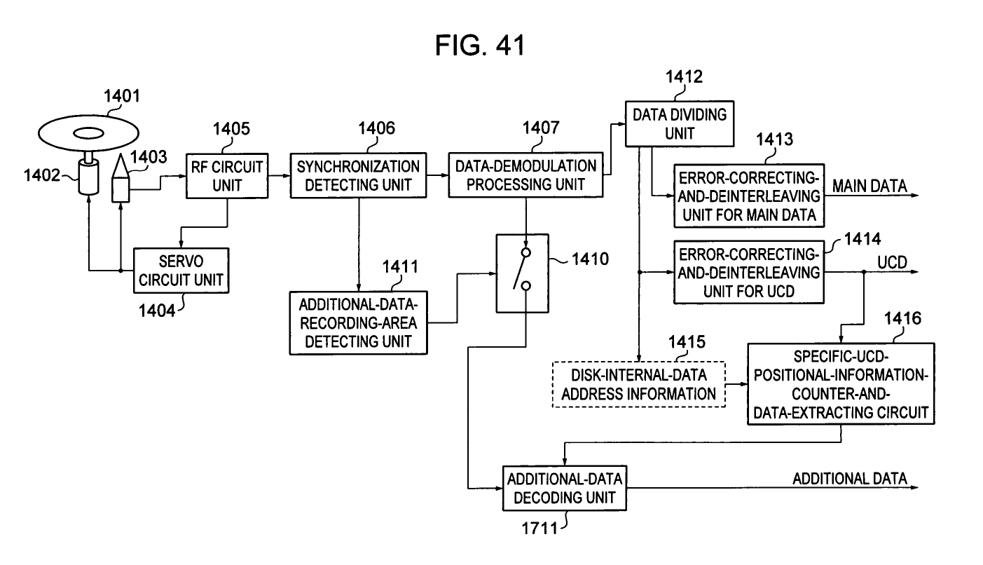

FIG. 41 shows the configuration of the information playback processor according to the third embodiment. In FIG. 41, component identical to those in the information playback processor according to the second embodiment described with reference to FIG. 34 are denoted by identical reference numerals.

Based on the synchronizing signal input from a synchronization detecting unit 1406, an additional-data-recording-area detecting unit 1411 identifies a recording area for a DC-control-bit storage frame for specific user control data and controls a switch 1410 based on the identification information. By controlling the switch 1410, a recording frame in the area required for decoding additional data, that is, a recording frame including a DC-control-bit storage frame for specific user control data, is input from the data-demodulation processing unit 1407 to an additional-data decoding unit 1711, which executes an additional data decoding process.

The additional-data decoding unit 1711 receives the DC-control-bit storage frame for specific user control data from the data-demodulation processing unit 1407 through the switch 1410, and specific user control data from the specific-UCD-positional-counter-and-data-extracting circuit 1416. The additional-data decoding unit 1711 executes arithmetic processing using DC control bits for specific user control data and specific-user-control-data bits.

Specifically, by executing arithmetic processing on the DC control bits for specific user control data and specific-user-control-data bits, that is, XOR or XNOR, the additional-data decoding unit 1711 acquires the result of arithmetic processing as additional data.

The specific-UCD-positional-counter-and-data-extracting circuit 1416 acquires disk-internal-data address information 1415 (see FIG. 31) and calculates user control data storing the additional data, that is, the position of specific user control data, and executes predetermined incrementing processing to selectively acquire specific user control data.

In the information playback processor, when data to be processed in the data-demodulation processing unit 1407 is a DC-control-bit storage frame for specific user control data, data of the frame is input to the additional-data decoding unit 1711 through the switch 1410, and the additional-data decoding unit 1711 acquires specific additional data component bits in the DC-control-bit storage frame for specific user control data and executes arithmetic processing with the specific-user-control-data bits to acquire additional data component bits.

While the data-demodulation processing unit 1407 is executing processing the DC-control-bit storage frame for specific user control data, the additional-data-recording-area detecting unit 1411 controls the switch 1410 to be on.

By executing similar processing based a DC-control-bit storage frame for specific user control data and specific user control data which are intermittently input, the additional-data decoding unit 1711 acquires additional data such as n-bit information used as key information, key-information generating information, content-playback control information, copy-control information, or other content-attribute information.

Next, a playback process including reading of the additional data is described below with reference to FIG. 24. The process shown in FIG. 24 is executed by the information playback processor shown in FIG. 23.

In step S1401, based on the address information (see FIG. 31) recorded on the disk, the positional information of specific user control data is acquired. In step S1402, demodulated data of the DC-control-bit storage frame for specific user control data is acquired. The additional-data-recording-area detecting unit 1411 shown in FIG. 41 determines timing of demodulating the DC-control-bit storage frame for specific user control data, and The DC-control-bit storage frame for specific user control data is output from the data-demodulation processing unit 1407 to the additional-data decoding unit 1711.

In addition, in step S1403, the additional-data decoding unit 1711 acquires, from the DC-control-bit storage frame input from the data-demodulation processing unit 1407, the value of DC control bits set at positions at which the DC control bits for specific user control data are stored, for example, eight frame parts #3, #6, #9, #12, #15, #18, #21, and #24. The value of DC control bits is referred to as DC bit information C.

In step S1404, bit information of specific user control data is acquired from the specific-UCD-positional-counter-and-data-extracting circuit 1416. The acquired information is referred to as specific-user-control-data bit information B.

In step S1405, the additional-data decoding unit 1711 performs calculation (e.g., XOR or XNOR) using DC-control-bit information C and specific-user-control-data bit information B.

In step S1406, the result of calculation using capacitor C and specific-user-control-data bit information B is set as additional data.

In step S1407, it is determined whether processing on all specific user control data in the same cluster has finished. If the processing has not finished yet, the process proceeds to step S1408 and the next specific user control data is acquired. Steps S1402 to S1407 are repeatedly executed.

In acquiring the next specific user control data in step S1408, when the first specific user control data in a cluster to be processed is “UC 0,0”, the column-position information is incremented by a predetermined value and “UC 0,5” is acquired as the next specific user control data.

If the process has determined in step S1407 that the processing on all specific user control data in the same cluster has finished, the process proceeds to step S1409 and determines whether extraction of additional data has finished. If there is unprocessed data, step S1402 and the subsequent steps are repeatedly executed. If the process has determined that all additional data has been acquired, the process ends.

Consecutive processing described herein can be executed one of hardware and software, or a configuration in which both are combined. When software processing is executed, it can be executed by installing a process-recorded program into a memory in a computer built-in dedicated hardware, or installing a program into a multi-purpose computer capable of executing various types of processing.

For example, the program can be recorded beforehand on a hard disk or on a read-only memory. Alternatively, the program can be temporarily or permanently stored (recorded) in a removable recording medium such as a CD-ROM (compact-disk read-only memory), an MO (magneto-optical disk), a DVD (digital versatile disk), a magnetic disk, or a semiconductor memory. The removable recording medium can be provided in the form of so-called “package software”.

The program is installed from the above removable recording medium to a computer. Moreover, the program is wirelessly transferred from a download site to the computer or is transferred by wire to the computer through a network such as the Internet. The computer can receive and install the transferred program into a built-in recording medium such as a hard disk.

Various types of processing described herein are not only executed in a time-series manner in accordance with the description, but also may be executed in parallel or separately depending on the processing capability of an apparatus executing the processing or as required. In addition, in this specification, the system means a logical set of a plurality of apparatuses, and is not limited to one having different apparatuses in a single housing.

It should be understood that various changes and modifications to the presently preferred embodiments described herein will be apparent to those skilled in the art. Such changes and modifications can be made without departing from the spirit and scope of the present invention and without diminishing its intended advantages. It is therefore intended that such changes and modifications be covered by the appended claims.

1. An information recording processor comprising:
a DC-control-bit selecting unit for executing DC-control-bit selecting processing in which values of DC control bits set in a recording frame are set to be any one of coincident and not coincident with user control data in response to the values of additional data component bits to be recorded on an information recording medium; and
a modulated data generating unit for generating a modulated recording frame used as recording-unit data by executing processing for modulating data to be recorded and DC-control-bit setting processing, wherein the modulated data generating unit selectively executes the DC-control-bit setting processing based on control of a digital sum variation and the DC-control-bit setting processing based on information input from the DC-control-bit selecting unit.

2. The information recording processor according to claim 1, wherein the DC-control-bit selecting unit is configured to execute selective processing in which, in response to the values of the additional data component bits to be recorded on the information recording medium, DC control bits set in a DC-control-bit storage frame for determining a response to additional data, the DC-control-bit storage frame being selected from the data to be recorded, are set to have values any one of coincident and not coincident with bit information of user control data for determining a response to additional data, the user control data being selected from the data to be recorded.

3. The information recording processor according to claim 1, wherein the DC-control-bit selecting unit is configured to execute selective processing in which values coincident with eight-bit information of user control data for determining a response to additional data, the user control data being selected from the data to be recorded, are any one of set and not set as the values of eight DC control bits set in a DC-control-bit storage frame for determining a response to additional data.

4. The information recording processor according to claim 1, wherein the DC-control-bit selecting unit is configured to execute processing in which user control data of which unit is composed of eight bits, the user control data being selected from the data to be recorded, is input as user control data for determining a response to additional data, and the values of eight DC control bits set in a DC-control-bit storage frame for determining a response to additional data are set in response to the values of the additional data component bits.

5. The information recording processor according to claim 1, wherein the DC-control-bit selecting unit is further configured to execute processing in which a value corresponding to the values of the additional data component bits to be recorded on the information recording medium is set as user control data, of which unit is composed of eight bits, the user control data being selected from the data to be recorded.

6. The information recording processor according to claim 1, wherein the modulated data generating unit is configured to execute processing in which at least one part of the DC control bits set in a DC-control-bit storage frame for determining a response to additional data, and selected from the data to be recorded is set based on DC-control-bit information input from said DC-control-bit selecting unit, and another part of the DC control bits is set based on control of the digital sum variation.

7. The information recording processor according to claim 1, wherein the additional data is set as component information included in at least one of content-encryption-key information to be recorded on the information recording medium, encryption-key generating information, content-playback control information, content-copy control information, and a password.

8. The information recording processor according to claim 1, wherein said modulated data generating unit is configured to generate the modulated recording frame by executing data converting processing satisfying (1, 7) run-length-limited encoding.

9. The information recording processor according to claim 1, wherein said modulated data generating unit is configured to execute modulated-recording-frame generating processing including conversion from two-bit information to three-bit information.

10. An information playback processor for executing processing for playing back information recorded on an information recording medium, said information playback processor comprising:
a data demodulating unit for executing demodulating processing on data read from the information recording medium; and
an additional data decoding unit for executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information based on a result of determination of correspondence.

11. The information playback processor according to claim 10, wherein, depending on whether a correspondence is provided between the DC control bits for determining a response to additional data and the user control data for determining a response to additional data, said additional data decoding unit is configured to perform processing for determining which of one and zero an additional data component bit is.

12. The information playback processor according to claim 10, wherein said additional data decoding unit is configured to perform processing which determines whether a correspondence is provided between the DC control bits for determining a response to additional data and the user control data for determining a response to additional data, and in which, based on the determination that the correspondence is provided, a component bit of the user control data for determining a response to additional data is acquired as an additional data component bit.

13. An information recording medium comprising additional data recorded thereon, wherein the additional data is analyzable based on correspondence between bit values of specific user control data included in recorded data, and DC control bits set in the recorded data.

14. The information recording medium according to claim 13, wherein the recorded data is based on a recording frame generated by controlling, in response to a value of component bits of the recorded additional data, correspondence between user control data and DC control bits set in the recording frame.

15. The information recording medium according to claim 13, wherein the additional data is recorded as component information included in at least one of encryption-key information for content recorded on said information recording medium, encryption-key generating information, content-playback control information, content-copy-control information, and a password.

16. The information recording medium according to claim 13, wherein the recorded data is based on a modulated recording frame generated by executing data converting processing satisfying (1, 7) run-length-limited encoding.

17. The information recording medium according to claim 13, wherein the recorded data is based on a modulated recording frame generated by executing processing for converting two-bit information to three-bit information.

18. An information recording method comprising:
executing DC-control-bit selecting processing in which values of DC control bits set in a recording frame are set to be any one of coincident and not coincident with user control data in response to the values of additional data component bits to be recorded on an information recording medium; and
generating a modulated data in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information selected in the DC-control-bit selecting step are selectively executed.

19. The information recording method according to claim 18, wherein, selective processing is executed in which, in response to the values of the additional data component bits to be recorded on the information recording medium, DC control bits set in a DC-control-bit storage frame for determining a response to additional data, the DC-control-bit storage frame being selected from the data to be recorded, are set at values any one of coincident and not coincident with bit information of user control data for determining a response to additional data, the user control data being selected from the data to be recorded.

20. The information recording method according to claim 18, wherein, selective processing is executed in which values coincident with eight-bit information of user control data for determining a response to additional data, the user control data being selected from the data to be recorded, are any one of set and are not set as the values of eight DC control bits set in a DC-control-bit storage frame for determining a response to additional data.

21. The information recording method according to claim 18, wherein, processing is executed in which user control data, of which unit is composed of eight bits, the user control data being selected from the data to be recorded, is input as user control data for determining a response to additional data, and the values of eight DC control bits set in a DC-control-bit storage frame for determining a response to additional data are set in response to the values of the additional data component bits.

22. The information recording method according to claim 18, further comprising executing processing in which a value corresponding to the values of the additional data component bits to be recorded on the information recording medium is set as user control data, of which unit is composed of eight bits, the user control data being selected from the data to be recorded.

23. The information recording method according to claim 18, further comprising executing processing in which at least one part of the DC control bits set in a DC-control-bit storage frame for determining a response to additional data, the DC-control-bit storage frame being selected from the data to be recorded, is set based on DC-control-bit information input in the DC-control-bit selecting step, and the other part of the DC control bits is set based on the control of the digital sum variation.

24. The information recording method according to claim 18, wherein the additional data is at least one of content-encryption-key information to be recorded on the information recording medium, encryption-key generating information, content-playback control information, content-copy control information, and a password.

25. The information recording method according to claim 18, wherein, the modulated recording frame is generated by executing data converting processing satisfying (1, 7) run-length-limited encoding.

26. The information recording method according to claim 18, wherein, the modulated recording frame is generated by processing that includes conversion from two-bit information to three-bit information.

27. An information playback method for executing processing for playing back information recorded on an information recording medium, the information playback method comprising:
executing demodulating processing on data read from the information recording medium; and
executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information based on the result of the determination of correspondence.

28. The information playback method according to claim 27, wherein depending on whether a correspondence is provided between the DC control bits for determining a response to additional data and the user control data for determining a response to additional data, processing is performed for determining which of one and zero an additional data component bit is.

29. The information playback method according to claim 27, wherein, processing is performed which determines whether a correspondence is provided between the DC control bits for determining a response to additional data and the user control data for determining a response to additional data, and in which, based on the determination that there is a correspondence, a component bit of the user control data for determining a response to additional data is acquired as an additional data component bit.

30. A computer program for executing processing for recording information, the computer program comprising:
a DC-control-bit selecting step of executing DC-control-bit selecting processing in which the values of DC control bits set in a recording frame are set to be coincident with user control data in response to the values of additional data component bits to be recorded on an information recording medium; and
a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on selecting information in the DC-control-bit selecting step are selectively executed.

31. A computer program for executing processing for playing back information recorded on an information recording medium, the computer program comprising:
a data demodulating step of executing demodulating processing on data read from the information recording medium; and
an additional data decoding step of executing determination of correspondence between DC control bits for determining a response to additional data, the DC control bits being acquired from a DC-control-bit storage frame for determining a response to additional data, and user control data for determining a response to additional data, and executing acquisition of additional-data-component-bit information on the based on the result of the determination of correspondence.

32. An information recording processor comprising:
a DC-control-bit selecting unit for executing DC-control-bit selecting processing in which, when specific user control data selected from user control data to be recorded on an information recording medium is user control data including additional data, the values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data; and
a modulated data generating unit for generating a modulated recording frame used as recording-unit data by executing processing for modulating data to be recorded and DC-control-bit setting processing, said modulated data generating unit selectively executing the DC-control-bit setting processing based on control of a digital sum variation and the DC-control-bit setting processing based on information input from said DC-control-bit selecting unit.

33. The information recording processor according to claim 32, wherein:
the specific user control data is eight-bit data; and
in the DC-control-bit selecting processing, when the specific user control data is the user control data including additional data, the DC-control-bit selecting unit sets eight DC control bits set in the DC-control-bit storage frame for specific user control data to have values coincident with eight bit values of the user control data including additional data, and when the specific user control data is the user control data including no additional data, the DC-control-bit selecting unit sets the eight DC control bits set in the DC-control-bit storage frame for specific user control data to have values different from the eight bit values of the user control data including additional data.

34. The information recording processor according to claim 32, further comprising a specific-user-control-data positional-information counter for selecting an item of the specific user control data,
wherein, in the DC-control-bit selecting processing, said DC-control-bit selecting unit sets the DC control bits in a DC-control-bit storage frame for specific user control data, the DC-control-bit storage frame corresponding only to the item of the specific user control data selected by said specific-user-control-data positional-information counter.

35. The information recording processor according to claim 32, further comprising a specific-user-control-data positional-information counter for selecting an item of the specific user control data,
wherein said specific-user-control-data positional-information counter is configured to execute processing for selecting the item of the specific user control data based on address information corresponding to data to be recorded on the information recording medium.

36. The information recording processor according to claim 35, wherein said specific-user-control-data positional-information counter is configured to execute processing for specifying row-position information and column-position information of user control data based on component bits of cluster-identification information in the address information corresponding to the data to be recorded on the information recording medium.

37. The information recording processor according to claim 35, wherein said modulated data generating unit is configured to execute processing in which at least part of the DC control bits set in a DC-control-bit storage frame for specific user control data, the DC-control-bit storage frame being selected from the data to be recorded, is set based DC-control-bit information input from said DC-control-bit selecting unit, and the other part of the DC control bits is set based on measurement of a digital sum variation.

38. The information recording processor according to claim 32, wherein the additional data is set as component information included in at least one of content-encryption-key information to be recorded on the information recording medium, encryption-key generating information, content-playback control information, content-copy control information, and a password.

39. The information recording processor according to claim 32, wherein said modulated data generating unit is configured to generate a modulated recording frame by executing data converting processing satisfying (1, 7) run-length-limited encoding.

40. The information recording processor according to claim 32, wherein said modulated data generating unit is configured to execute modulated-recording-frame generating processing including conversion from two-bit information to three-bit information.

41. An information recording processor comprising:
a DC-control-bit calculating unit for executing arithmetic processing using data included in specific user control data set in user control data to be recorded on an information recording medium, and additional data, and setting values obtained in the arithmetic processing as the values of DC control bits set in a DC-control-bit storage frame for specific user control data; and
a modulated data generating unit for generating a modulated recording frame used as recording-unit data by executing processing for modulating data to be recorded and DC-control-bit setting processing, said modulated data generating unit selectively executing the DC-control-bit setting processing based on control of a digital sum variation and the DC-control-bit setting processing based on information input from said DC-control-bit selecting unit.

42. The information recording processor according to claim 41, wherein said DC-control-bit calculating unit executes, as the arithmetic processing, any one of exclusive disjunction and exclusive non-disjunction of the data included in the specific user control data and the additional data, and sets the obtained values as the values of the DC control bits set in the DC-control-bit storage frame for specific user control data.

43. The information recording processor according to claim 41, wherein:
the specific user control data is eight-bit data; and
said DC-control-bit calculating unit executes, as the arithmetic processing, any one of exclusive disjunction and exclusive non-disjunction of eight bits of the data included in the specific user control data and eight component bits of the additional data, and sets eight bit values obtained in the arithmetic processing as the values of eight DC control bits set in the DC-control-bit storage frame for specific user control data.

44. An information playback processor for executing processing for playing back information recorded on an information recording medium, said information playback processor comprising:
a data demodulating unit which executes demodulating processing on data read from the information recording medium; and
an additional data decoding unit which executes determination of correspondence between DC control bits acquired from a DC-control-bit storage frame for specific user control data, and specific user control data, and determines, based on a result of said determination of correspondence, whether or not the user control data includes additional data, and which executes acquisition of the additional data based on the result of the determination.

45. The information playback processor according to claim 44, wherein said additional data decoding unit is configured to execute processing in which, when the DC control bits acquired from the DC-control-bit storage frame for specific user control data are coincident with the specific user control data, the specific user control data is identified as user control data including the additional data.

46. The information playback processor according to claim 44, wherein:
the specific user control data is eight-bit data; and
said additional data decoding unit is configured to execute processing which determines whether or not the eight-bit data in the specific user control data is coincident with data of eight DC control bits selected from the DC-control-bit storage frame for specific user control data, and which determines, based on a result of determination, whether or not the specific user control data includes the additional data.

47. The information playback processor according to claim 44, further comprising a specific-user-control-data positional-information counter for selecting an item of the specific user control data,
wherein said additional data decoding unit is configured to execute processing which, in response to only the item of the specific user control data selected by said specific-user-control-data positional-information counter, determines correspondence with DC control bits in the DC-control-bit storage frame for specific user control data.

48. The information playback processor according to claim 44, further comprising a specific-user-control-data positional-information counter for selecting an item of the specific user control data,
wherein said specific-user-control-data positional-information counter is configured to execute processing for selecting the item of the specific user control data based on address information corresponding to the data recorded on the information recording medium.

49. The information playback processor according to claim 48, wherein said specific-user-control-data positional-information counter is configured to execute processing for specifying row-position information and column-position information of user control data based on component bits of cluster-identification information in the address information corresponding to the data to be recorded on the information recording medium.

50. An information playback processor for executing processing for playing back information recorded on an information recording medium, said information playback processor comprising:
a data demodulating unit which executes demodulating processing on data read from the information recording medium; and
an additional data decoding unit which executes arithmetic processing of DC control bits acquired from a DC-control-bit storage frame for specific user control data and specific user control data, and acquisition of additional data based on a result of the arithmetic processing.

51. The information playback processor according to claim 50, wherein said additional data decoding unit executes, as the arithmetic processing, any one of exclusive disjunction and exclusive non-disjunction of the DC control bits acquired from the DC-control-bit storage frame for specific user control data and the specific user control data, and acquires obtained values as the values of additional data component bits.

52. The information playback processor according to claim 50, wherein said additional data decoding unit executes, as the arithmetic processing, any one of exclusive disjunction and exclusive non-disjunction of eight bits of data included in the specific user control data and eight DC control bits acquired from the DC-control-bit storage frame for specific user control data, and sets eight bit values obtained in the arithmetic processing as the values of additional data component bits.

53. An information recording medium having a data recording configuration in which information indicating whether additional data is included in specific user control data selected from user control data included in recorded data is analyzable based on values of DC control bits set in a DC-control-bit storage frame for specific user control data.

54. The information recording medium according to claim 53, wherein:
when the specific user control data is user control data including additional data, the DC control bits in the DC-control-bit storage frame for specific user control data are set to have values corresponding to information of bits in the specific user control data; and
when the specific user control data is user control data including no additional data, the DC control bits in the DC-control-bit storage frame for specific user control data are set to have values not corresponding to information of bits in the specific user control data.

55. The information recording medium according to claim 53, wherein the additional data is recorded as component information included in at least one of content-encryption-key information for content recorded on the information recording medium, encryption-key generating information, content-playback control information, content-copy control information, and a password.

56. An information recording medium having a configuration in which bit information is recorded as values of DC control bits set in a DC-control-bit storage frame for specific user control data, the bit information being calculated as a result of arithmetic processing using information of bits in specific user control data selected from user control data included in recorded data and information of additional data component bits.

57. The information recording medium according to claim 56, wherein values which are obtained by executing, as the arithmetic processing, any one of exclusive disjunction and exclusive non-disjunction of data included in the specific user control data and the additional data are set as the values of the DC control bits in the DC-control-bit storage frame for specific user control data.

58. An information recording method comprising:
executing DC-control-bit selecting processing in which, when specific user control data selected from user control data to be recorded on an information recording medium is user control data including additional data, values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data; and
generating a modulated data in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from said DC-control-bit selecting unit are selectively executed.

59. The information recording method according to claim 58, wherein:
the specific user control data is eight-bit data; and
in selecting DC-control-bit, when the specific user control data is the user control data including additional data, eight DC control bits set in the DC-control-bit storage frame for specific user control data are set to have values coincident with eight bit values of the user control data including additional data, and when the specific user control data is the user control data including no additional data, the eight DC control bits set in the DC-control-bit storage frame for specific user control data are to have values different from the eight bit values of the user control data including additional data.

60. The information recording method according to claim 58, further comprising of counting a specific-user-control-data positional-information for selecting an item of the specific user control data,
wherein, in selecting DC-control-bit, the DC control bits in a DC-control-bit storage frame for specific user control data are set, the DC-control-bit storage frame corresponding only to the item of the specific user control data selected in the specific-user-control-data positional-information counting step.

61. The information processing method according to claim 58, further comprising counting a specific-user-control-data positional-information for selecting an item of the specific user control data,
wherein, in counting specific-user-control-data positional-information, the item of the specific user control data is selected based on address information corresponding to data to be recorded on the information recording medium.

62. The information recording method according to claim 61, wherein, in counting specific-user-control-data positional-information, row-position information and column-position information of user control data are specified based on component bits of cluster-identification information in the address information corresponding to the data to be recorded on the information recording medium.

63. The information recording method according to claim 58, wherein, in generating modulated data, at least part of the DC control bits set in a DC-control-bit storage frame for specific user control data, the DC-control-bit storage frame being selected from the data to be recorded, is set based DC-control-bit information input in the DC-control-bit selecting step, and the other part of the DC control bits is set based on measurement of a digital sum variation.

64. The information recording method according to claim 58, wherein the additional data is set as component information included in at least one of content-encryption-key information for content to be recorded on the information recording medium, encryption-key generating information, content-playback control information, content-copy control information, and a password.

65. The information recording method according to claim 58, wherein, in generating modulated data, a modulated recording frame is generated by executing data converting processing satisfying (1, 7) run-length-limited encoding.

66. The information recording method according to claim 58, wherein, in generating modulated data, modulated-recording-frame generating processing including conversion from two-bit information to three-bit information is executed.

67. An information recording method comprising:
executing arithmetic processing using data included in specific user control data set user control data to be recorded on an information recording medium, and additional data, and setting calculated values as the values of DC control bits set in a DC-control-bit storage frame for specific user control data; and
generating a modulated data in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from said DC-control-bit selecting unit are selectively executed.

68. The information recording method according to claim 64, wherein, in calculating DC-control-bit, any one of exclusive disjunction and exclusive non-disjunction of the data included in the specific user control data and the additional data is executed as the arithmetic processing, and calculated values are set as the values of the DC control bits set in the DC-control-bit storage frame for specific user control data.

69. The information recording method according to claim 67, wherein:
the specific user control data is eight-bit data; and
in calculating DC-control-bit, any one of exclusive disjunction and exclusive non-disjunction of eight bits of the data included in the specific user control data and eight component bits of the additional data is executed as the arithmetic processing, and eight bit values obtained in the arithmetic processing are set as the values of eight DC control bits set in the DC-control-bit storage frame for specific user control data.

70. An information playback method for executing processing for playing back information recorded on an information recording medium, said information playback method comprising:
executing demodulating processing on data read from the information recording medium; and
decoding an additional data in which determination of correspondence between DC control bits acquired from a DC-control-bit storage frame for specific user control data, and specific user control data is executed, and based on a result of said determination of correspondence, determination of whether or not the user control data includes additional data is performed, and in which acquisition of the additional data is executed based on the result of the determination.

71. The information playback method according to claim 70, wherein, in decoding additional data, when the DC control bits acquired from the DC-control-bit storage frame for specific user control data are coincident with the specific user control data, the specific user control data is identified as user control data including the additional data.

72. The information playback method according to claim 70, wherein:
the specific user control data is eight-bit data; and
decoding the additional data determines whether or not the eight-bit data in the specific user control data is coincident with data of eight DC control bits selected from the DC-control-bit storage frame for specific user control data, and determines, based on a result of determination, whether or not the specific user control data includes the additional data.

73. The information playback method according to claim 70, further comprising counting a specific-user-control-data positional-information for selecting an item of the specific user control data,
wherein, in decoding additional data, in response to only the item of the specific user control data selected in the specific-user-control-data positional-information counting step, correspondence with DC control bits in the DC-control-bit storage frame for specific user control data is determined.

74. The information playback method according to claim 70, further comprising counting a specific-user-control-data positional-information for selecting an item of the specific user control data,
wherein, in counting specific-user-control-data positional-information, the item of the specific user control data is selected based on address information corresponding to data recorded on the information recording medium.

75. The information playback method according to claim 74, wherein, in counting specific-user-control-data positional-information, the item of the specific user control data is selected based on address information corresponding to data recorded on the information recording medium.

76. An information playback method for executing processing for playing back information recorded on an information recording medium, said information playback method comprising:
demodulating processing on data read from the information recording medium; and
executing arithmetic processing of DC control bits acquired from a DC-control-bit storage frame for specific user control data and specific user control data, and acquisition of additional data on the basis of the result of the arithmetic processing.

77. The information playback method according to claim 76, wherein, any one of exclusive disjunction and exclusive non-disjunction of the DC control bits acquired from the DC-control-bit storage frame for specific user control data and the specific user control data is performed as the arithmetic processing, and values obtained in the arithmetic processing are acquired as the values of additional data component bits.

78. The information playback method according to claim 76, wherein, any one of exclusive disjunction and exclusive non-disjunction of eight bits of data included in the specific user control data and eight DC control bits acquired from the DC-control-bit storage frame for specific user control data is performed as the arithmetic processing, and eight bit values obtained in the arithmetic processing are set as the values of additional data component bits.

79. A computer program for executing information recording processing, said computer program comprising:
a DC-control-bit selecting step for executing DC-control-bit selecting processing in which, when specific user control data selected from user control data to be recorded on an information recording medium is user control data including additional data, the values of DC control bits set in a DC-control-bit storage frame for specific user control data are set as bit values corresponding to the specific user control data, and in which, when the specific user control data is user control data including no additional data, the values of DC control bits set in a DC-control-bit storage frame for specific user control data are set to differ from bit values of the user control data including no additional data; and
a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input from said DC-control-bit selecting unit are selectively executed.

80. A computer program for executing information recording processing, said computer program comprising:
a DC-control-bit calculating step for executing arithmetic processing using data included in specific user control data set user control data to be recorded on an information recording medium, and additional data, and setting calculated values as the values of DC control bits set in a DC-control-bit storage frame for specific user control data; and
a modulated data generating step in which a modulated recording frame used as recording-unit data is generated by executing processing for modulating data to be recorded and DC-control-bit setting processing, and in which the DC-control-bit setting processing based on control of a digital sum variation and the DC-control-bit setting processing based on information input in the DC-control-bit selecting step are selectively executed.

81. A computer program for executing processing for playing back information recorded on an information recording medium, said computer program comprising:
a data demodulating step of executing demodulating processing on data read from the information recording medium; and
an additional data decoding step in which determination of correspondence between DC control bits acquired from a DC-control-bit storage frame for specific user control data, and specific user control data is executed, and based on a result of said determination of correspondence, determination of whether or not the user control data includes additional data is performed, and in which acquisition of the additional data is executed based on the result of the determination.

82. A computer program for executing processing for playing back information recorded on an information recording medium, said computer program comprising:
a data demodulating step of demodulating processing on data read from the information recording medium; and
an additional data decoding step of executing arithmetic processing of DC control bits acquired from a DC-control-bit storage frame for specific user control data and specific user control data, and acquisition of additional data based on a result of the arithmetic processing.
